(19) United States
(12) Patent Application Publication
(10) Pub. No.: US 2026/0289051 A1
(43) Pub. Date: Sep. 24, 2026

(54) SYSTEM

(71) Applicant: SoftBank Group Corp., Tokyo (JP)

(72) Inventor: Hiroyuki MIZUNO, Tokyo (JP)

(73) Assignee: SoftBank Group Corp., Tokyo (JP)

(21) Appl. No.: 19/568,798

(22) Filed: Mar. 17, 2026

(30) Foreign Application Priority Data
Mar. 19, 2025 (JP) 2025-045215

(51) Int. Cl. G06F 30/27; G06F 30/13

(52) U.S. Cl. CPC G06F 30/27; G06F 30/13

(57) ABSTRACT

A system includes a processor that is configured to receive, in an interactive manner, spatial layout requirements from a user and analyze the spatial layout requirements by using natural language processing to generate a prompt sentence suitable for a generative AI model, generate an optimal spatial layout plan by using the generative AI model while taking into account at least space utilization efficiency, work efficiency, smoothness of communication, environmental impact, and an emotion of the user, and visually present the generated spatial layout plan by using three-dimensional modeling, recognize the emotion of the user, and adjust the spatial layout plan based on the recognized emotion of the user.

### CROSS-REFERENCE TO RELATED APPLICATION

This application is based on and claims priority under 35 USC 119 from Japanese Patent Application No. 2025-045215 filed on Mar. 19, 2025, the disclosure of which is incorporated by reference herein.

### BACKGROUND

### Technical Field

The present disclosure relates to a system.

### Related Art

Japanese Patent Application Laid-Open (JP-A) No. 2022-180282 discloses a persona chatbot control method executed by at least one processor. The method includes steps of: receiving a user utterance, adding the user utterance to a prompt including a description of a chatbot character and an associated instruction sentence, encoding the prompt, and inputting the encoded prompt to a language model to generate a chatbot utterance responding to the user utterance.

Conventional space layout design systems and tools primarily focus on static design parameters such as area allocation, furniture arrangement, and basic circulation, and typically optimize for objective indices including space utilization efficiency and work efficiency. However, these conventional systems do not sufficiently incorporate subjective and dynamic factors such as user emotions, perceived stress, and comfort, and therefore often fail to provide a spatial layout that promotes both productivity and psychological well-being of users. In addition, existing systems generally lack an integrated mechanism that interactively receives natural language requirements from users, automatically converts such requirements into a suitable input for a generative AI model, and then further refines the resulting layout based on real-time emotional feedback from the user. As a result, it is difficult to efficiently generate and iteratively adjust an optimal spatial layout plan that simultaneously accounts for space utilization, work efficiency, smooth communication, environmental impact, and user emotion. Accordingly, there is a need for a system that can: (i) interactively receive and interpret spatial layout requirements expressed in natural language, (ii) utilize a generative AI model to automatically generate an optimal spatial layout plan based on multiple objective and subjective criteria, and (iii) recognize and analyze user emotion and adjust the spatial layout plan in response to the emotional state of the user, thereby improving work efficiency, reducing stress, and enhancing overall user satisfaction.

### SUMMARY

In order to solve the above-described problems, an aspect of the present invention provides a system comprising a processor, wherein the processor is configured to receive, in an interactive manner, spatial layout requirements from a user and analyze the spatial layout requirements by using natural language processing to generate a prompt sentence suitable for a generative AI model. The processor is further configured to generate an optimal spatial layout plan by using the generative AI model while taking into account at least space utilization efficiency, work efficiency, smoothness of communication, environmental impact, and an emotion of the user. The processor is also configured to visually present the generated spatial layout plan by using three-dimensional modeling, recognize the emotion of the user, and adjust the spatial layout plan based on the recognized emotion of the user. In some embodiments, the processor is configured to generate the optimal spatial layout plan based on emotion data of the user while taking into account at least work efficiency and stress reduction, thereby enabling the system to propose a layout that mitigates user stress and enhances operational performance. In other embodiments, the processor is configured to analyze an emotional state of the user and adjust the spatial layout plan based on a result of the analysis, so that the spatial layout plan can be iteratively and dynamically optimized in response to changes in the user's emotional state.

The term “system” refers to a combination of hardware and software components that cooperate to perform the processing described in the claims, including at least one processor and, optionally, memory, input/output devices, and communication interfaces.

The term “processor” refers to any hardware device or combination of devices capable of executing instructions, such as a central processing unit (CPU), a graphics processing unit (GPU), a digital signal processor (DSP), an application-specific integrated circuit (ASIC), a field-programmable gate array (FPGA), or any other computing element, including a virtualized processing resource in a cloud environment.

The term “user” refers to a human operator or occupant who inputs spatial layout requirements, views the generated spatial layout plan, and whose emotions, emotional state, or emotion data are recognized, analyzed, or taken into account by the system.

The term “spatial layout requirements” refers to information indicating a desired arrangement, configuration, or characteristics of a physical space, including but not limited to desired sizes of areas, types and locations of workspaces, shared spaces, circulation paths, environmental considerations, and qualitative preferences expressed by the user.

The term “interactive manner” refers to a mode of operation in which the system and the user exchange information in real time or near real time, such that the user can input requirements, receive responses, and provide further inputs based on the responses, for example through a dialog-based graphical user interface, a chat interface, or voice interaction.

The term “natural language processing” refers to a set of techniques for processing and analyzing text or speech expressed in a human language, including but not limited to tokenization, parsing, semantic analysis, intent detection, and entity extraction.

The term “prompt sentence suitable for a generative AI model” refers to a text string or structured instruction that is formatted or composed in a way that is appropriate for input to a generative AI model so as to induce the generative AI model to output a desired spatial layout plan or related information.

The term “generative AI model” refers to a machine learning model configured to generate content, such as text, images, or structured data, based on input data, including but not limited to transformer-based language models, diffusion models, generative adversarial networks (GANs), or variational autoencoders.

The term “optimal spatial layout plan” refers to a representation of a proposed arrangement of elements within a physical space that is determined by the system to satisfy or balance one or more criteria or objectives, such as space utilization efficiency, work efficiency, smoothness of communication, environmental impact, and user emotion, according to a predetermined evaluation method or optimization algorithm.

The term “space utilization efficiency” refers to an index or metric representing how effectively the available physical area is used for functional purposes, for example based on a ratio of occupied area to total area or on a distribution of functional zones.

The term “work efficiency” refers to an index or metric representing the expected effectiveness or productivity of work activities in the space, including factors such as walking distances, accessibility of resources, avoidance of congestion, and suitability of the layout for the intended tasks.

The term “smoothness of communication” refers to an index or metric representing how easily and frequently users can interact and communicate with each other in the space, considering factors such as proximity of shared areas, visibility, and accessibility of communication zones.

The term “environmental impact” refers to an index or metric associated with the environmental burden of the designed space, including, for example, expected energy consumption, natural lighting utilization, ventilation efficiency, and material or equipment choices that may influence sustainability.

The term “emotion of the user” refers to a psychological state or affective response of the user, such as stress, comfort, satisfaction, anxiety, or excitement, which can be inferred from physiological signals, facial expressions, voice characteristics, behavioral data, or explicit feedback.

The term “emotion data of the user” refers to data representing or indicating the emotion of the user, including raw sensor measurements, processed features, classification results, scores, or any other information derived from sensing or input that is used by the system to infer or quantify user emotion.

The term “emotional state of the user” refers to a current or recent emotional condition of the user, such as being relaxed, stressed, focused, or fatigued, which is determined or estimated by the system based on emotion data or user feedback.

The term “three-dimensional modeling” refers to a technique or process for representing a spatial layout as a three-dimensional model, including generation of geometric data, surfaces, and visual attributes that enable three-dimensional visualization on a display device.

The term “visually present” refers to causing a representation of the spatial layout plan to be displayed on a display device, such as a monitor, projector, or head-mounted display, so that the user can visually perceive the layout, including in two-dimensional or three-dimensional views.

The term “recognize the emotion of the user” refers to detecting or identifying the user's emotional state by analyzing emotion data, sensor data, or user input with the aid of algorithms, including but not limited to machine learning or rule-based methods.

The term “analyze an emotional state of the user” refers to processing emotion-related data to determine characteristics or trends of the user's emotional condition, such as intensity, valence, or changes over time, and deriving a result that can be used to influence layout generation or adjustment.

The term “adjust the spatial layout plan” refers to modifying at least a part of the spatial layout plan, including changes to positions, sizes, shapes, or types of zones or objects, in response to recognized or analyzed user emotion or other criteria.

### BRIEF DESCRIPTION OF THE DRAWINGS

Exemplary embodiments of the present disclosure will be described in detail based on the following figures, wherein:

FIG. 1 is a schematic diagram illustrating an example of a configuration of a data processing system according to a first exemplary embodiment;

FIG. 2 is a schematic diagram illustrating an example of relevant functions of a data processing device and a smart device according to the first exemplary embodiment;

FIG. 3 is a schematic diagram illustrating an example of a configuration of a data processing system according to a second exemplary embodiment;

FIG. 4 is a schematic diagram illustrating an example of relevant functions of a data processing device and smart glasses according to the second exemplary embodiment;

FIG. 5 is a schematic diagram illustrating an example of a configuration of a data processing system according to a third exemplary embodiment;

FIG. 6 is a schematic diagram illustrating an example of relevant functions of a data processing device and a headset-type terminal according to the third exemplary embodiment;

FIG. 7 is a schematic diagram illustrating an example of a configuration of a data processing system according to a fourth exemplary embodiment;

FIG. 8 is a schematic diagram illustrating an example of relevant functions of a data processing device and a robot according to the fourth exemplary embodiment;

FIG. 9 illustrates an emotion map mapping plural emotions;

FIG. 10 illustrates an emotion map mapping plural emotions;

FIG. 11 is a sequence diagram showing the flow of data processing system processing in Example 1;

FIG. 12 is a sequence diagram showing the flow of data processing system processing in Application Example 1;

FIG. 13 is a sequence diagram showing the flow of data processing system processing in Example 2; and

FIG. 14 is a sequence diagram showing the flow of data processing system processing in Application Example 2.

### DETAILED DESCRIPTION

Description follows regarding an example of exemplary embodiments of a system according to technology disclosed herein, with reference to the appended drawings.

First, explanation follows regarding terminology employed in the following description.

In the following exemplary embodiments, a reference-numeral-appended processor (hereinafter simply referred to as “processor”) may be implemented by a single computation unit, and may be implemented by a combination of plural computation units. The processor may be implemented by a single type of computation unit, or may be implemented by a combination of plural types of computation units. Examples of computation unit include a central processing unit (CPU), a graphics processing unit (GPU), a general-purpose computing on graphics processing units (GPGPU), an accelerated processing unit (APU), and the like.

In the following exemplary embodiments, random access memory (RAM) appended with a reference numeral is memory temporarily stored with information, and is employed as working memory by a processor.

In the following exemplary embodiments, reference-numeral-appended storage is a single or plural non-volatile storage devices for storing various programs and various parameters and the like. Examples of non-volatile storage devices include flash memory (such as a solid state drive (SSD)), a magnetic disk (for example, a hard disk), magnetic tape, and the like.

In the following exemplary embodiments, a reference-numeral-appended communication interface (I/F) is an interface including a communication processor and an antenna or the like. The communication I/F has the role of communicating between plural computers. An example of a communication standard applied for the communication I/F is a wireless communication standard, such as a Fifth Generation Mobile Communication System (5G), Wi-Fi (registered trademark), Bluetooth (registered trademark), and the like.

In the following exemplary embodiments “A and/or B” has the same definition as “at least one out of A or B”. Namely, “A and/or B” may mean A alone, may mean B alone, or may mean a combination of A and B. Moreover, similar logic to “A and/or B” is applied when “and/or” is employed to link three or more items in the present specification.

### First Exemplary Embodiment

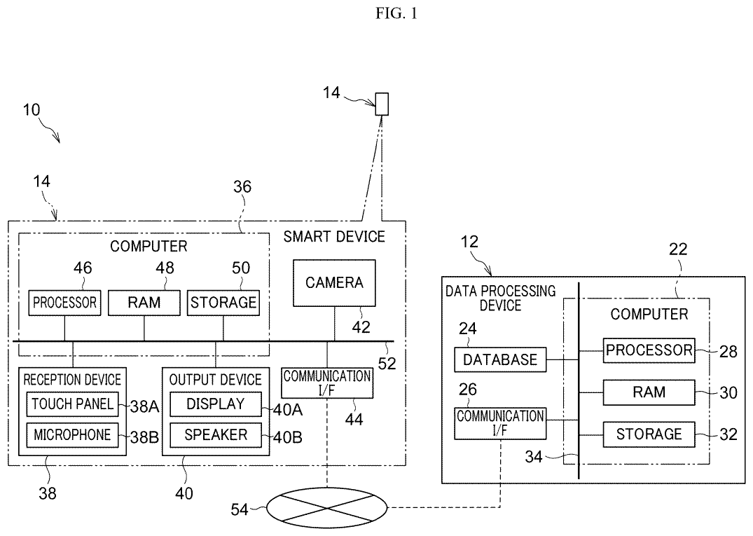

FIG. 1 illustrates an example of a configuration of a data processing system 10 according to a first exemplary embodiment.

As illustrated in FIG. 1, the data processing system 10 includes a data processing device 12 and a smart device 14. A server is an example of the data processing device 12.

The data processing device 12 includes a computer 22, a database 24, and a communication I/F 26. The computer 22 is an example of a “computer” according to technology disclosed herein. The computer 22 includes a processor 28, RAM 30, and storage 32. The processor 28, the RAM 30, and the storage 32 are connected to a bus 34. The database 24 and the communication I/F 26 are also connected to the bus 34. The communication I/F 26 is connected to a network 54. Examples of the network 54 include a Wide Area Network (WAN) and/or a local area network (LAN).

The smart device 14 includes a computer 36, a reception device 38, an output device 40, a camera 42, and a communication I/F 44. The computer 36 includes a processor 46, RAM 48, and storage 50. The processor 46, the RAM 48, and the storage 50 are connected to a bus 52. The reception device 38, the output device 40, the camera 42, and the communication I/F 44 are also connected to the bus 52.

The reception device 38 includes a touch panel 38A, a microphone 38B, and the like for receiving user input. The touch panel 38A receives user input from contact of a pointer (for example, a pen, a finger, or the like) by detecting contact of the pointer. The microphone 38B receives spoken user input by detecting speech of the user. A control unit 46A in the processor 46 transmits data representing the user input received by the touch panel 38A and the microphone 38B to the data processing device 12. A specific processing unit 290 in the data processing device 12 acquires the data indicating the user input.

The output device 40 includes a display 40A, a speaker 40B, and the like for presenting data to a user 20 by outputting the data in an expression format perceivable by the user 20 (for example, audio and/or text). The display 40A displays visual information such as text, images, or the like under instruction from the processor 46. The speaker 40B outputs audio under instruction from the processor 46. The camera 42 is a compact digital camera installed with an optical system such as a lens, an aperture, a shutter, and the like, and with an imaging device such as a complementary metal-oxide semiconductor (CMOS) image sensor or a charge coupled device (CCD) image sensor or the like.

The communication I/F 44 is connected to the network 54. The communication I/F 44 and the communication I/F 26 perform the role of exchanging various information between the processor 46 and the processor 28 over the network 54.

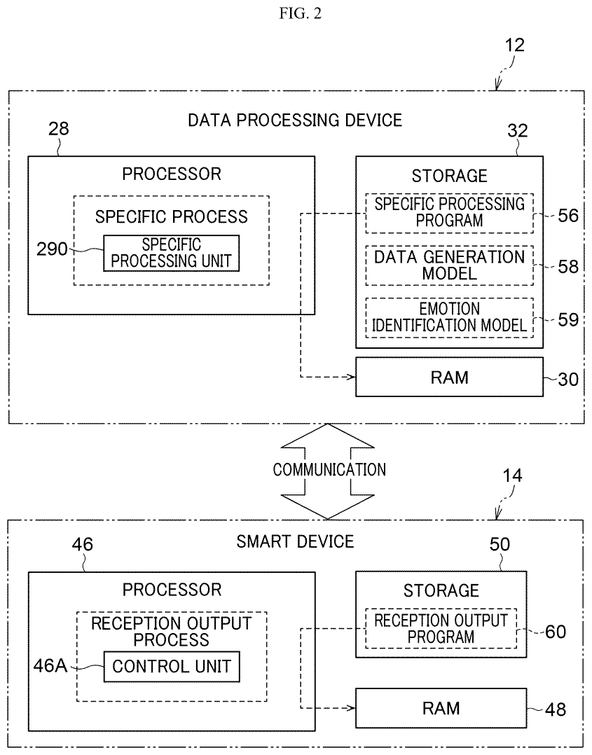

FIG. 2 illustrates an example of relevant functions of the data processing device 12 and the smart device 14.

As illustrated in FIG. 2, specific processing is performed by the processor 28 in the data processing device 12. A specific processing program 56 is stored in the storage 32. The specific processing program 56 is an example of a “program” according to technology disclosed herein. The processor 28 reads the specific processing program 56 from the storage 32, and in the RAM 30 executes the read specific processing program 56. The specific processing is implemented by the processor 28 operating as the specific processing unit 290 according to the specific processing program 56 executed in the RAM 30.

A data generation model 58 and an emotion identification model 59 are stored in the storage 32. The data generation model 58 and the emotion identification model 59 are employed by the specific processing unit 290. The specific processing unit 290 uses the emotion identification model 59 to estimate an emotion of a user, and is able to perform the specific processing using the user emotion. In an emotion estimation function (emotion identification function) that uses the emotion identification model 59, various estimations, predictions, and the like are performed related to emotions of the user, include estimating and predicting the emotion of the user, however, there is no limitation to such examples. Moreover, estimation and prediction of emotion also includes, for example, analyzing (parsing) emotions and the like.

Reception and output processing is performed by the processor 46 in the smart device 14. A reception and output program 60 is stored in the storage 50. The reception and output program 60 is employed by the data processing system 10 in combination with the specific processing program 56. The processor 46 reads the reception and output program 60 from the storage 50, and in the RAM 48 executes the read reception and output program 60. The reception and output processing is implemented by the processor 46 operating as the control unit 46A according to the reception and output program 60 executed in the RAM 48. Note that a configuration may be adopted in which a similar data generation model and emotion identification model to the data generation model 58 and the emotion identification model 59 are included in the smart device 14, and these models are used to perform similar processing to the specific processing unit 290. The reception and output program is implemented by the processor 46 operating as the control unit 46A according to the reception and output program 60 executed in the RAM 48.

Note that devices other than the data processing device 12 may include the data generation model 58. For example, a server device (for example, a generation server) may include the data generation model 58. In such cases, the data processing device 12 performs communication with the server device including the data generation model 58 to obtain a processing result (prediction result or the like) obtained using the data generation model 58. The data processing device 12 may be a server device, and may be a terminal device owned by the user (for example, a mobile phone, a robot, a home electrical appliance, or the like). Next, description follows regarding an example of processing by the data processing system 10 according to the first exemplary embodiment.

### Example 1

Description follows regarding a flow of the specific processing in an Example 1. The units of the system described below are implemented by the data processing device 12 and the smart device 14. The data processing device 12 is called a “server” and the smart device 14 is called a “terminal”.

Conventional computer-implemented spatial layout design systems mainly rely on fixed rule sets or manual parameter tuning performed by human experts. Such systems typically require a user to input highly structured parameters, such as numeric dimensions or predefined layout types, and then execute deterministic optimization or simulation processes. Consequently, these systems are poorly suited to handling requirement information expressed in natural language, such as intuitive or qualitative preferences, and cannot flexibly interpret ambiguous or multi-faceted user intents. This leads to a technical limitation in human-computer interaction, in that the computing system is unable to automatically convert free-form textual requirements into machine-usable structured constraints with sufficient precision and robustness.

Furthermore, existing computer-aided layout tools generally generate layouts in a single pass based on the initial input conditions, without effectively incorporating iterative feedback or affective reactions from the user. Even if some level of interactive editing is provided, the user must manually adjust geometric parameters, such as region sizes and positions, which imposes a high cognitive and operational load. As a result, the underlying processor is not efficiently utilized to automate the translation of feedback into updated design constraints and is unable to automatically refine layout candidates in response to successive user interactions, thereby limiting the overall computational efficiency of the layout generation pipeline.

In addition, known systems do not effectively utilize generative AI models within a closed loop that starts from natural language requirement information, passes through structured constraint extraction and prompt sentence generation, and ends with layout plan generation and visualization. In many cases, generative AI models are invoked in a standalone manner, with manually prepared prompts, without systematic pre-processing (such as constraint structuring) or post-processing (such as consistency verification and correction of region data). This causes instability and inconsistency in the generated layout data structures and prevents the processor from reliably using the generative AI model as a deterministic component within a broader automated pipeline.

Moreover, conventional systems either ignore user emotion entirely or use emotion-related information only as a qualitative suggestion, without integrating it into formal constraint variables or objective functions in the computation of layout plans. Consequently, the processor cannot adapt the spatial configuration parameters such as area ratios of open regions, numbers of individual work regions, or widths of circulation paths based on measured or inferred emotional states. This results in a missed opportunity to algorithmically improve work efficiency and burden reduction, measured as quantitative evaluation metrics computed from both structured constraint information and user emotion information. Therefore, there is a need for an improved computer-implemented system and method in which a processor (i) receives and analyzes natural language requirement information, (ii) automatically generates a structured prompt sentence suitable for a generative AI model, (iii) performs consistency-checked layout generation and visualization, and (iv) iteratively updates a spatial layout plan based on user feedback and emotion information, thereby improving the functioning of the computer system itself in terms of interaction handling, data structuring, and automated optimization behavior.

The specific processing by the specific processing unit 290 of the data processing device 12 in Example 1 is realized by the following means.

The present invention provides a server comprising a processor and a memory storing instructions which, when executed by the processor, cause the processor to receive, via an interactive interface, natural-language requirement information regarding a spatial layout from a user; to analyze the requirement information using natural language processing to extract structured constraint information including at least a space type, area conditions, functional conditions, circulation conditions, and comfort conditions; to generate, based on the structured constraint information, a prompt sentence as a generation instruction text that is inputtable to a generative AI model; to input the prompt sentence to the generative AI model and obtain, from the generative AI model, layout plan data representing a spatial layout plan that takes into account at least space utilization efficiency, work efficiency, communication, environmental load, and user emotion; to perform consistency verification and correction processing on position information, dimension information, and function information for each region included in the layout plan data, and to convert the layout plan data into layout display data including geometric information and explanatory information; to cause a client device to visually present the spatial layout plan using the layout display data and to obtain feedback information from the user in response to the presentation; to regenerate the prompt sentence by combining the feedback information with the requirement information so as to iteratively update the spatial layout plan; and to recognize emotion information of the user obtained during or after the presentation of the spatial layout plan and to adjust at least a region configuration, dimension allocation, and arrangement relationship of the spatial layout plan based on the emotion information. This enables the computer system to automatically transform unstructured natural-language requirements and affective feedback into structured constraints and iterative prompt sentences for a generative AI model, to generate and refine consistent layout plan data with reduced manual intervention, and to improve computational efficiency and interaction quality in computer-implemented spatial layout design.

The term “user” refers to any person or entity that provides requirement information, feedback information, or emotion information to the system via an interactive interface. The term “interactive interface” refers to a human-machine interface that enables bidirectional communication between the user and the system, and includes, for example, graphical user interfaces, voice-based interfaces, and text-based chat interfaces.

The term “requirement information” refers to information provided by the user that expresses desired conditions, preferences, or constraints regarding a spatial layout, and may be expressed in natural language or other input formats.

The term “spatial layout” refers to an arrangement of regions, elements, or functional areas within a physical or virtual space, including information such as positions, dimensions, and relationships among the regions.

The term “natural language processing” refers to a set of computational techniques for analyzing and processing human language, including at least tokenization, parsing, semantic analysis, and extraction of structured information from unstructured text.

The term “structured constraint information” refers to machine-readable data derived from the requirement information, the data including at least attributes such as space type, area conditions, functional conditions, circulation conditions, and comfort conditions represented in a structured format.

The term “space type” refers to a classification of a spatial layout according to its primary use or function, such as office, commercial space, educational facility, medical facility, or residential space.

The term “area conditions” refers to constraints or preferences related to size or surface area of one or more regions in the spatial layout, including absolute area values, relative area ratios, and minimum or maximum area limits.

The term “functional conditions” refers to constraints or preferences specifying the functions to be provided in the spatial layout, including, for example, required types and numbers of work areas, meeting areas, circulation areas, storage areas, or relaxation areas.

The term “circulation conditions” refers to constraints or preferences regarding movement paths or accessibility within the spatial layout, including at least widths of circulation paths, connectivity between regions, and accessibility requirements.

The term “comfort conditions” refers to constraints or preferences related to subjective or objective comfort in the spatial layout, including factors such as openness, privacy, noise level, lighting, and perceived spaciousness.

The term “prompt sentence” refers to a generation instruction text constructed by the processor based on the structured constraint information, the text being suitable for input to a generative AI model to cause the model to generate a spatial layout plan.

The term “generative AI model” refers to a computational model based on machine learning that generates output data, such as text or structured layout data, in response to an input prompt sentence, the model performing inference using learned parameters.

The term “inference processing” refers to computational processing performed by the generative AI model in response to the prompt sentence, including internal numerical calculations to generate output data without retraining the model parameters.

The term “spatial layout plan” refers to a plan representing a candidate arrangement of regions within a space, including data describing at least region configuration, positions, dimensions, functions of regions, and relationships between regions.

The term “layout plan data” refers to data representing the spatial layout plan in a form suitable for further processing by the processor, the data including at least region identifiers, position information, dimension information, and functional information.

The term “position information” refers to data indicating the location of a region within a reference coordinate system of the spatial layout, including, for example, coordinates or relative positions.

The term “dimension information” refers to data indicating the size or shape of a region in the spatial layout, including, for example, width, depth, height, or other geometric measures.

The term “function information” refers to data that describes the intended use or role of a region in the spatial layout, such as open work area, individual work region, meeting room, corridor, or storage area.

The term “consistency verification” refers to processing performed by the processor to determine whether position information, dimension information, and function information in the layout plan data satisfy predetermined rules or constraints, such as area limits or circulation requirements.

The term “correction processing” refers to processing performed by the processor to modify position information, dimension information, or function information in the layout plan data to resolve inconsistencies or to better satisfy constraints or evaluation conditions.

The term “layout display data” refers to data derived from the layout plan data and formatted for visualization, including geometric information suitable for rendering and explanatory information describing properties of regions.

The term “geometric information” refers to data that defines the shapes, sizes, and spatial relationships of regions for the purpose of graphical rendering, such as coordinates of vertices, widths, heights, and layout orientation.

The term “explanatory information” refers to descriptive data associated with regions in the spatial layout plan, including labels, textual descriptions, usage notes, or annotations for use in display or user understanding.

The term “visual presentation” refers to a display operation in which the layout display data is rendered on a display device using two-dimensional or three-dimensional visualization techniques, enabling the user to perceive the spatial layout plan.

The term “feedback information” refers to information provided by the user in response to the visual presentation of the spatial layout plan, the information including additional requirements, modifications, evaluations, or preferences.

The term “iteratively update” refers to repeatedly modifying the spatial layout plan by regenerating prompt sentences and invoking the generative AI model based on updated requirement information and feedback information over multiple cycles.

The term “emotion information” refers to data representing an emotional state or reaction of the user, obtained by explicit input, sensor data, or analysis of user behavior or expressions.

The term “emotional state” refers to a condition of the user's affect, such as comfort, discomfort, tension, or concentration, that can be inferred or measured and used as a parameter in adjusting the spatial layout plan.

The term “emotion indices” refers to numerical or categorical values representing quantified aspects of the emotional state of the user, including at least comfort or discomfort, tension, and concentration.

The term “region configuration” refers to a composition of regions in the spatial layout plan, including which regions exist, how many regions exist of each type, and how the regions are arranged relative to each other.

The term “dimension allocation” refers to the distribution of space among regions in the spatial layout plan, including how total available area is allocated to respective regions or groups of regions.

The term “arrangement relationship” refers to relative positions and adjacency relationships among regions in the spatial layout plan, including which regions are adjacent, separated, or connected by circulation paths.

The term “evaluation value” refers to a quantitative value computed by the processor based on structured constraint information and emotion information to evaluate a quality of the spatial layout plan with respect to indices such as work efficiency and burden reduction.

The term “predetermined condition” refers to a condition or threshold used by the processor to determine whether the evaluation value is acceptable, the condition being stored in advance or dynamically set according to system configuration.

The term “spatial configuration parameters” refers to adjustable parameters that define characteristics of the spatial layout plan, including at least area ratio of open regions, number of individual work regions, and width of circulation paths.

The term “area ratio of open regions” refers to a proportion of total available area that is allocated to regions classified as open regions, such as open workspaces or open common areas.

The term “individual work regions” refers to regions in the spatial layout that are designated for individual work, with relatively higher privacy or isolation compared to open regions.

The term “circulation paths” refers to routes or regions within the spatial layout used for movement of persons, including corridors, passageways, and access paths between regions.

The term “width of circulation paths” refers to a measure of the lateral extent of a circulation path, used as a constraint or parameter in determining accessibility, comfort, or compliance with standards.

The term “work efficiency” refers to a performance measure related to how effectively work can be carried out within the spatial layout, which may be estimated or computed based on spatial configuration and user behavior models.

The term “burden reduction” refers to a reduction in physical or psychological load experienced by the user in the spatial layout, which is evaluated using a combination of constraint satisfaction and emotion-related information.

In one embodiment, a server, a terminal, and a communication network cooperate to implement the system for generating and updating a spatial layout plan based on natural-language requirement information, a generative AI model, and user emotion information.

The server includes at least one processor, a memory, a network interface, and a non-transitory storage medium. The terminal includes at least one processor, a memory, a display unit, an input unit, and a communication module. The server and the terminal communicate via a wired or wireless network, such as an Ethernet network or a wireless local area network. The server stores in the memory executable instructions that cause the processor of the server to implement a plurality of software modules, including an interface control module, a natural language processing module, a constraint structuring module, a prompt generation module, a generative AI interface module, a layout post-processing module, an evaluation and optimization module, an emotion analysis module, and a visualization data generation module. The server may execute these modules using a general-purpose operating system and an application runtime environment, for example, a server operating system and a runtime for a programming language such as Python or JavaScript.

The terminal stores in its memory executable instructions that cause the processor of the terminal to implement a user interface application. The terminal executes a web browser or a native application and presents an interactive interface including at least a text input field, selection controls, and a layout visualization area. The terminal may use a rendering library such as an HTML5 canvas library or a vector graphics library to draw the spatial layout plan. The user operates the terminal to input requirement information regarding a spatial layout. The user enters natural-language sentences, such as:
“I want a wide open office space with several quiet individual work booths.”
or
“Design an office layout where the open space is near the windows, and provide three small meeting rooms.”

The terminal transmits the requirement information and associated parameters, such as total floor area, target number of workers, or layout type, to the server via the network interface. The server receives the requirement information and stores it in a structured request record in a database. The server then invokes the natural language processing module to analyze the requirement information. The natural language processing module may be implemented using a library such as an industrial natural language library or a transformer-based language model executed via a machine learning framework such as PyTorch or TensorFlow.

The natural language processing module performs tokenization, part-of-speech tagging, and dependency parsing to identify key noun phrases and verb phrases indicating spatial requirements. The server further applies semantic role labeling to determine, for example, which terms correspond to space types, such as “office,” “meeting room,” or “booth,” which terms correspond to area or quantity constraints, such as “wide,” “three,” or “small,” and which terms correspond to qualitative preferences, such as “near the windows” or “quiet.” In one example, the server maps the phrase “wide open office space” to a constraint that an open work region should occupy at least a predetermined percentage of total area, and maps “quiet individual work booths” to a constraint specifying a minimum number of individual acoustic booth regions.

The constraint structuring module converts the analysis results into structured constraint information represented as internal records stored in the memory of the server. These records may include fields for a space type, area conditions, functional conditions, circulation conditions, and comfort conditions. For example, the server may store:
a space type field indicating “office,”
an area condition field indicating that the total area is approximately 200 square units and that the open region area ratio should be equal to or larger than a threshold,
a functional condition field indicating presence and count of individual work regions and meeting regions,
a circulation condition field indicating minimum corridor width or required connections between regions, and
a comfort condition field indicating high priority of quietness in individual work regions and high priority of openness near windows.

The server then uses the prompt generation module to generate a prompt sentence suitable for input to a generative AI model. The prompt generation module selects, from a plurality of stored templates, a template corresponding to the detected space type and use case. The module fills placeholders in the template with the structured constraint information. An example prompt sentence generated by the server is as follows:
“You are an expert interior and spatial layout designer.
Design an office layout within approximately 200 square meters.
Requirements:
   Create a wide open office space as the main area.
   Include at least 4 quiet individual work booths.
   Ensure clear circulation paths of at least 1.5 meters width.
   Place the open space near the windows to maximize natural light.
   Maintain a balance between openness and acoustic privacy in the booths.
Output a structured description of the layout, including approximate dimensions, zone locations, and functional descriptions for each area.”

In another example, the server generates:
“Design a 250 square meter office layout with a large open space for collaborative work, 3 private meeting rooms for 6 people each, and a small lounge area.
Ensure logical circulation and clear separation between quiet and noisy zones.
Return the result as a detailed textual description of each zone, including its approximate size, relative position, and purpose.”

By generating the prompt sentence in this structured and template-based way, the server improves the consistency and completeness of input data delivered to the generative AI model, thereby reducing variance and error in the model output compared to manually created prompts.

The generative AI interface module sends the prompt sentence to the generative AI model.

The generative AI model may be a transformer-based language model with multiple layers of self-attention and feed-forward networks, having, for example, several billion parameters.

The generative AI model may run on a hardware accelerator, such as a graphics processing unit, located either on the same server or on another computing apparatus accessible via an application programming interface.

The generative AI model receives the prompt sentence, encodes it into token embeddings, and propagates the embeddings through a sequence of transformer layers. Each transformer layer performs multi-head self-attention to compute context-aware representations and applies position-wise non-linear transformations. The model computes an output token sequence representing a spatial layout plan description or a machine-readable representation of zone definitions. The model has been trained in advance on a corpus including spatial layouts and architectural descriptions. During training, the model uses a loss function such as cross-entropy loss and updates its parameters via a gradient-based optimization algorithm, such as an adaptive moment estimation algorithm. The training process adjusts weights of linear transformations and attention parameters so that the model learns correlations between natural-language constraints and appropriate spatial configurations.

The server receives from the generative AI model an output sequence and converts it into layout plan data. When the output is in a text format, the server uses parsing rules to identify region names, approximate sizes, and adjacency relations. When the output is in a semi-structured format, the server maps that format into internal structures representing zones, each zone having at least position information, dimension information, and function information. The layout post-processing module verifies consistency of the layout plan data by checking whether the sum of region areas approximately matches the total area condition, whether circulation paths satisfy minimum width constraints, and whether functional requirements, such as the number of meeting rooms or individual work regions, are met.

If inconsistencies are detected, the server adjusts region dimensions or resizes all regions by a common scale factor so as to conform to the total area condition. The server may also allocate surplus or deficit area to auxiliary regions, such as buffer corridors, to maintain functional integrity. These correction operations are performed via deterministic algorithms executed by the processor, not only by relying on the generative AI model.

The server then generates layout display data suitable for visualization by the terminal. The visualization data generation module converts the internal coordinates and dimensions into normalized coordinates for a display canvas, assigns color codes based on region function types, and attaches explanatory information such as textual labels and usage notes. The server transmits the layout display data to the terminal via the network.

The terminal receives the layout display data and renders a visual representation of the spatial layout plan on the display unit. The terminal draws each region as a polygon or rectangle with a color and a label. The terminal may support zooming and panning so that the user can inspect details of the layout. The user can view dimensions and functions of each region through tooltips or side panels when selecting regions.

The user observes the presented layout and then provides feedback information via the interactive interface. The user may input additional natural-language instructions, such as:
“Increase the number of quiet individual work booths to 6 and reduce the open space slightly, but keep the corridors wide.”
or
“Move the meeting rooms closer to the entrance and keep the lounge area near the windows.”

The terminal sends the feedback information to the server. The server combines the feedback information with the original requirement information in the natural language processing module and constraint structuring module. The server updates the structured constraint information accordingly, for example by modifying the count of individual work regions and by adjusting target area ratios. The prompt generation module then generates a new prompt sentence that explicitly indicates the revision, for example:
“Revise the previous office layout.
Increase the number of quiet individual work booths from 4 to 6.
Slightly reduce the area of the main open space while keeping circulation paths at least 1.5 meters wide.
Keep the open space near the windows and preserve the overall comfort and usability of the layout.”

The generative AI interface module sends the updated prompt sentence to the generative AI model, obtains a revised layout plan, and the layout post-processing module and visualization data generation module execute the same sequence as described above. In this manner, the server repeatedly and automatically transforms user feedback into updated constraints and new prompt sentences, and iteratively refines the spatial layout plan without requiring the user to edit low-level geometric parameters. This iterative loop reduces manual operations and improves the efficiency and accuracy of layout generation.

The server also handles emotion information of the user. Emotion information may be provided by explicit self-report input, physiological sensors, or analysis of voice or facial expressions using a separate emotion detection module. The emotion analysis module of the server receives emotion-related data and converts it into emotion indices, such as comfort or discomfort level, tension level, and concentration level. The server stores these indices in association with the corresponding layout plan and presentation state.

The evaluation and optimization module calculates an evaluation value for the spatial layout plan by combining structured constraint information and emotion indices. The evaluation value may be computed as a weighted sum of terms representing work efficiency, expected stress reduction, and satisfaction of functional constraints. The module compares the evaluation value with a predetermined condition, such as a threshold stored in the memory, and determines whether the current layout plan is acceptable.

If the evaluation value does not satisfy the predetermined condition, the evaluation and optimization module modifies the structured constraint information or includes additional constraints into the prompt sentence. For example, when the comfort index is low while tension is high, the evaluation and optimization module may increase target area ratios of open regions, reduce the number of closely packed individual work regions, or increase widths of circulation paths. These changes are explicitly encoded into the next prompt sentence so that the generative AI model receives clear and structured instructions reflecting emotional feedback.

By explicitly using emotion indices as quantitative parameters for constraint adjustment, the server performs an optimization-like process at the computing system level. The server does not merely present layouts and record user feelings, but modifies spatial configuration parameters and thereby guides the generative AI model toward layouts that are predicted to improve both objective efficiency and subjective comfort. This increases the quality of the layout plan and reduces the number of iterations required to reach an acceptable design, thereby improving computing resource usage and interaction efficiency.

From a computer technology standpoint, the described configuration improves at least the following aspects:

The server reduces processing time and network usage by generating compact and constraint-complete prompt sentences instead of sending large raw requirement texts and partial hints to the generative AI model.

The server improves accuracy and consistency of generated spatial layouts by performing pre-processing (structured constraint extraction) and post-processing (consistency verification and correction) around the generative AI model, thereby turning an inherently probabilistic generator into a more deterministic component of a larger pipeline.

The server improves data management by maintaining structured records linking requirement information, prompt sentences, layout plan data, emotion indices, and evaluation values, enabling efficient retrieval, comparison, and incremental refinement of layout plans.

The server improves computing efficiency by reusing structured constraint information across iterations and only updating differential constraints based on new feedback or updated emotion indices.

The generative AI model is used in a non-conventional way, as the server constrains and guides model outputs through pre-defined templates, quantitative constraints, and deterministic correction algorithms. The model does not merely replace human designers but is integrated into a technical pipeline that improves layout generation performance. The combination of structured constraint extraction, prompt sentence templating, consistency-checked layout post-processing, and emotion-driven optimization forms a non-standard rule set and processing flow that yields technical improvements in speed, accuracy, and robustness of computer-implemented spatial layout planning.

In alternative embodiments, the server may employ different generative AI models and network architectures. For example, the generative AI model may be a combination of a language model and a graph-based layout generator, where a first transformer encodes the prompt sentence into a set of constraint vectors, and a second network generates a graph representing adjacency relations between regions. The server may further perform graph optimization using heuristic search or integer programming to refine region placements based on geometric constraints. In another variation, the server may precompute a library of typical layout patterns and use a neural retrieval module to select and adapt the most suitable pattern given the current structured constraint information.

The server may also support multiple terminals simultaneously, allowing several users to collaborate on the same spatial layout. In such a case, the server aggregates requirement information and feedback information from multiple users and reconciles conflicting constraints via a negotiation module that adjusts weights assigned to respective requirements. By implementing these embodiments, the server, the terminal, and the associated modules provide a concrete realization of a computer-implemented system that not only automates certain aspects of spatial layout design but also improves the way in which the computing system processes natural-language requirements, manages structured constraints, interacts with a generative AI model, and iteratively updates layout plans based on both objective constraints and user emotion information.

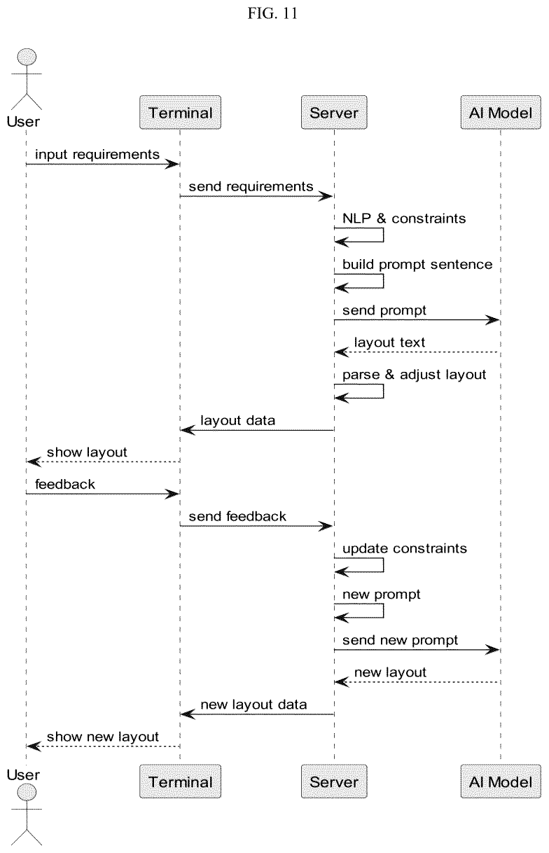

The following describes the processing flow using FIG. 11.

### Step 1:

The user operates the terminal to access an interactive interface.

The terminal receives, as input, a user request expressed in natural language, for example: “I want a wide open office space with several quiet individual work booths.”

The terminal displays a text input field and optional controls (such as sliders or dropdowns for total area, number of people, and layout type), and the user enters the requirement information and selects additional parameters.

The terminal packages the requirement text and the selected parameters into a structured request, and outputs this structured request as a data object, for example a set of key-value pairs, to be transmitted to the server.

### Step 2:

The terminal transmits the structured request to the server via a communication network.

The terminal sets an HTTP request body as input, including the requirement text and parameter values, and sends the request to a predefined server endpoint.

The server receives the HTTP request as input, parses the body to extract the requirement text and parameter values, and outputs a normalized internal representation of the request, which includes user identification, timestamp, and the raw requirement text.

The server stores this normalized request in a storage unit, such as a database, to be used as the basis for further processing.

### Step 3:

The server invokes a natural language processing module to analyze the requirement text.

The server uses the raw requirement text as input and performs tokenization, part-of-speech tagging, and dependency parsing to identify linguistic units that correspond to spatial requirements, such as “open office space,” “quiet,” “booths,” “near windows,” and numeric expressions like “three” or “six.”

The server applies semantic analysis rules and a trained classification model to map detected phrases to semantic categories such as space type, area-related term, function-related term, and location preference.

The server outputs intermediate semantic annotations, for example lists of extracted entities, their types, and their relationships, which will be used for constraint structuring.

### Step 4:

The server executes a constraint structuring module to convert the semantic annotations into structured constraint information.

The server uses, as input, the semantic annotations and the numeric parameters received from the terminal, such as total area and target number of workers.

The server performs data aggregation and transformation operations, including:
mapping terms like “wide open space” to quantitative area ratios or minimum area thresholds,
mapping “quiet individual work booths” to a required count of booth regions with acoustic isolation attributes,
mapping phrases like “near the windows” to spatial relation constraints between open regions and boundary regions.

The server constructs a structured constraint record, including fields for space type, area conditions, functional conditions, circulation conditions, and comfort conditions, and outputs this record as structured constraint information to be used for prompt generation.

### Step 5:

The server operates a prompt generation module to produce a prompt sentence for a generative AI model.

The server uses the structured constraint information as input and selects a template corresponding to the detected space type and use case.

The server fills template placeholders with values and phrases derived from the structured constraints, concatenates sentences in a predefined order, and adds explicit instructions for output format and design criteria.

The server outputs a completed prompt sentence, for example:
“You are an expert interior and spatial layout designer.
Design an office layout within approximately 200 square meters.
Requirements:
   Create a wide open office space as the main area.
   Include at least 4 quiet individual work booths.
   Ensure clear circulation paths of at least 1.5 meters width.
   Place the open space near the windows to maximize natural light.
   Maintain a balance between openness and acoustic privacy in the booths.
Output a structured description of the layout, including approximate dimensions, zone locations, and functional descriptions for each area.”

### Step 6:

The server invokes a generative AI model by using the prompt sentence as input.

The server sends the prompt sentence to a model execution environment, such as a transformer-based language model running on a graphics processing unit, via an application programming interface.

The generative AI model performs numerical operations including embedding lookup, matrix multiplications in self-attention layers, and non-linear activation steps to infer a sequence of output tokens representing a candidate spatial layout plan.

The server receives the output sequence from the generative AI model and outputs preliminary layout plan data, which may be a textual description or a semi-structured list of regions with attributes.

### Step 7:

The server executes a layout parsing and normalization module to convert the preliminary layout plan data into internal layout plan data structures.

The server uses the output from the generative AI model as input and applies parsing rules or text-to-structure algorithms to extract, for each region, attributes such as region name, function type, approximate width, approximate depth, and adjacency relations.

The server creates a region list, assigns unique identifiers to each region, and computes initial coordinates or relative positions based on adjacency and approximate size.

The server outputs normalized layout plan data that includes, for each region, position information, dimension information, and function information suitable for consistency checking.

### Step 8:

The server executes a consistency verification module on the normalized layout plan data.

The server uses the normalized layout plan data and the structured constraint information as input and performs arithmetic checks and logical checks, such as verifying that the sum of region areas approximates the total area condition, that corridor widths satisfy the minimum circulation conditions, and that the required number of functional regions (such as booths or meeting rooms) is present.

The server detects any violations, for example if the open area ratio is below the target threshold or if the number of individual work regions is insufficient.

The server outputs a verification result indicating whether the layout plan data is consistent, along with a list of detected issues.

### Step 9:

The server operates a correction module to adjust the layout plan data based on the verification result.

The server uses, as input, the normalized layout plan data and the detected issues.

The server performs data computations such as scaling region dimensions, reallocating surplus area among compatible regions, resizing corridors to meet width constraints, and adding or removing minor auxiliary regions where needed.

The server re-computes region coordinates to maintain adjacency and connectivity while satisfying the corrected dimensions.

The server outputs corrected layout plan data, which is a refined spatial representation consistent with the structured constraints.

### Step 10:

The server executes a visualization data generation module to produce layout display data.

The server uses the corrected layout plan data as input and maps region coordinates and dimensions into display coordinates suitable for a drawing canvas, taking into account the resolution and aspect ratio of the terminal display.

The server assigns color codes and labels to each region based on the region function and attaches explanatory information, such as usage notes and approximate sizes, to be shown in tooltips or side panels.

The server outputs layout display data that comprises geometric information and explanatory information for each region, and this layout display data is transmitted to the terminal.

### Step 11:

The terminal receives the layout display data and renders the spatial layout plan on the display unit.

The terminal uses the layout display data as input and executes drawing operations to display regions as shapes at the specified coordinates with the specified sizes and colors.

The terminal overlays textual labels and provides interactive elements, such as clickable regions and scrollable side panels, to present explanatory information.

The terminal outputs a visual representation of the spatial layout plan to the user and updates the interface state to accept further actions.

### Step 12:

The user observes the presented spatial layout plan on the terminal and provides feedback information.

The user uses the visual information as input and decides modifications, such as increasing the number of booths, relocating meeting rooms, or adjusting openness.

The user enters new natural-language feedback, for example: “Increase the number of quiet individual work booths to 6 and reduce the open space slightly, but keep the corridors wide.” The terminal outputs this feedback information as a new request payload and sends it to the server, thereby initiating a new cycle of analysis and layout refinement.

### Step 13:

The server receives feedback information from the terminal and updates the structured constraint information.

The server uses, as input, the original structured constraint information and the new feedback text, and re-applies natural language processing to extract updated or additional constraints, such as a new count for individual work regions or a modified open area ratio.

The server merges old and new constraints, resolving conflicts by predefined priority rules (for example giving precedence to the latest feedback), and produces updated structured constraint information.

The server outputs this updated structured constraint information and passes it to the prompt generation module to regenerate a prompt sentence that reflects the requested changes.

### Step 14:

The server processes emotion information of the user and adjusts spatial configuration parameters.

The server uses, as input, emotion-related data associated with the layout presentation, such as user self-reported comfort or sensor-derived emotion indices.

The server maps the emotion information to emotion indices, including comfort or discomfort, tension, and concentration, and then computes adjustments to spatial configuration parameters, such as area ratio of open regions, number of individual work regions, and width of circulation paths.

The server updates the structured constraint information by modifying relevant fields according to the computed adjustments, and outputs revised constraints that incorporate both explicit feedback information and implicit emotional responses, which are then used in subsequent prompt sentence generation and layout plan creation.

### Application Example 1

Description follows regarding a flow of the specific processing in an Application Example 1. The units of the system described below are implemented by the data processing device 12 and the smart device 14. The data processing device 12 is called a “server” and the smart device 14 is called a “terminal”

Conventional computer-implemented space planning tools largely depend on manual definition of constraints and static rule sets. In many systems, a user is required to translate high-level, natural-language requirements into detailed parameters such as object coordinates, aisle widths, or zone labels through complex graphical operations. This manual translation imposes a heavy cognitive load on the user and often results in sub-optimal use of processing resources because the computing system is not directly optimized to interpret natural-language instructions or to iteratively refine layouts based on user feedback. Furthermore, in known systems that incorporate machine learning, the generative component is often treated as a black-box content generator: the system simply calls a model once and displays its output, without integrating a structured pipeline that converts natural-language input into machine-interpretable layout conditions, evaluates multiple candidate layouts with explicit computational metrics, and feeds user reaction data back into the generation and evaluation logic. As a result, computing resources such as processors, memory, and communication interfaces are not used efficiently to converge on layouts that reflect user preferences, and the system cannot systematically improve its performance over time. Additionally, existing systems tend to lack integrated mechanisms for: (i) automatically generating prompt sentences and numerical feature values from user natural-language input in a form optimized for a generative AI model; (ii) executing algorithmic evaluation, such as movement path analysis and visibility analysis, on multiple candidate layouts within the same processing flow; and (iii) maintaining and exploiting detailed history information (prompt sentences, layout conditions, adopted layouts, and user reactions) to adapt model parameters and evaluation indices. The absence of this integrated loop causes unnecessary repetition of user operations, increased network traffic due to ineffective iterations, and inefficient neural network computations that are not aligned with learned user preferences.

The technical problem to be solved, therefore, is to improve the operation of computer systems that perform space layout generation by providing a coordinated architecture and processing pipeline that: efficiently parses and structures natural-language layout requests; generates and evaluates multiple candidate layouts using a generative AI model and algorithmic metrics; incorporates user feedback, including emotional or evaluative responses, into the weighting of model inputs and evaluation indices; and adaptively updates model and evaluation parameters based on accumulated history. By solving this problem, the computing system can reduce unnecessary computations, improve the quality and relevance of generated layouts, and enhance the efficiency and effectiveness of human computer interaction in layout design tasks.

The specific processing by the specific processing unit 290 of the data processing device 12 in Application Example 1 is realized by the following means.

The present invention provides a server comprising a processor, a storage device, and a communication interface, the processor being configured to cooperate with at least one terminal including a display device and an input device, to acquire, via the communication interface, user requests related to spatial arrangement expressed in natural language and transmitted from the terminal, to execute a language analysis program to convert the user requests into structured data representing spatial arrangement conditions, to generate, based on the structured data, prompt sentences suitable for input to a generative AI model and associated numerical feature values, to input the prompt sentences and the numerical feature values to the generative AI model executed on a numerical computation resource and generate layout data representing a plurality of candidate spatial arrangement plans, to execute, for the plurality of candidate spatial arrangement plans, algorithmic evaluation including a movement path analysis algorithm and a visibility evaluation algorithm to calculate index values including movement distance, congestion degree, visibility, and environmental influence, to select an optimal spatial arrangement plan based on the index values and the spatial arrangement conditions and, when necessary, adjust the layout data by local search or rule-based correction, to convert the selected or adjusted spatial arrangement plan into display data and transmit corresponding image information to the terminal for visual presentation, to acquire, via the communication interface, evaluation information indicating user reactions or data indicating a user emotional state together with additional natural-language requests or layout manipulation inputs, to update the spatial arrangement conditions and change weighting of at least one of the numerical feature values and the evaluation indices based on the evaluation information or the emotional state, to repeatedly execute the generation and evaluation processing in accordance with updated spatial arrangement conditions, and to store, in the storage device, the prompt sentences, the spatial arrangement conditions, the spatial arrangement plans, the evaluation information, and update histories thereof as history information and to update parameters of at least one of the generative AI model and the evaluation indices based on the history information. This enables improved operation of the computing system by optimizing the end-to-end processing pipeline for natural-language-driven spatial layout generation, reducing redundant computation and user interaction steps, adaptively aligning neural network computations and evaluation logic with learned user preferences, and thereby efficiently producing spatial arrangement plans that better satisfy user requirements while making effective use of processing, memory, and communication resources.

The term “system” refers to a combination of one or more information processing devices, storage devices, communication devices, and terminal devices that cooperatively execute the processing described in the claims.

The term “processor” refers to a hardware computation unit, such as a central processing unit or a graphics processing unit, that executes instructions of a program to perform data processing, control, and calculation functions.

The term “storage device” refers to a hardware component, such as a semiconductor memory, magnetic storage, or optical storage, that stores programs, parameters, layout data, history information, and other digital information.

The term “communication device” refers to a hardware and software combination that enables data transmission and reception between the system components and external devices via wired or wireless communication networks.

The term “terminal” refers to an information processing apparatus, such as a mobile device, portable computer, or fixed display terminal, that includes at least a display device and an input device and that interacts with a user.

The term “display device” refers to a component that visually presents information to a user, such as a flat-panel display, projection display, or head-mounted display.

The term “input device” refers to a component that acquires operation information or input data from a user, such as a touch panel, keyboard, pointing device, microphone, or sensor.

The term “user request” refers to information that expresses a user's requirement or intention regarding spatial arrangement, which is input through the terminal using natural language or layout manipulation operations.

The term “spatial arrangement” refers to a configuration of objects, zones, or functional areas within a physical or virtual space, including positions, sizes, orientations, and relationships among those elements.

The term “character information” refers to digital data representing a sequence of characters or symbols, such as text expressed in a natural language.

The term “natural language” refers to a language used for human communication, such as spoken or written language, as opposed to a formal programming or markup language.

The term “language analysis program” refers to software that performs natural language processing, including at least tokenization, grammatical analysis, and semantic analysis, on character information.

The term “structured data representing spatial arrangement conditions” refers to data organized in a predetermined format, such as key-value pairs, lists, or tables, that explicitly describe constraints, requirements, and parameters related to a spatial arrangement.

The term “spatial arrangement conditions” refers to constraints, preferences, and target values that define a desired configuration of a space, including conditions on positions, distances, visibility, flow, or other layout-related properties.

The term “prompt sentence” refers to a natural-language or structured text expression generated for or used as input to a generative AI model to specify or condition the content to be generated.

The term “numerical feature values” refers to numeric data, such as scalar values, vectors, or matrices, derived from spatial arrangement conditions or other context information, and used as input parameters for a generative AI model or evaluation algorithm.

The term “generative AI model” refers to a machine learning model, such as a neural network, that generates new data, including spatial arrangements, based on input data such as prompt sentences and numerical feature values.

The term “numerical computation device” refers to a hardware resource, such as a processor or accelerator, optimized for performing numerical operations including matrix and vector computations required for running a generative AI model.

The term “neural network computation” refers to a sequence of numerical operations, including linear transformations and nonlinear activation functions, executed in accordance with a neural network architecture to produce output data from input data.

The term “layout data” refers to digital data representing one or more spatial arrangement plans, including information about positions, sizes, orientations, and types of objects or zones.

The term “spatial arrangement plan” refers to a specific candidate configuration of objects and areas within a space, defined according to spatial arrangement conditions and represented by layout data.

The term “movement path analysis algorithm” refers to a computational procedure that analyzes potential or simulated movement paths of entities in a space to evaluate properties such as movement distance, congestion, or flow efficiency.

The term “visibility evaluation algorithm” refers to a computational procedure that determines visibility metrics, such as line-of-sight, visible area, or prominence of objects, within a spatial arrangement.

The term “index values” refers to numerical indicators computed by algorithms, such as movement path analysis or visibility evaluation, that quantify performance or quality aspects of a spatial arrangement.

The term “movement distance” refers to a numerical measurement of distance traveled or to be traveled by entities within a space, calculated along paths defined in a spatial arrangement plan.

The term “congestion degree” refers to a numerical indication of the likelihood or severity of crowding or bottlenecks in specific regions or paths of a spatial arrangement.

The term “visibility” refers to a numerical indication of how easily objects, zones, or areas can be seen or recognized from certain viewpoints or routes in a space.

The term “environmental influence” refers to a numerical indication of the environmental impact or environmental performance of a spatial arrangement, such as energy efficiency or use of natural light.

The term “local search” refers to an optimization procedure that iteratively modifies parts of a spatial arrangement in the vicinity of a current solution to improve one or more evaluation indices.

The term “rule-based correction” refers to an adjustment of layout data performed according to predetermined rules or constraints that enforce required conditions on a spatial arrangement.

The term “display data structure” refers to a data format suitable for rendering by a display device, containing information such as coordinates, shapes, colors, and rendering parameters for representing a spatial arrangement as an image.

The term “image information” refers to digital data that defines visual content for presentation on a display device, including two-dimensional or three-dimensional representations of a spatial arrangement.

The term “layout manipulation input” refers to user input that directly modifies or designates elements of a spatial arrangement, such as dragging objects, resizing areas, or selecting layout components through a user interface.

The term “evaluation information” refers to data indicating a user's assessment, reaction, or preference regarding a presented spatial arrangement, including explicit ratings, selections, or feedback.

The term “user emotional state” refers to information representing or estimating a user's emotional condition, such as satisfaction, stress, or comfort, obtained from user input or sensor data.

The term “evaluation indices” refers to a set of metrics, including at least space utilization efficiency, work efficiency, communication smoothness, environmental impact, and user preference, used to evaluate candidate spatial arrangement plans.

The term “weighting” refers to the assignment or adjustment of numerical weights to numerical feature values or evaluation indices to change their relative influence on computations by the generative AI model or evaluation algorithms.

The term “history information” refers to accumulated data including past prompt sentences, spatial arrangement conditions, generated spatial arrangement plans, user reactions, evaluation results, and update histories.

The term “update history” refers to records describing changes over time to spatial arrangement conditions, layout data, evaluation indices, model parameters, or other system parameters.

The term “parameters of the generative AI model” refers to adjustable numerical values, such as weights and biases, within the generative AI model that determine the model's behavior.

The term “parameters of the evaluation indices” refers to adjustable numerical values or coefficients used in computing evaluation indices, such as threshold values, weight coefficients, or normalization factors.

The term “user preference” refers to characteristics of layouts, patterns, or attribute combinations that a user tends to favor, inferred from evaluation information, emotional state data, or adopted spatial arrangement plans.

The term “prompt sentence of a similar type” refers to a prompt sentence whose content, structure, or extracted features are similar to those of a prior prompt sentence stored in history information, as determined by a similarity measure in the system.

In one embodiment, a server, one or more terminals, and one or more storage devices cooperate to implement the claimed system for computer-implemented spatial arrangement planning.

The server includes at least one processor, a main memory, a non-volatile storage device, and a communication interface. The processor executes programs stored in the storage device and loaded into the main memory. The storage device stores a language analysis program, a generative AI model implemented using a neural network framework, an evaluation module, and a history management module. The communication interface provides wired or wireless connectivity, for example via an Ethernet controller or a wireless communication module, and uses network protocols such as TCP/IP and HTTPS.

The terminal includes at least one processor, a memory, a display device such as a liquid crystal display or organic light-emitting display, an input device such as a touch panel or keyboard, and a communication module such as a wireless local area network module or a cellular modem. The terminal executes an application program that presents a graphical user interface for spatial layout design.

The user operates the terminal to input a prompt sentence that describes spatial arrangement requirements in natural language. For example, the user may input:
“Please propose a store layout that prioritizes the visibility of products and minimizes customer walking distance.”
“Generate a store layout with a wide space around the cashier area.”
“Generate an office layout that encourages communication between teams while keeping private meeting rooms quiet.”
“Create a store layout that reduces congestion near the entrance and keeps the promotion area close to the cashier.”
“Propose a layout that reduces environmental impact by maximizing natural light usage and minimizing the number of artificial light fixtures.”

The terminal converts user operations into text data, encodes the text in a character encoding such as UTF-8, and generates request data structures that include the prompt sentence and optional context information such as floor dimensions, entrance locations, or object catalogs.

The terminal uses an application-level communication library to encapsulate these data structures into an HTTP request and transmits the request via the communication module to the server.

The server receives the request through the communication interface and passes the request content to the language analysis program. The language analysis program is implemented as software executed by the processor using a general-purpose programming language such as Python and libraries for natural language processing, for example tokenization and part-of-speech analysis libraries and semantic parsing libraries. The server converts the prompt sentence into structured data representing spatial arrangement conditions. In one implementation, the server generates an internal representation as a dictionary or record that includes keys such as target_visibility_score, max_congestion_level, cashier_clearance_radius, communication_weight, and environmental_weight.

The server performs linguistic preprocessing, including tokenization, lemmatization, syntactic dependency parsing, and semantic role labeling. The server maps extracted phrases such as “prioritizes the visibility of products,” “wide space around the cashier area,” or “encourages communication between teams” to predefined feature definitions. Each feature definition is associated with a set of numerical feature values. For example, the phrase “prioritizes the visibility of products” is converted into a high value for a visibility feature, a constraint on the maximum height of objects near main paths, and an increased weight for display-facing floor area. The phrase “wide space around the cashier area” is converted into a minimum clearance radius around cashier positions and a constraint to prevent obstruction in that region.

The server generates a prompt sentence for the generative AI model and corresponding numerical feature vectors. The generated prompt sentence may be a normalized or enriched text condition, such as “Store layout with high product visibility, wide cashier clearance, and low entrance congestion.” The numerical feature vectors are constructed as fixed-dimension arrays, including continuous values normalized between predetermined ranges and one-hot encodings representing categorical aspects such as store type or office type.

The server loads a generative AI model into the main memory. In one embodiment, the generative AI model is a neural network built using a machine learning framework such as a tensor computation library and a neural network library. The model may have a conditional generative adversarial network architecture or a conditional transformer-based architecture. For example, in a conditional generative adversarial network embodiment, the generator network receives both a noise vector and a condition vector that concatenates the numerical feature values and an embedding of the prompt sentence. The discriminator network receives candidate layout representations and the same condition vector. The generator network includes multiple fully connected layers, convolutional layers, and normalization layers. The discriminator network includes convolutional layers and output layers that output a probability indicating whether a layout is realistic and consistent with the condition vector. In another embodiment, the generative AI model is a transformer-based sequence model that treats layout elements as tokens. In this case, the server converts layout elements into token sequences and uses attention layers to model relationships between objects, such as adjacency and visibility. The condition vector derived from the prompt sentence is injected into the transformer via special condition tokens or bias terms.

The server performs forward propagation of the generative AI model on the processor or on an attached accelerator such as a graphics processing unit. The processor executes matrix multiplication instructions and vector operations necessary for the neural network computations. The generative AI model outputs layout data in a predefined data structure. For example, the output may be a two-dimensional grid representation in which each cell includes probabilities of object types, or a list of object records including coordinates, sizes, orientations, and types. The server converts this raw output into layout data structured as an array of layout items, each layout item specifying an object identifier, an object category, a position in the floor coordinate system, a size, and an orientation.

The server does not simply display the first generated layout. Instead, the server generates multiple candidate layouts by sampling different noise vectors or by using different decoding strategies, such as top-k sampling or temperature-controlled sampling. For each candidate layout, the server executes a movement path analysis algorithm and a visibility evaluation algorithm.

In one embodiment, the server represents walkable space as a graph structure where nodes correspond to grid cells or waypoints and edges represent possible movement transitions. The server uses a graph algorithm library or custom pathfinding functions to compute shortest paths between important points, such as the entrance and key products, or between gateways and exits. The server calculates movement distance metrics and congestion risk by simulating multiple agents or by evaluating edge capacities and path overlaps.

For visibility evaluation, the server discretizes the space into viewpoint positions and uses geometric computations to determine line-of-sight between viewpoints and objects. The server computes visibility scores as functions of the visible area of objects, the number of viewpoints from which objects are visible, and the distance between viewpoints and objects. The server also evaluates obstruction by other objects.

The server aggregates movement distance, congestion, visibility, and environmental influence into index values. Environmental influence may be computed by evaluating object placement relative to windows or light sources, or by calculating energy use estimates. The server computes a composite score for each candidate layout using a weighted sum or other aggregation function where weights are derived from the structured spatial arrangement conditions.

The server selects the candidate layout that maximizes or optimizes the composite score while satisfying hard constraints such as minimum aisle widths or safety clearances. When a candidate layout violates a strict constraint, the server applies rule-based correction. For example, the server may shift objects away from emergency exits or enlarge aisles in regions where the computed congestion degree exceeds a threshold. The server may also perform local search, such as iteratively moving or rotating individual objects in small increments and re-evaluating the index values, to refine the layout.

The server converts the selected or refined layout into display data structures suitable for rendering by the terminal. The display data may include a two-dimensional vector representation or a three-dimensional model configuration. The server encodes coordinates, shapes, colors, and labels into a standardized format such as a markup language or a custom JSON-like structure, and transmits this display data to the terminal via the communication interface.

The terminal receives the display data, interprets the data using the application program, and renders the spatial arrangement on the display device. The terminal uses graphics libraries such as a two-dimensional drawing library or a three-dimensional rendering library to draw floor boundaries, objects such as shelves or desks, and zones with distinct colors. The terminal allows the user to zoom, pan, and select objects. The terminal may also overlay the original prompt sentence and key evaluation metrics, such as estimated average walking distance or visibility score, to make the computational evaluation visible to the user.

The user reviews the rendered layout and may provide evaluation information or emotional reactions. For example, the user may rate the layout, select preferred regions, or indicate dissatisfaction with congestion near a certain area. The user may input additional prompt sentences, such as “Please reduce congestion near the entrance and keep promotional items easy to find,” or “Increase seating near the windows while maintaining wide aisles.” The terminal captures these inputs as text or selection data and sends them to the server. The server interprets evaluation information and user emotional state data as signals that affect weight adjustments in the generative AI model inputs or the evaluation indices. For instance, if the user repeatedly selects layouts with more open space near a cashier zone, the server increases the weight associated with cashier clearance features in subsequent computations. The server stores prompt sentences, spatial arrangement conditions, generated layouts, chosen layouts, evaluation information, and weight settings in the storage device as history information.

In one learning embodiment, the server periodically updates model parameters using the accumulated history. For a conditional generative adversarial network, the server applies supervised or semi-supervised training using adopted layouts as target outputs conditioned on the corresponding feature vectors. The server computes a loss function that combines reconstruction error for adopted layouts and adversarial loss measuring realism, and uses gradient-based optimization to update network weights. For the evaluation indices, the server may adjust weights in the composite scoring function by solving an optimization problem that increases alignment between selected layouts and user-adopted layouts.

This architecture and data flow provide technical improvements over conventional systems. The server restructures natural-language input into compact feature vectors and structured spatial constraints, which reduces the dimensionality of input to the generative AI model and reduces the number of candidate layouts needed to converge to a satisfactory solution. By executing movement path analysis and visibility evaluation inside the server in a formalized manner, the system allows the processor to perform efficient graph-based computations and geometric computations that are tuned to the layout domain, rather than relying on manual user inspection. The use of iterative generation and evaluation under changing weights derived from user reactions reduces redundant computation because the model is guided toward user-preferred regions of the solution space. The history-based adaptation of model parameters and evaluation indices further reduces the number of iterations required in future sessions, thereby reducing communication load between the terminal and server and improving response time.

The server improves computer technology itself by introducing a specialized data structure for spatial arrangement conditions, a generative AI model conditioned by those structures, and a multi-stage evaluation pipeline that executes on general-purpose processors and accelerators in a way that optimizes computational workload. The server does not merely automate human layout operations. Instead, the server executes a non-conventional sequence of processing steps that includes automatic translation of natural-language constraints into numerical features, structured neural network generation with domain-specific conditioning, algorithmic evaluation using graph and visibility algorithms, feedback-based weight adaptation, and history-based model retraining. This non-conventional sequence leads to improved precision of generated layouts, faster convergence to acceptable solutions, and lower error rates compared to manual design or straightforward single-pass generation. In alternative embodiments, the generative AI model architecture may vary. In one variant, the server uses a variational autoencoder that encodes existing layouts from the history into a latent space and decodes new layouts conditioned on prompt feature vectors. In another variant, the server uses a hybrid model that combines a graph neural network for representing arrangement of objects and a convolutional network for spatial grid refinements. The learning method may also vary; the server may use reinforcement learning where reward signals are derived from evaluation indices and user acceptance, and the server updates policy parameters using temporal-difference learning.

In all embodiments, the terminal performs user interface and rendering tasks, and the user acts as a provider of high-level text requests and subjective feedback, while the server performs detailed language analysis, generative model execution, algorithmic evaluation, and adaptive control of model parameters and evaluation weights. By defining careful data structures, concrete algorithms, and an integrated flow between language input, generative AI output, and algorithmic evaluation, the system realizes a specific improvement in computer-implemented layout generation, achieving higher computational efficiency, improved layout quality, and more effective management of spatial design data.

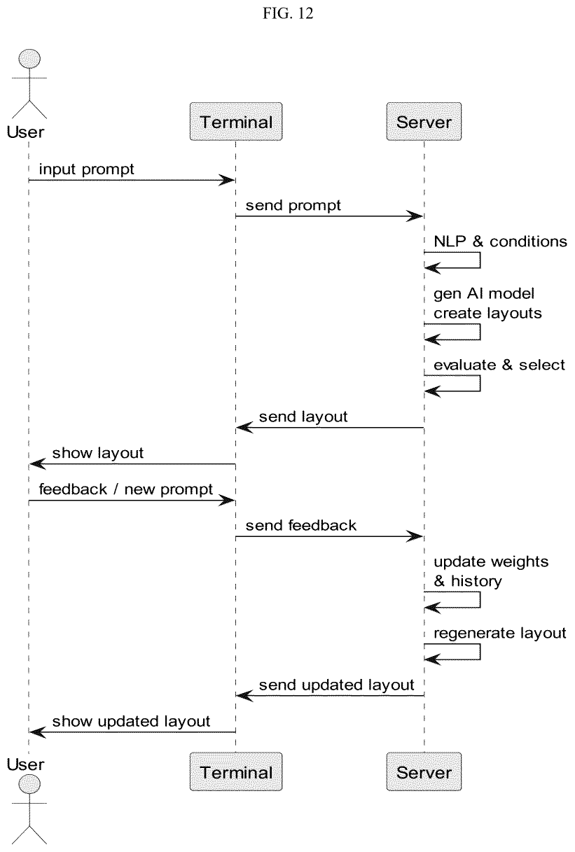

The following describes the processing flow using FIG. 12.

### Step 1:

The user operates the terminal to launch a layout-design application and inputs a prompt sentence in natural language.

Input: The user's keystrokes, touch inputs, or voice data.

Processing: The terminal converts the user's operations into a text string (for example, UTF-8 encoded), displays the text in an input field, and confirms completion of input (for example, when the user presses a send button).

Output: A prompt sentence string such as “Please propose a store layout that prioritizes the visibility of products and minimizes customer walking distance.”

### Step 2:

The terminal generates request data including the prompt sentence and context information.

Input: The prompt sentence string and internal context (for example, floor size, store type, default parameters stored in the app).

Processing: The terminal constructs a data object (for example, a key-value structure) containing fields such as prompt, floor_width, floor_depth, entrance_positions, and layout_mode. The terminal serializes this object into a request body (for example, JSON) and attaches metadata such as user identifier and timestamp.

Output: A structured request payload ready for transmission to the server.

### Step 3:

The terminal transmits the request payload to the server via a communication interface.

Input: The structured request payload generated in Step 2.

Processing: The terminal uses a networking library to open a secure connection (for example, HTTPS over TCP/IP), sets HTTP headers (for example, content type and authentication token), and sends an HTTP POST request to a predefined server endpoint. The terminal waits for an acknowledgment from the server.

Output: A network message containing the request payload delivered to the server.

### Step 4:

The server receives and parses the request payload.

Input: The HTTP request containing the prompt sentence and context information.

Processing: The server's web application framework extracts the request body, parses the serialized data (for example, JSON parsing), and validates required fields (for example, checks that prompt is non-empty and dimensions are valid numbers). The server records a log entry with the prompt sentence and metadata.

Output: An internal representation of the user request, including the prompt sentence string and context parameters, stored in server memory.

### Step 5:

The server executes natural language preprocessing on the prompt sentence.

Input: The prompt sentence string from Step 4.

Processing: The server calls a language analysis program that performs tokenization, lowercasing, part-of-speech tagging, and dependency parsing. The server identifies domain-specific phrases such as “prioritizes the visibility of products,” “wide space around the cashier area,” or “minimizes customer walking distance.” The server maps these phrases to initial symbolic features such as VISIBILITY_HIGH, CASHIER_CLEARANCE_WIDE, and WALK_DISTANCE_LOW.

Output: A set of symbolic features and annotations representing semantic elements extracted from the prompt sentence.

### Step 6:

The server converts symbolic features into structured spatial arrangement conditions.

Input: The symbolic features and annotations from Step 5, together with context parameters (for example, floor dimensions).

Processing: The server applies a rule mapping table that associates each symbolic feature with parameter definitions. For example, VISIBILITY_HIGH is mapped to a target_visibility_score, a maximum shelf height near main aisles, and a minimum sightline length; CASHIER_CLEARANCE_WIDE is mapped to a minimum clearance radius and no-block zones. The server combines these mappings into a structured conditions object including numeric targets, ranges, and categorical flags.

Output: Structured spatial arrangement conditions, represented as a data object with fields such as target_visibility_score, cashier_clearance_radius, max_congestion_level, communication_weight, and environmental_weight.

### Step 7:

The server encodes the spatial arrangement conditions into numerical feature vectors and a normalized prompt sentence for the generative AI model.

Input: The structured spatial arrangement conditions from Step 6 and the original prompt sentence.

Processing: The server normalizes each numeric parameter into a fixed range (for example, 0 to 1), performs one-hot encoding for categorical parameters (for example, store_type, office_type), and concatenates them into a condition vector. The server also converts the prompt sentence into an embedding vector by applying a text embedding model (for example, a pre-trained encoder). The server may construct a model-specific prompt sentence such as “Store layout with high visibility, low congestion, and wide cashier area” for transformer-type models.

Output: A condition vector, a text embedding vector, and an optional normalized prompt sentence for conditioning the generative AI model.

### Step 8:

The server executes the generative AI model to produce multiple candidate layouts.

Input: The condition vector, the text embedding vector, and optional normalized prompt sentence from Step 7, and random noise vectors for sampling.

Processing: The server loads a trained generative AI model (for example, a conditional generative adversarial network or transformer-based generator) into memory and executes it on a processor or accelerator. For each sampling, the server concatenates the noise vector with the condition vector and text embedding, feeds this combined vector into the input layer, and performs forward propagation through multiple layers (for example, linear layers, convolutional layers, attention layers, and activation functions). The server repeats this process for a predetermined number of samples to generate multiple candidate layouts. Output: A set of raw layout outputs, each represented as a tensor or intermediate structure encoding object positions, sizes, and types.

### Step 9:

The server converts raw layout outputs into layout data structures.

Input: The raw layout outputs from Step 8.

Processing: The server interprets each output tensor according to the model specification (for example, each slice corresponds to an object slot, with fields for x, y, width, height, type probabilities, and orientation). The server applies decoding logic such as selecting the highest-probability type for each slot, clipping coordinates to floor boundaries, and removing objects with probabilities below a threshold. The server then constructs an explicit list of layout items for each candidate, where each item contains an identifier, object category, coordinates, dimensions, and orientation.

Output: A set of candidate layout data structures, each describing a complete spatial arrangement plan.

### Step 10:

The server performs movement path analysis for each candidate layout.

Input: Each candidate layout data structure from Step 9 and context parameters such as entrances, exits, and key destinations.

Processing: The server discretizes the floor into a grid or graph representation, marking walkable and non-walkable regions based on object footprints. The server constructs a graph with nodes representing walkable cells and edges representing adjacent relationships. Using a graph algorithm (for example, shortest path search), the server computes movement paths between key points and calculates metrics such as average path length, maximum path length, and path overlap. The server derives a congestion degree metric by aggregating expected flow across shared edges.

Output: For each candidate layout, numeric metrics including movement distance values and congestion degree values.

### Step 11:

The server performs visibility evaluation for each candidate layout.

Input: Each candidate layout data structure from Step 9 and viewpoint definitions (for example, entrance positions or main aisles).

Processing: The server samples viewpoint positions on the floor and performs geometric computations to determine line-of-sight between each viewpoint and each object. The server checks for obstructions by other objects and computes visible area and visibility angles. The server aggregates these values into a visibility score per candidate, for example by summing weighted visible areas of key objects or calculating the number of viewpoints from which important zones are visible.

Output: For each candidate layout, visibility scores and related visibility metrics.

### Step 12:

The server computes composite evaluation index values and selects an optimal layout.

Input: Movement distance metrics and congestion degree values from Step 10, visibility metrics from Step 11, and the spatial arrangement conditions from Step 6.

Processing: The server uses the spatial arrangement conditions to determine weighting factors for evaluation indices, such as the relative importance of visibility versus congestion. The server computes a composite score for each candidate layout by combining metrics, for example via a weighted sum or other scoring function. The server filters out any candidates that violate hard constraints (for example, minimum aisle width or blocked exits). The server selects the candidate with the best composite score as an initial optimal layout.

Output: A selected optimal layout data structure and associated evaluation index values.

### Step 13:

The server optionally refines the selected layout using local search and rule-based correction.

Input: The selected layout data structure and constraint definitions derived from the spatial arrangement conditions.

Processing: The server identifies local regions where metrics are sub-optimal (for example, local congestion peaks or low visibility spots) and applies local modifications such as shifting or rotating individual objects within small ranges. After each modification, the server recomputes local metrics and accepts changes that improve the composite score.

Additionally, the server enforces rule-based corrections, such as ensuring that emergency exits remain unobstructed and that a minimum clearance radius around cashier zones is kept free from obstacles.

Output: A refined layout data structure that satisfies constraints and improves evaluation metrics.

### Step 14:

The server generates display data for the refined layout and transmits it to the terminal.

Input: The refined layout data structure and context parameters such as floor dimensions and display preferences.

Processing: The server converts each layout item into rendering primitives, such as polygons, icons, and labels. The server constructs a display data object containing coordinates, shapes, colors, and textual labels for all objects and zones. The server serializes this display data and sends it to the terminal via the communication interface using an HTTP response or a similar protocol.

Output: Display data representing a two-dimensional or three-dimensional view of the spatial arrangement, delivered to the terminal.

### Step 15:

The terminal renders the display data and presents the layout to the user.

Input: The display data transmitted from the server in Step 14.

Processing: The terminal parses the display data, maps layout items to on-screen graphics, and uses a graphics library to draw floor plans, objects, and zones on the display device. The terminal supports user interaction such as pinch-to-zoom, panning, and object selection by mapping touch or pointer events to layout coordinates. The terminal also displays the user's original prompt sentence and may show key evaluation metrics such as average walking distance or visibility score.

Output: A visual representation of the layout on the terminal display and an interactive user interface ready to accept further user input.

### Step 16:

The user evaluates the displayed layout and provides feedback or an additional prompt sentence.

Input: The rendered layout on the terminal display and interactive controls.

Processing: The user visually inspects object placement, aisles, and open spaces, and decides whether the layout satisfies their requirements. The user may provide explicit evaluation (for example, a satisfaction rating), select problematic areas, or input a new or modified prompt sentence such as “Please reduce congestion near the entrance and keep promotional items easy to find,” or “Increase seating near the windows while maintaining wide aisles.” Output: User feedback data, including evaluation information and additional prompt sentences or manipulation operations, captured by the terminal.

### Step 17:

The terminal sends the user feedback data to the server for iterative refinement.

Input: The user feedback data from Step 16.

Processing: The terminal packages evaluation information, additional prompt sentences, and any direct layout manipulation data into a structured feedback payload. The terminal transmits this payload to the server using a network request similar to the initial request.

Output: A feedback message delivered to the server containing user evaluations and updated requirements.

### Step 18:

The server updates spatial arrangement conditions and evaluation weights based on user feedback.

Input: The feedback payload from Step 17 and the existing spatial arrangement conditions from Step 6.

Processing: The server interprets additional prompt sentences with the language analysis program, producing new symbolic features and numerical conditions. The server combines the original and new conditions, giving higher priority to elements indicated by user dissatisfaction or preference. The server adjusts weighting factors for evaluation indices, such as increasing the weight of congestion reduction if the user complained about crowding. The server updates the condition vector and feature weights used in evaluation and generation.

Output: Updated spatial arrangement conditions, updated condition vectors, and updated evaluation weights.

### Step 19:

The server logs interaction history and, optionally, updates model and evaluation parameters.

Input: The original and additional prompt sentences, spatial arrangement conditions, generated layouts, selected layouts, evaluation metrics, and user feedback.

Processing: The server writes these data to the storage device as history records linked by session identifiers and timestamps. In a training or adaptation mode, the server uses this history to adjust parameters of the generative AI model or the evaluation indices, for example by performing gradient-based updates on model weights using adopted layouts as targets, or by recalibrating evaluation weight coefficients to better match user-selected outcomes.

Output: Updated history records in storage and, when adaptation is enabled, updated model parameters and evaluation index parameters.

### Step 20:

The server and terminal repeat generation, evaluation, and presentation cycles until a final layout is accepted.

Input: The updated spatial arrangement conditions and evaluation weights from Step 18, and the user's indication of whether further refinement is needed.

Processing: If the user requests further refinement, the server returns to the generation and evaluation steps (Steps 8 through 14) using the updated conditions and weights, and the terminal repeats the display and interaction steps (Steps 15 through 17). This loop continues until the user indicates final acceptance of a layout.

Output: A final spatial arrangement plan accepted by the user and stored as a completed design in the server's storage.

It is also possible to incorporate an emotion engine for estimating the user's emotions. That is, the specific processing unit 290 may estimate the user's emotions using an emotion identification model 59, and perform specific processing based on the estimated emotions.

### Example 2

Description follows regarding a flow of the specific processing in an Example 2. The units of the system described below are implemented by the data processing device 12 and the smart device 14. The data processing device 12 is called a “server” and the smart device 14 is called a “terminal”

Conventional computer-implemented space planning systems primarily rely on fixed rule sets, template-based layout engines, or manual authoring tools executed on general-purpose processors. In such systems, a processor typically receives constraint parameters, executes a deterministic optimization routine or applies pre-defined patterns, and outputs a static proposal for a spatial arrangement. These approaches exhibit several technical limitations in terms of how the computing resources are utilized and how effectively the processor can generate, refine, and present layout proposals.

First, conventional systems are not configured to translate heterogeneous, interactive user requirements into machine-interpretable instructions that are optimized for generative models. User inputs are often accepted as form fields or simple parameter sets and are passed directly into a layout computation module. As a result, the processor cannot systematically convert high-level, natural language requirements into structured prompts suitable for a generative AI model. This leads to inefficient use of advanced generative infrastructures and restricts the quality and adaptability of the generated layouts.

Second, existing systems generally lack a processor-controlled feedback loop that iteratively refines a layout proposal in cooperation with a generative AI model. When a generated layout fails to meet user needs or omits certain functional elements, a conventional system typically requires a user to manually redefine constraints or start a new planning session. The processor is not configured to automatically detect missing or inconsistent elements in the generated content, nor to programmatically adjust subsequent requests to the generative engine. This absence of an automated, machine-driven refinement loop results in increased processing time, repeated computation, and suboptimal utilization of computational resources.

Third, conventional systems do not effectively bridge between unstructured generative output and structured, machine-usable representation suitable for visualization and further computational processing. Generative models often output free-form textual descriptions, yet traditional processors in layout systems are not designed to parse, segment, and convert such textual content into structured arrangement information containing explicit area units, functions, positional relationships, and passage arrangements. This deficiency makes it difficult to generate consistent two-dimensional or three-dimensional visual representation data and hinders downstream processing such as computational evaluation or modification of proposed layouts.

Fourth, many known systems do not provide integrated processing to evaluate generated layouts according to multiple technical criteria, such as space utilization efficiency, work efficiency, smoothness of information exchange, and environmental load. Even when some evaluation metrics are computed, the evaluation may not be tightly coupled in the processor's control flow with generative prompt construction and layout regeneration. As a consequence, the processor cannot operate a tightly integrated pipeline where analysis, generation, structuring, evaluation, visualization, and iterative refinement are coherently orchestrated to improve the behavior and performance of the overall computer system.

Accordingly, there is a need for an improved computer-implemented system in which a processor is specifically configured to: (i) acquire interactive requirement information and convert it into formatted information; (ii) construct optimized prompt sentences for a generative AI model; (iii) communicate with a generative AI model and obtain response information; (iv) transform the response information into structured arrangement information; (v) compute evaluation information for multiple technical criteria; (vi) generate visual representation data; and (vii) iteratively refine the layout proposal by automatically incorporating user feedback and detected deficiencies into updated prompt sentences. By configuring the processor in this manner, the computer system can more efficiently utilize both local and external computing resources, reduce redundant processing and manual intervention, and improve the technical quality and reliability of generated spatial arrangement proposals.

The specific processing by the specific processing unit 290 of the data processing device 12 in Example 2 is realized by the following means.

The present invention provides a server comprising a processor configured to acquire, in an interactive manner via a communication interface, requirement information relating to a spatial arrangement from a user terminal, convert the requirement information into formatted information, analyze the formatted information by using a natural language processing module to obtain an analysis result, construct, based on the analysis result, a prompt sentence suitable for input to a generative AI model, transmit the prompt sentence to the generative AI model operating on an external computing resource, acquire response information including a proposal relating to the spatial arrangement from the generative AI model, analyze the response information to convert the proposal relating to the spatial arrangement into structured arrangement information, generate evaluation information relating to space utilization efficiency, work efficiency, smoothness of information exchange, and environmental load based on the structured arrangement information, generate two-dimensional or three-dimensional visual representation data based on the structured arrangement information and the evaluation information, output the visual representation data to a display device associated with the user terminal, acquire feedback information from the user relating to the proposal for the spatial arrangement presented on the display device, integrate the feedback information into the requirement information to update the prompt sentence, and repeatedly execute regeneration processing of the proposal for the spatial arrangement by the generative AI model using the updated prompt sentence. This enables the server to implement a tightly integrated processing pipeline in which user requirements are automatically transformed into optimized prompt sentences, generative outputs are converted into structured and evaluable representations, and iterative refinement is performed under processor control, thereby improving the efficiency, robustness, and technical performance of computer-implemented spatial arrangement generation and visualization.

The term “system” refers to a combination of one or more computing devices and associated components that are configured to execute instructions to perform the functions described herein.

The term “processor” refers to one or more hardware processing units, such as a central processing unit or other instruction execution circuitry, configured to execute computer-readable instructions to implement the functions described herein.

The term “user” refers to a human operator or an entity that provides requirement information and feedback information relating to a spatial arrangement to the system.

The term “terminal device” refers to an electronic apparatus, such as a personal computer, tablet, or mobile device, configured to communicate with the server, provide an interface for user input, and present output information to the user.

The term “server” refers to a computing apparatus, typically including at least one processor, memory, and a communication interface, configured to execute server-side processing for acquiring, analyzing, generating, and outputting information relating to a spatial arrangement.

The term “communication interface” refers to hardware and software components that enable data exchange between the server and external devices or networks, including wired or wireless communication means.

The term “spatial arrangement” refers to an organization or layout of physical or logical areas within a space, including locations, sizes, functions, and relationships of individual areas or elements.

The term “requirement information” refers to data representing constraints, preferences, or conditions specified by the user regarding a spatial arrangement, including but not limited to capacity, functions, and environmental considerations.

The term “formatted information” refers to requirement information that has been converted into a structured or standardized representation that is suitable for subsequent computational processing.

The term “analysis result” refers to output data generated by a processing operation, such as natural language processing, applied to the formatted information, and representing extracted features, structures, or interpretations used for further processing.

The term “natural language processing” refers to a set of computational techniques that analyze, interpret, or transform text expressed in a natural language into a representation suitable for machine processing.

The term “prompt sentence” refers to a natural-language instruction or description generated by the processor for input to a generative AI model, the instruction or description being constructed to cause the generative AI model to produce a desired output related to a spatial arrangement.

The term “generative AI model” refers to a machine learning model configured to generate data, including text or other content, in response to an input such as a prompt sentence.

The term “external computing resource” refers to a computing environment separate from the server, such as a remote server or cloud computing platform, on which the generative AI model is executed.

The term “response information” refers to data returned by the generative AI model in response to a prompt sentence, the data including at least a proposal relating to a spatial arrangement.

The term “proposal” refers to content generated by the generative AI model that suggests one or more configurations, layouts, or arrangements of areas in a spatial arrangement.

The term “structured arrangement information” refers to a machine-readable representation of a spatial arrangement proposal in which areas, functions, positions, and relationships are expressed in a structured format such as records, fields, or hierarchical data.

The term “evaluation information” refers to computed data representing assessments or metrics of a spatial arrangement, including assessments relating to space utilization efficiency, work efficiency, smoothness of information exchange, and environmental load.

The term “space utilization efficiency” refers to an evaluation criterion indicating how effectively an available space is used in view of constraints such as capacity, accessibility, and functional allocation.

The term “work efficiency” refers to an evaluation criterion indicating how a spatial arrangement influences performance of tasks, including aspects such as ease of movement, adjacency of related functions, and reduction of unnecessary travel.

The term “smoothness of information exchange” refers to an evaluation criterion indicating how a spatial arrangement facilitates communication and information flow among users or groups.

The term “environmental load” refers to an evaluation criterion indicating an impact of a spatial arrangement on environmental factors, including but not limited to energy usage, natural light utilization, and resource consumption.

The term “two-dimensional visual representation data” refers to data describing a graphical representation of a spatial arrangement in a plane, including layout drawings, diagrams, or maps suitable for display.

The term “three-dimensional visual representation data” refers to data describing a graphical representation of a spatial arrangement in three dimensions, including models or scenes suitable for rendering from multiple viewpoints.

The term “display device” refers to an output apparatus, such as a monitor, screen, or projector, configured to present visual representation data to a user.

The term “feedback information” refers to data input by the user after reviewing a proposal for a spatial arrangement, the data indicating acceptance, rejection, modifications, or additional constraints.

The term “regeneration processing” refers to a sequence of operations in which an updated prompt sentence is supplied to the generative AI model to generate a revised proposal based on previously obtained information and feedback.

The term “area unit” refers to a portion or zone of a spatial arrangement that is treated as a distinct element for purposes of function assignment, positioning, and evaluation.

The term “area information” refers to structured data describing characteristics of an area unit, including at least a function, a positional relationship with other areas, and a passage arrangement.

The term “function” refers to a role or use assigned to an area unit, such as workspace, meeting area, circulation space, or storage area.

The term “positional relationship” refers to information indicating a relative location or adjacency between area units in a spatial arrangement.

The term “passage arrangement” refers to an organization of circulation paths or routes within a spatial arrangement that connect area units and allow movement of users.

The term “missing element” refers to an item, feature, or requirement that is required according to the requirement information or system configuration but is absent from the response information provided by the generative AI model.

The term “inconsistency” refers to a condition in which information within the response information or between the response information and the requirement information is logically incompatible, contradictory, or violates one or more constraints.

The term “constraint condition” refers to structured data representing a requirement, restriction, or rule that is added to a prompt sentence to influence the behavior of the generative AI model.

The term “re-inputting” refers to a process in which an updated or augmented prompt sentence is supplied again to the generative AI model to generate new response information.

In one embodiment, a server cooperates with one or more terminal devices operated by a user to implement the claimed system. The server includes at least one processor, a main memory, a non-volatile storage device, and a communication interface. The terminal includes at least one processor, a display device, an input device, a memory, and a communication interface. The server and the terminal are interconnected via a network such as the Internet. The server executes server-side software implemented, for example, on a general-purpose computing platform running an operating system such as a UNIX-based system or a commercial server operating system. The server executes an application framework, for example a web application framework, that provides an application programming interface (API) for communication with the terminal. The server further executes modules that implement a natural language processing engine, a prompt sentence generation engine, a generative AI interface engine, a layout structuring engine, an evaluation engine, a visualization engine, and a feedback integration engine.

The terminal executes client-side software such as a web browser or a native application. The terminal presents graphical user interface screens that allow the user to input requirement information relating to a spatial arrangement, such as desired capacity, required types of areas, adjacency preferences, circulation constraints, and environmental considerations. The terminal processes user operations received through an input device such as a keyboard, a pointing device, or a touch panel, and constructs data representing the requirement information. The terminal transmits the requirement information to the server via the communication interface using a predetermined communication protocol.

The server receives the requirement information and converts it into formatted information.

The server stores the formatted information in one or more data structures in memory, for example as records including fields for numerical parameters, categorical parameters, and textual descriptions. The server applies a natural language processing engine to any free-form text included in the requirement information. The natural language processing engine may include tokenization, part-of-speech tagging, phrase chunking, and dependency parsing, implemented using algorithms that map input text to token sequences, annotate each token with syntactic and semantic tags, and construct parse trees stored in tree-based data structures.

The server uses the results of the natural language processing engine to generate a prompt sentence suitable for input to a generative AI model. The server uses a prompt sentence generation engine that assembles a structured textual instruction by combining template fragments with values derived from the formatted information and analysis results. The server stores a library of template fragments in non-volatile storage. The server selects fragments and inserts specific parameter values such as numbers of persons, floor dimensions, area types, and priority criteria. In one example, the server constructs a prompt sentence as follows:
“You are a professional office space planner. Design an office layout for 30 employees on a 20 meter by 15 meter rectangular floor. Prioritize space utilization efficiency, work efficiency, and smooth information exchange. Provide: (1) an open workspace area for all employees, (2) 2 meeting rooms, (3) 1 central shared collaboration space, and (4) circulation paths that minimize walking distances. Consider low environmental impact by maximizing the use of natural light and avoiding unnecessary partitions. Describe each zone, its approximate location on the floor, and its adjacency to other zones. Present the result in clear, structured text.”

The server transmits the generated prompt sentence to a generative AI model executed on an external computing resource. The generative AI model is implemented as a neural network having multiple layers, such as an encoder-decoder transformer architecture including an embedding layer, a plurality of self-attention layers, feed-forward layers, and output layers that generate tokens. The generative AI model is trained in advance using supervised learning on large corpora of text data, including architectural descriptions, layout descriptions, and general language data.

The generative AI model uses the prompt sentence as input, represented as a sequence of tokens mapped to numerical vectors. The neural network processes the vectors through layers that perform attention-based weighting and non-linear transformations. The model computes a probability distribution over possible next tokens at each time step, and selects tokens according to a decoding strategy, such as greedy decoding or sampling based on temperature and top-k or nucleus parameters. The external computing resource includes hardware accelerators such as graphics processing units that perform matrix multiplications and other linear algebra operations required for the neural network computations.

The server receives response information from the generative AI model via the communication interface. The response information includes a text description of a spatial arrangement proposal. The server stores the response information in memory and applies a layout structuring engine that parses the free-form text into structured arrangement information. The layout structuring engine analyzes the text using rule-based segmentation, pattern matching, and semantic tagging. The server identifies sections such as “Zones,” “Adjacency,” and “Circulation,” and extracts descriptions of area units, their functions, and their relative positions. The server converts these descriptions into structured records, each record including fields for a zone name, a function, a positional relationship, an estimated capacity, and a passage arrangement attribute.

The server then applies an evaluation engine to the structured arrangement information. The evaluation engine computes evaluation information relating to space utilization efficiency, work efficiency, smoothness of information exchange, and environmental load. The server, for example, calculates a space utilization score by estimating the area allocated to each function and comparing it to recommended ranges stored in reference tables. The server calculates a work efficiency score by analyzing adjacency relationships, counting the number of direct connections between related areas, and estimating average path lengths along the passage arrangement between frequently used area pairs. The server calculates a smoothness of information exchange score by identifying positions of shared spaces and collaboration zones relative to work areas and evaluating their accessibility. The server calculates an environmental load score by modeling exposure to natural light, approximate travel distances, and the concentration of high-usage facilities.

The server stores the evaluation information together with the structured arrangement information. The server uses a visualization engine to generate two-dimensional or three-dimensional visual representation data. For two-dimensional representation, the server maps area units to coordinates and dimensions on a floor plane according to the positional relationships described in the structured arrangement information. The server generates vector graphics data that defines shapes, boundaries, and labels. For three-dimensional representation, the server extrudes the two-dimensional shapes along a vertical axis and generates a scene description including camera positions, lighting parameters, and material attributes. The server formats the visual representation data in a format suitable for rendering by the terminal, such as a scene graph or a set of drawing commands.

The terminal receives the visual representation data and renders the spatial arrangement proposal on the display device. The terminal displays the layout, overlays labels for each area unit, and provides interactive operations such as zooming and panning. The user observes the layout and reviews the arrangement of zones and circulation paths. The terminal transmits feedback information input by the user, such as a request to add another meeting room or to relocate a shared area, to the server.

The server integrates the feedback information into the existing requirement information. The server converts the feedback information into formatted information and updates the internal representation of requirements. The server then updates the prompt sentence by modifying or appending relevant constraints, such as “Increase the number of meeting rooms from 2 to 3 and ensure that at least one meeting room is located near the main entrance.” The server transmits the updated prompt sentence to the generative AI model and obtains a new response. By repeating this cycle under processor control, the server automatically refines the spatial arrangement proposal without requiring the user to manually reconstruct all constraints from the beginning.

The server in this embodiment is configured to reduce computational load and improve response time by maintaining structured arrangement information and evaluation information in memory and reusing them during iterative refinement. Rather than regenerating all calculations from scratch, the server compares new proposals with previously evaluated configurations, detects changes at the area-unit level, and incrementally updates evaluation information. This incremental update strategy reduces redundant computations and leads to a measurable improvement in processing efficiency.

The generative AI model used by the server is trained before deployment using a training dataset containing examples of spatial arrangement descriptions and associated structured annotations. The model is trained using a loss function such as cross-entropy between predicted tokens and ground-truth tokens. During training, the model updates its weights through gradient descent with an optimizer such as Adam, using backpropagation to propagate error gradients. Data augmentation methods may be used, such as paraphrasing training sentences, permuting order of constraints, and injecting synthetic constraint descriptions, to improve the model's robustness in handling diverse prompt sentences. The server may further employ a post-processing rule set that follows non-conventional patterns compared to manual design workflows. The server, for example, enforces minimum separation distances between incompatible area types, imposes capacity thresholds on circulation segments, and introduces bias terms into the evaluation function that penalize configurations exceeding certain environmental load thresholds. These rules are applied programmatically and affect both the evaluation engine and the way updated prompt sentences are constructed. Because these rules are directly integrated into the machine-controlled loop, the server achieves layout refinements that are not straightforwardly obtainable through conventional manual editing.

The server improves the technical functioning of the computer system in several ways. The use of a dedicated prompt sentence generation engine and a structured layout structuring engine reduces the size and ambiguity of data sent to and received from the external generative AI model, resulting in lower communication overhead and fewer iterations needed to reach an acceptable layout. The conversion of free-form generative output into structured arrangement information enables the server to perform efficient indexing and querying of layout elements, which improves retrieval speed when the server compares alternative layouts. The server, by implementing incremental evaluation updates and automated deficiency detection, reduces the number of full recomputations, thereby decreasing CPU and memory usage.

In one example, the server detects missing elements by comparing structured arrangement information against requirement information in a deterministic algorithm. The server constructs a list of required area types and counts from the requirement information and a corresponding list from the structured arrangement information. The server identifies discrepancies and generates a constraint condition string that explicitly specifies missing or inconsistent items. The server appends this constraint condition to the prompt sentence and resubmits it to the generative AI model. This automatic detection and correction mechanism reduces errors and leads to more accurate satisfaction of constraints, which is a technical effect beyond simply automating human layout drafting.

In another example, the server uses a variant of a transformer-based generative AI model that includes additional input channels for structured meta-constraints. The server encodes constraint vectors representing target scores for space utilization efficiency, work efficiency, and environmental load, and supplies these vectors along with the tokenized prompt sentence. The model uses learned projections to integrate the constraint vectors into its attention mechanism. As a result, the model internal computations are biased toward outputs that satisfy multi-objective criteria. This arrangement modifies the way the model performs matrix multiplications and attention weighting, thereby changing the behavior of the computing hardware and improving the quality and convergence speed of layout generation. The terminal may be implemented in multiple forms, such as a handheld device, a desktop computer, or a large-format interactive display for collaborative use. The server may support different visualization modes depending on the capabilities of the terminal. For a low-power terminal, the server may pre-render raster images or simplified vector graphics, thereby reducing rendering load on the terminal processor and minimizing network bandwidth usage. For a high-performance terminal, the server may transmit three-dimensional scene descriptions and allow the terminal to perform real-time rendering and interaction. By adapting the format of visual representation data, the server improves communication efficiency and load distribution across heterogeneous devices.

Alternative embodiments may vary the internal configuration of the server modules while still performing the claimed functions. In one variation, the server integrates the natural language processing engine and the prompt sentence generation engine into a single module that directly maps requirement information to prompt sentences using a rule-based grammar. In another variation, the server uses a separate, smaller neural network model to post-process the generative AI model's output into structured arrangement information, thereby offloading some parsing complexity to a learned model and reducing the amount of rule-based code. In another variation, the evaluation engine uses simulation-based metrics, such as pathfinding algorithms on a graph representing the passage arrangement, to compute travel distances and congestion points.

The user, in typical use, operates the terminal to specify spatial arrangement requirements, receives visualized proposals, and supplies feedback through simple operations. The server, by orchestrating the described components and data flows, enables the user to obtain high-quality, technically evaluated spatial arrangements without needing to understand the underlying computational processes. Nonetheless, the technical improvements reside in the server's internal processing: the transformation of heterogeneous inputs into optimized prompt sentences, the structuring and evaluation of generative outputs, and the automated iterative refinement controlled by explicit algorithms and data structures. These operations yield faster convergence to satisfactory layouts, more accurate satisfaction of complex constraints, and more efficient utilization of computing and communication resources, thereby constituting an improvement in computer technology rather than a mere automation of human design practices.

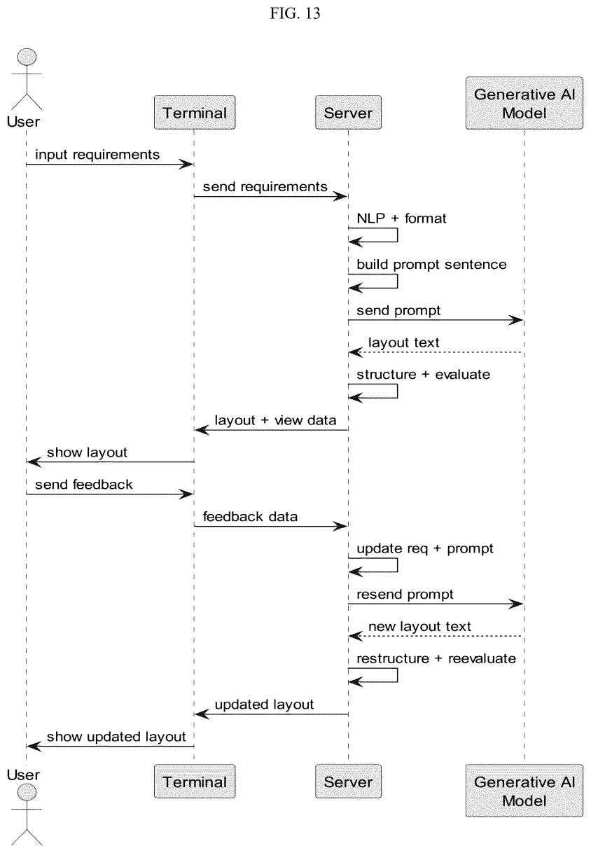

The following describes the processing flow using FIG. 13.

### Step 1:

The user operates the terminal to open an application and inputs requirement information relating to a spatial arrangement. The input includes, for example, the number of occupants, types of required areas, adjacency preferences, circulation requirements, and environmental constraints, entered via text fields, selection boxes, and sliders. The terminal receives this input as raw event data from an input device and converts it into an internal data object. As input, the terminal uses the sequence of user operations; as output, the terminal produces a structured requirement object containing key-value pairs representing each requirement item.

### Step 2:

The terminal validates the requirement object and prepares it for transmission. The terminal checks, for example, that numeric fields contain valid values, that mandatory items are present, and that selected options are consistent. If validation passes, the terminal serializes the requirement object into a formatted message, such as a JSON string, and attaches metadata such as a session identifier and timestamp. As input, the terminal uses the structured requirement object; as output, the terminal produces a formatted request message ready to be sent to the server.

### Step 3:

The terminal transmits the formatted request message to the server through a communication interface. The terminal opens a network connection, encapsulates the message in a communication protocol packet, and sends the packet toward a predetermined server endpoint. As input, the terminal uses the formatted request message; as output, the terminal produces a network transmission containing the requirement data and then waits for a response from the server.

### Step 4:

The server receives the formatted request message from the terminal. The server, via its communication interface, decodes the incoming packets, reconstructs the message payload, and parses the formatted data into an internal representation. As input, the server uses the received formatted request message; as output, the server produces a requirement information structure stored in memory, such as a set of records with fields corresponding to each requirement item.

### Step 5:

The server applies a natural language processing engine to free-form text elements contained in the requirement information structure. The server tokenizes sentences, assigns part-of-speech tags, identifies noun phrases and verbs, and builds dependency relations. The server uses algorithms such as rule-based tokenization and statistical tagging to transform each text field. As input, the server uses the raw text fields within the requirement information structure; as output, the server produces an analysis result that includes token lists, syntactic structures, and semantic labels associated with the requirement information.

### Step 6:

The server generates formatted information by integrating the analysis result with the original requirement items. The server maps extracted concepts (e.g., “central shared space,” “quiet zone,” “maximize natural light”) to standardized internal attributes and updates the requirement information structure accordingly. The server resolves synonyms, normalizes units, and infers missing parameters when possible. As input, the server uses the requirement information structure and the analysis result; as output, the server produces a refined, formatted information structure that is consistent and suitable for prompt construction.

### Step 7:

The server constructs a prompt sentence for a generative AI model. The server selects template fragments from a prompt library based on the formatted information and fills placeholder positions with actual parameter values, such as floor dimensions, number of areas, and evaluation priorities. The server concatenates the fragments into a coherent natural-language instruction. As input, the server uses the formatted information structure; as output, the server produces a complete prompt sentence text string that specifies the design task and constraints.

### Step 8:

The server logs and optionally optimizes the prompt sentence before transmission. The server may remove redundant phrases, reorder constraint descriptions to emphasize critical requirements, and append instructions about desired output structure, such as section headings and bullet lists. The server uses string processing algorithms to analyze length and structure and to adjust the text accordingly. As input, the server uses the initial prompt sentence; as output, the server produces an optimized prompt sentence tailored to the generative AI model.

### Step 9:

The server transmits the optimized prompt sentence to the generative AI model operating on an external computing resource. The server encapsulates the prompt sentence and model parameters (such as maximum token count and temperature) in a request payload and sends it via a network interface to the external resource. As input, the server uses the optimized prompt sentence and configuration parameters; as output, the server produces a network request that causes the external computing resource to execute the generative AI model with the specified prompt sentence.

### Step 10:

The generative AI model executed on the external computing resource processes the prompt sentence. The external resource tokenizes the prompt sentence, maps tokens to embedding vectors, and propagates the vectors through multiple neural network layers including self-attention and feed-forward blocks. The model computes probability distributions over output tokens and selects tokens step-by-step to form a response. As input, the external resource uses the tokenized prompt sentence and model parameters; as output, the external resource produces response information that includes a textual proposal for the spatial arrangement.

### Step 11:

The server receives the response information from the external computing resource. The server extracts the generated text from the response payload and stores it in memory. The server may record metadata such as generation time, used parameters, and model identifier. As input, the server uses the received response payload; as output, the server produces a raw layout proposal text string contained within the response information.

### Step 12:

The server structures the layout proposal using a layout structuring engine. The server scans the raw text for section markers (such as “Zones,” “Adjacency,” “Circulation”) and applies pattern matching and parsing rules to identify area units, their functions, capacity indications, and positional descriptions. The server creates structured records for each area unit, populating fields for name, function, relative position, and relationships to other areas. As input, the server uses the raw layout proposal text; as output, the server produces structured arrangement information represented as a collection of area-unit records and relationship data.

### Step 13:

The server evaluates the structured arrangement information using an evaluation engine. The server computes numerical metrics for space utilization efficiency by estimating area allocation and comparing it with reference ranges, work efficiency by calculating adjacency-based connectivity scores and approximate path lengths, smoothness of information exchange by measuring accessibility to shared areas, and environmental load by modeling expected travel distances and use of natural light. As input, the server uses the structured arrangement information and reference data stored in memory; as output, the server produces evaluation information that includes multiple evaluation scores and diagnostic indicators.

### Step 14:

The server generates visual representation data based on the structured arrangement information and the evaluation information. For two-dimensional layouts, the server assigns each area unit a position and size on a floor plane, consistent with relative position descriptions, and encodes this in vector shapes and text labels. For three-dimensional layouts, the server extrudes area units into volumes and defines camera views. The server overlays evaluation results by, for example, coloring zones according to efficiency scores. As input, the server uses the structured arrangement information and the evaluation information; as output, the server produces visual representation data suitable for rendering on the terminal.

### Step 15:

The server transmits the visual representation data and associated textual explanations to the terminal. The server assembles a response payload that includes the structured arrangement information, the evaluation information, and the visual representation data. The server sends this payload through the communication interface to the terminal. As input, the server uses the generated visual representation data and related information; as output, the server produces a response message that encapsulates all content required for user presentation.

### Step 16:

The terminal receives the response message from the server and decodes the contained data. The terminal parses structured records, extracts the visual representation data, and prepares rendering commands. The terminal may build an internal scene graph or layout model according to the received information. As input, the terminal uses the response message; as output, the terminal produces in-memory data structures representing the layout for display.

### Step 17:

The terminal renders the layout and evaluation results on the display device. The terminal draws shapes representing area units, applies labels and colors, and displays evaluation scores and textual descriptions alongside the graphical layout. The terminal may enable interaction, allowing the user to zoom, pan, or select specific zones for detailed information. As input, the terminal uses the in-memory layout representation and rendering parameters; as output, the terminal produces a visual output on the display device that presents the spatial arrangement proposal.

### Step 18:

The user reviews the displayed layout and evaluation results and determines whether modifications are desired. The user interacts with the terminal to provide feedback, such as adding new constraints, changing numerical parameters, or selecting zones to be altered. The terminal captures these actions as feedback information. As input, the user uses the visual output from the display and the current arrangement information; as output, the user produces revised requirements and feedback data through the input device.

### Step 19:

The terminal converts the user's feedback information into updated requirement data and sends it to the server. The terminal integrates the feedback with existing requirement identifiers, creates a differential representation if necessary (e.g., indicating changed items only), and serializes the updated requirements. As input, the terminal uses the feedback information received from the user and the previous requirement state; as output, the terminal produces an updated formatted request message that reflects the user's modifications.

### Step 20:

The server receives the updated request message and integrates it with the prior requirement and arrangement context. The server updates the formatted information structure to reflect the new constraints and preferences, recalculates any derived parameters that depend on changed values, and constructs a modified prompt sentence that incorporates explicit instructions about missing elements or adjustments. As input, the server uses the updated request message and the stored prior state; as output, the server produces a new prompt sentence and an updated internal state for the next iteration of layout generation by the generative AI model.

### Application Example 2

Description follows regarding a flow of the specific processing in an Application Example 2. The units of the system described below are implemented by the data processing device 12 and the smart device 14. The data processing device 12 is called a “server” and the smart device 14 is called a “terminal”.

Conventional space layout design systems largely operate as static configuration tools that rely on fixed rule sets or manual expert input. Such systems typically accept user requirements in a limited, form-based manner and generate candidate layouts using predetermined heuristics or simple optimization routines. As a result, they suffer from several technical problems when implemented on information processing apparatuses.

First, existing systems are not configured to automatically transform rich, unstructured natural language input, including spoken requirements, into machine-usable, structured layout constraints and optimized prompt sentences for a generative AI model. The lack of an integrated pipeline from speech and free-form text to structured constraints and model-ready prompts forces users or operators to perform intermediate translation and encoding tasks manually. This increases processing latency, burdens computing resources with repeated trial-and-error executions, and leads to inefficient utilization of computational components such as processors and memory.

Second, existing systems do not effectively incorporate emotion-related data derived from multimodal inputs such as text, voice, biological signals, and image information into the core layout computation. Emotion recognition, when present, is typically implemented as a separate analytics feature that does not directly constrain or guide the underlying layout generation algorithm. As a consequence, the system cannot dynamically adjust layout parameters, such as the placement density or location of rest regions, concentration regions, or collaboration regions, in response to real-time or time-aggregated emotional states of users and workers. This separation leads to suboptimal use of sensor data and computational models: the layout generation engine cannot leverage emotion signals as first-class optimization variables, and the system fails to converge efficiently toward layouts that reduce stress or improve comfort.

Third, known techniques do not provide an iterative, closed-loop control architecture between the generative AI model and a visualization-and-feedback module. In conventional systems, once a layout is generated, any user feedback is handled as an informal comment or as a complete restart of the design process, rather than as structured input to generate improved prompt sentences and refined model inputs. This lack of systematic feedback integration prevents the layout generation process from efficiently converging within fewer computational iterations, and causes redundant re-computation, higher processor load, and unnecessary network and storage operations.

Fourth, existing systems generally treat spatial layout validation and visualization as post-processing stages that are loosely coupled to the generative computation. Geometric checks, safety criteria, route constraints, and emotion-distribution-based refinements are often handled in separate tools or manual workflows, which are not integrated into a single processor-controlled pipeline. This results in fragmented processing, increased data format conversions, and repeated I/O operations between heterogeneous applications, which degrade overall system performance and stability.

Fifth, typical architectures do not maintain structured logs of prompt sentences, final layout plan data, emotion distribution data, and associated feedback in a form that can be efficiently used to retrain or fine-tune the underlying generative AI model and emotion recognition model. As a result, the system cannot systematically exploit historical interaction data to improve model performance and reduce future computation times. This leads to a stagnant model quality and prevents the computing system from adapting to the characteristics of real environments and user populations.

Accordingly, there is a need for an improved computing system architecture and processing method that (i) automatically converts interactive natural language and multimodal emotion inputs into structured spatial constraints and optimized prompt sentences for a generative AI model, (ii) tightly couples emotion recognition outputs with the core layout generation and numeric optimization logic, (iii) establishes a closed-loop, iterative pipeline between generative computation, geometric and safety validation, three-dimensional visualization, and user feedback, and (iv) stores and reuses prompt-level and layout-level history to enhance model training. Such a system should reduce redundant computation, improve the efficiency and accuracy of layout generation, and provide technically improved functioning of the computer system itself, rather than merely automating a mental design process.

The specific processing by the specific processing unit 290 of the data processing device 12 in Application Example 2 is realized by the following means.

The present invention provides a server comprising a processor configured to receive, in an interactive manner, spatial arrangement requirements from a user via natural language input including voice, to perform speech recognition and text-editing display processing to obtain text data, to analyze the text data using a natural language processing technique to generate structured data representing layout constraints and user priorities, to dynamically construct a prompt sentence for a generative AI model based on the structured data and past layout information, to acquire multimodal emotion-related data including text, voice, and image inputs from the user or workers, to compute emotion feature values using an emotion recognition model and integrate the emotion feature values into spatial arrangement conditions, to execute the generative AI model using the prompt sentence and the spatial arrangement conditions as inputs and thereby generate spatial arrangement plan data, to perform verification and numerical optimization on the spatial arrangement plan data with respect to geometric consistency, safety criteria, and route constraints in order to generate final spatial arrangement plan data, to generate three-dimensional scene data and visualization data from the final spatial arrangement plan data and transmit the visualization data to a terminal device, to acquire user operation and evaluation inputs with respect to the visually presented spatial arrangement plan and iteratively update the spatial arrangement conditions and re-execute the generative AI model based on the updated conditions, to temporally aggregate emotion data based on biological information and image information from workers to generate emotion distribution data per region and to generate an additional prompt sentence for partially modifying an existing spatial arrangement plan using the emotion distribution data, and to store the final spatial arrangement plan data, the prompt sentences, and the emotion distribution data and execute a learning-data generation process for training the generative AI model and the emotion recognition model based on stored results. This enables the computing system to automatically and efficiently transform unstructured user and sensor inputs into optimized, model-ready prompt sentences, to integrate emotion-derived constraints directly into the core generative and optimization pipeline, to reduce redundant recomputation by operating an iterative, closed-loop architecture between generation, validation, visualization, and feedback, and to improve the performance of the underlying models and the overall layout computation by leveraging accumulated prompt-level and layout-level history, thereby providing a concrete improvement in computer technology.

The term “processor” refers to a hardware or virtualized computation resource, such as a central processing unit or graphics processing unit, configured to execute program instructions that implement the functions of the system.

The term “user” refers to a human operator who interacts with the system by providing spatial arrangement requirements, feedback, and other inputs through an input device or terminal.

The term “worker” refers to a person who performs tasks in a physical environment subject to a spatial arrangement plan, and from whom emotion-related data such as biological information and image information may be collected.

The term “spatial arrangement” refers to a configuration of physical regions and objects within a target environment, including types, positions, dimensions, and attributes of such regions and objects.

The term “spatial arrangement plan” refers to structured data describing a proposed spatial arrangement, including information about region types, locations, sizes, and functional attributes.

The term “spatial arrangement plan data” refers to machine-readable data representing a spatial arrangement plan, including but not limited to coordinates, dimensions, classifications, and metadata of regions and objects.

The term “final spatial arrangement plan data” refers to spatial arrangement plan data that has been subjected to verification and numerical optimization with respect to geometric consistency, safety criteria, and route constraints.

The term “spatial arrangement conditions” refers to a collection of constraints, priorities, and parameters, derived from user requirements and emotion feature values, that govern the generation and optimization of a spatial arrangement plan.

The term “natural language input” refers to information expressed in a human language, including spoken or typed sentences, phrases, or words, that describe requirements or feedback regarding a spatial arrangement.

The term “text data” refers to a representation of natural language input in a character-based digital format suitable for processing by a computing apparatus.

The term “speech recognition process” refers to a computational process that converts an audio signal representing human speech into corresponding text data.

The term “display process for text editing” refers to a process in which a computing apparatus presents text data on a display and enables a user to edit, confirm, or correct the text data through an input device.

The term “natural language processing technique” refers to a computational technique for analyzing and processing natural language text, including operations such as tokenization, syntactic analysis, semantic analysis, and keyword extraction.

The term “structured data” refers to data organized in a machine-interpretable schema, such as key-value pairs, records, or objects, that represent extracted layout constraints, user priorities, and other parameters.

The term “layout constraints” refers to conditions or limitations applied to a spatial arrangement, including but not limited to floor area, number of workers, required functional regions, environmental conditions, and placement rules.

The term “user priorities” refers to preference values specified or inferred for a user regarding aspects of a spatial arrangement, such as emphasis on concentration, collaboration, environmental performance, or comfort.

The term “prompt sentence” refers to a textual instruction or query, constructed for input to a generative AI model, that encodes structured data, constraints, and objectives for generating or updating a spatial arrangement plan.

The term “additional prompt sentence” refers to a prompt sentence generated in view of emotion distribution data or feedback, and used to partially modify or refine an existing spatial arrangement plan.

The term “generative AI model” refers to a machine learning model, such as a generative neural network or language model, that produces data representing a spatial arrangement plan in response to a prompt sentence and associated conditions.

The term “past spatial arrangement information” refers to stored data describing prior spatial arrangement plans, associated constraints, and outcomes, which may be used as reference information when generating a new prompt sentence or plan.

The term “emotion-related data” refers to data indicative of an emotional state of a user or worker, including but not limited to text input, voice input, biological information, and image information.

The term “biological information” refers to physiological data acquired from a user or worker, such as heart rate, skin conductance, or other measurable bodily signals.

The term “image information” refers to visual data, such as still images or video frames, acquired from an imaging device and including depictions of a user or worker.

The term “emotion recognition model” refers to a computational model configured to infer emotion feature values or emotion states from emotion-related data, including text, audio, and visual inputs.

The term “emotion feature values” refers to numerical or categorical indicators representing aspects of an emotional state, such as stress, fatigue, activity, or environmental orientation.

The term “emotion state” refers to a classification or description of a mental or affective condition of a user or worker, such as stressed, relaxed, fatigued, or active, derived from emotion-related data.

The term “emotion data” refers to processed or raw data indicating or supporting inference of an emotion state, including feature vectors, labels, and time-series measurements.

The term “emotion distribution data” refers to data representing emotion states or emotion intensity values aggregated over time and space, and associated with respective regions within a spatial arrangement.

The term “space utilization efficiency” refers to an evaluation index indicating how effectively available space is used in a spatial arrangement, considering factors such as occupancy, circulation, and functional allocation.

The term “work efficiency” refers to an evaluation index indicating effectiveness and productivity of work activities supported by a spatial arrangement, including factors such as travel distance, task completion time, and accessibility.

The term “facilitation of information exchange” refers to a property of a spatial arrangement that supports communication and collaboration among workers, such as visibility, proximity, and accessibility of collaboration regions.

The term “environmental load” refers to an evaluation index indicating environmental impact associated with a spatial arrangement, including energy use, natural light utilization, and material-related factors.

The term “verification process” refers to a computational process that checks spatial arrangement plan data for compliance with predefined rules, including geometric consistency, safety criteria, and route constraints.

The term “geometric consistency” refers to a property of a spatial arrangement in which regions and objects do not violate geometric rules, such as non-overlap, proper adjacency, and valid dimensions.

The term “safety criteria” refers to rules or conditions relating to safety, such as minimum clearances, access to exits, and separation from hazardous areas, that a spatial arrangement must satisfy.

The term “route constraints” refers to conditions regarding paths or circulation routes in a spatial arrangement, including minimum corridor widths, connectivity, and avoidance of obstructions.

The term “numerical optimization process” refers to a computational process that modifies variables of spatial arrangement plan data to improve one or more evaluation indices subject to constraints, using mathematical optimization techniques.

The term “evaluation indices” refers to quantitative measures used to assess a spatial arrangement plan, including but not limited to path length, congestion, safety, work efficiency, and environmental load.

The term “three-dimensional modeling technique” refers to a computational technique for generating three-dimensional scene data that represent geometric and visual properties of a spatial arrangement.

The term “three-dimensional scene data” refers to data structures defining a three-dimensional representation of a spatial arrangement, including information about objects, positions, orientations, and visual attributes.

The term “visualization data” refers to data suitable for rendering a spatial arrangement on a display device, including two-dimensional and three-dimensional representations, textures, and rendering parameters.

The term “terminal device” refers to an information processing apparatus, such as a personal computer, tablet, or smartphone, configured to present visualization data and to acquire user inputs.

The term “operation input” refers to input data representing user manipulations of a user interface, such as selection, dragging, zooming, or rotation of objects in a visualized spatial arrangement.

The term “evaluation input” refers to input data representing a user's assessment or preference regarding a spatial arrangement plan, including ratings, textual comments, or modification requests.

The term “layout modification” refers to a change applied to a spatial arrangement plan, including movement, addition, deletion, or resizing of regions or objects.

The term “learning-data generation process” refers to a process of constructing datasets from stored plan data, prompt sentences, emotion data, and related information, for use in training or fine-tuning a generative AI model or emotion recognition model.

The term “history information” refers to accumulated records of interactions with the system, including user requirements, prompt sentences, model outputs, feedback, emotion distribution data, and approved layout plans.

The term “multi-stage prompt sentence” refers to a prompt sentence that includes multiple segments or levels of instruction, such as descriptive statements of evaluation indices and conditional statements for updating a spatial arrangement plan.

The term “descriptive statement” refers to a portion of a prompt sentence that explicitly describes objectives, evaluation indices, or context for a spatial arrangement plan.

The term “conditional statement” refers to a portion of a prompt sentence that specifies conditions or rules for modifying or generating a spatial arrangement plan.

The term “storage results” refers to records persisted in a storage medium, including final spatial arrangement plan data, prompt sentences, emotion distribution data, and associated metadata, used for subsequent processing or learning.

In one embodiment, a server, a terminal, and one or more sensors cooperate to implement the claimed system. The server includes at least one processor, a memory storing programs and data structures, a communication interface, and a storage device. The terminal includes an input/output interface, a display, and optionally a microphone and a camera. The sensors include imaging devices and physiological sensors disposed in a workspace used by workers.

The server executes an operating system, an application framework, a natural language processing library, a numerical computation library, and a machine learning framework. For example, the server executes a general-purpose operating system, a language runtime such as a Python runtime, a natural language processing toolkit such as a tokenization and parsing library, a numerical computation library such as a vector and matrix computation library, and a machine learning framework such as a tensor-based deep learning library. The server also executes a three-dimensional scene generation engine, which may be implemented by a three-dimensional modeling tool or a real-time rendering engine, in a batch or headless mode.

The terminal executes a web browser or a native application that presents a graphical user interface to the user. The terminal may call a speech-to-text service to convert an audio signal captured by the microphone into text. The terminal may execute an image capture module that streams frames from the camera to the server.

In one embodiment, the server stores program modules in the memory, including a natural language understanding module, a prompt sentence generator, a generative AI model interface, a layout optimizer, a three-dimensional scene generator, an emotion recognition interface, an emotion aggregation module, a feedback processor, and a learning data generator. The server stores data structures including user profile data, project-level spatial arrangement conditions, structured layout constraints, emotion feature values, spatial arrangement plan data, emotion distribution data, and history information linking prompt sentences with generated layouts and feedback.

In one embodiment, the server analyzes natural language requirements from the user using a sequence of concrete operations. The server receives text data from the terminal and converts the text into tokens using a tokenizer. The server constructs a sequence of token identifiers and feeds the sequence into a syntactic parser implemented using a recurrent neural network or a transformer-based encoder. The server extracts key phrases denoting floor area, number of workers, required functional regions, environmental conditions, and user priorities by applying a named entity recognizer trained on layout-related corpora. The output of the natural language understanding module is a structured data object, for example a map or record in the memory, that includes fields such as:
floor area: a numeric value representing square meters,
worker_count: a numeric value,
region_types: a list of region category identifiers,
environmental constraints: a list of constraints associated with energy use or natural light,
priority_weights: a vector of weights for focus, collaboration, environmental performance, and comfort.

The server generates a prompt sentence for a generative AI model based on this structured data and stored past spatial arrangement information. The server executes a prompt sentence generator that maps the structured data to a natural language description according to a predefined template and a rule set. The server selects phrases and sentence structures to explicitly indicate evaluation indices and constraints to the generative AI model. For example, the server may generate a prompt sentence such as:

“Based on the following conditions, generate an optimal office layout: floor size 300 square meters, 25 workers, two meeting rooms, one quiet concentration area, and one collaboration area. Prioritize concentration and stress reduction, while providing sufficient collaboration areas. Minimize total walking distance and avoid narrow corridors. Output the layout as structured data with positions, dimensions, and functions of all regions, and provide an explanation of how stress reduction and collaboration are balanced.”

By explicitly encoding evaluation indices and constraints in the prompt sentence, the server ensures that the generative AI model receives a precise and machine-usable problem specification. This reduces the need for repeated trial-and-error calls from the terminal and improves the efficiency of model execution on the server hardware.

In one embodiment, the server computes emotion feature values from multimodal inputs. The server receives biological information such as heart rate series from wearable devices and image information such as face images from cameras. The server executes a convolutional neural network configured for facial emotion recognition, where the network includes a plurality of convolutional layers, pooling layers, and fully connected layers trained to output a probability vector over emotion classes such as “stressed,” “relaxed,” “fatigued,” and “active.” The server similarly executes a time-series classifier on heart rate data, implemented as a recurrent neural network or a temporal convolutional network, to detect elevated stress patterns. The server converts these outputs into normalized emotion feature values, such as a stress_score, fatigue_score, and activity_score in the range of 0 to 1.

The server also derives an environmental orientation score by applying a sentiment classifier to the user's textual comments, where the classifier is implemented as a neural network receiving sentence embeddings derived by a transformer encoder. The server stores these emotion feature values in association with the structured layout constraints. In contrast to simple tagging, the server uses these features as direct inputs to the layout generation pipeline: the emotion feature values determine weight vectors in the objective function of the layout optimizer and modify constraint sets for placement of rest regions and collaboration regions.

In one embodiment, the server integrates emotion distribution data with spatial arrangement plan data. The emotion aggregation module receives per-worker emotion feature values and associates each measurement with a spatial region identifier encoded in the spatial arrangement plan data. The server maintains a two-dimensional grid or graph structure in memory where each node corresponds to a physical region, and each node stores aggregated emotion statistics such as mean stress_score over a time window, standard deviation, and event counts for threshold exceedance. The server normalizes these statistics to create an emotion heat map across the workspace. The server then generates an additional prompt sentence that describes this emotion heat map in natural language, for example: “Given the current factory layout, stress levels are high in the assembly area near the northeast corner and moderate in the packaging area near the south side. Reduce stress in the high-stress regions by repositioning noisy machines and by adding rest areas within 10 meters of the affected workstations, while maintaining production throughput and preserving safety clearances.”

The server uses this additional prompt sentence as input to the generative AI model to compute an updated spatial arrangement plan. By leveraging emotion distribution data encoded in a structured grid or graph, the server performs a non-conventional refinement based on time-aggregated sensor data, rather than a simple rule-based reconfiguration. In one embodiment, the server interfaces with a generative AI model implemented as a transformer-based neural network hosted on a graphics processing unit. The generative AI model includes a multi-layer self-attention architecture with positional encodings, multi-head attention modules, feed-forward layers, and layer normalization, configured to process a token sequence representing the prompt sentence and optional serialized layout data. The server maps the structured constraints to a token sequence, appends them to the textual prompt, and performs embedding lookup before passing them into the transformer. The model outputs tokens representing serialized spatial arrangement plan data and a textual explanation. The server decodes the serialized plan into a structured data object in memory. The server trains or fine-tunes the generative AI model using supervised learning and reinforcement-style adjustments. In supervised learning, the server uses previously approved layouts and their associated prompt sentences as training samples. The server defines a loss function combining a token-level cross-entropy component and a layout-level consistency penalty that measures differences between generated and approved coordinates and attributes. The server updates model parameters using a gradient-based optimizer such as stochastic gradient descent or an adaptive variant. The server may augment data by perturbing coordinates or modifying prompt wording to improve robustness and generalization.

By structuring the internal data and by aligning the training loss with geometric and safety consistency, the server causes the generative AI model to prefer layouts that reduce invalid configurations and minimize the number of failed post-processing checks. This reduces the average number of calls from the layout optimizer and shortens end-to-end processing time. In one embodiment, the server executes a layout optimizer that operates on the spatial arrangement plan data produced by the generative AI model. The server represents the layout as a set of objects in a two- or three-dimensional coordinate space, with each object having position, orientation, and size attributes. The server formulates an optimization problem where decision variables represent small displacements and resizing factors. The server defines an objective function that is a weighted sum of path length, congestion, region adjacency preferences, and stress-related penalties derived from emotion distribution data. The server enforces linear or non-linear constraints to represent non-overlap, minimum corridor widths, and safety distance from hazardous regions.

The server uses an optimization library to solve this problem, applying an interior-point method or a gradient-based solver, depending on the convexity of the objective and constraints. The server performs incremental optimization starting from the generative AI output, rather than from scratch, thereby reducing computation and avoiding large, unstable modifications. The server writes the optimized positions back into the spatial arrangement plan data and records the resulting objective and constraint violation metrics. Because the generative AI model is trained to approximate feasible solutions, the optimization phase typically converges in fewer iterations and with lower processor utilization, improving overall throughput.

In one embodiment, the server generates three-dimensional scene data using a three-dimensional modeling engine. The server maintains a mapping from logical region types (for example, “desk area,” “machine area,” “meeting room,” “rest area”) to three-dimensional asset identifiers. The server invokes a scripting interface of the engine to instantiate corresponding models at positions specified in the final spatial arrangement plan data. The server assigns materials and lighting parameters by reading environmental attributes from the plan data, such as “use natural light” or “use sound-absorbing materials.” The server then exports a three-dimensional scene file or a set of renderable assets for consumption by the terminal. The use of consistent mappings and direct script-based generation avoids manual conversions between design tools and reduces I/O overhead.

The terminal loads the three-dimensional scene data and renders the scene using a graphics API. The terminal allows the user to manipulate camera viewpoints and to select objects to view metadata such as dimensions or function labels. The user may drag regions or objects to suggest modifications. The terminal encodes these changes into delta records, which are sent back to the server, rather than resending entire layout plans. This delta-based communication reduces network load and makes the iterative refinement more responsive.

In one embodiment, the server records all prompt sentences, structured constraints, emotion feature values, spatial arrangement plan data, emotion distribution data, and approved layouts into a persistent storage. The learning data generator constructs training datasets by pairing prompt sentences with final layouts and by attaching context variables such as user priorities and aggregated emotion states. The server periodically retrains or fine-tunes the generative AI model and the emotion recognition model using these datasets. The server uses mini-batch gradient training and defines error functions that penalize misalignment with approved layouts and misclassification of emotion states. Because the server constrains training data to those plans that have passed geometric and safety validation, the models learn to avoid invalid configurations, thus reducing the need for repeated verification in subsequent runs. In one embodiment, the system improves computer technology in several ways. First, the use of structured constraints and explicitly encoded evaluation indices in prompt sentences reduces the search space of the generative AI model and leads to faster convergence during inference, lowering GPU computation time per layout. Second, the tight integration of emotion feature values and emotion distribution data into the objective and constraints of the layout optimizer leads to more accurate and stable layouts, decreasing the number of re-runs required to satisfy safety and comfort requirements. Third, the delta-based update of layouts and the reuse of history information reduce communication overhead between the server and the terminal and reduce the volume of data that has to be processed by the generative AI model. Fourth, the alignment of training objectives with validation outcomes enables the generative AI model to produce layouts with fewer geometric and safety violations, thereby minimizing costly post-processing and manual correction.

In another embodiment, the server uses alternative neural network architectures. For example, the emotion recognition model may be implemented as a hybrid model that combines a convolutional neural network for image input with a transformer encoder for text input, and a feature fusion layer that concatenates the resulting embeddings. The generative AI model may be implemented as a sequence-to-graph model that produces a graph representation of the layout, where nodes represent regions and edges represent adjacency relationships. The layout optimizer may then operate directly on this graph using graph algorithms, such as shortest path computation and community detection, to adjust adjacency and cluster regions with similar emotion profiles.

In another embodiment, the server executes the generative AI model on a dedicated accelerator such as a tensor processing unit, while natural language processing and optimization are executed on general-purpose CPUs. The server schedules workloads across processors to minimize idle time and memory contention. The server can pipeline natural language processing for a new request while layout optimization for a previous request is running, thus improving latency and throughput.

In another embodiment, the server adjusts learning rates, sampling temperatures, and prompt templates dynamically in response to system-level metrics such as average convergence iterations, model error rates, and user satisfaction scores. The server stores these hyperparameters in configuration records and updates them based on measured technical performance. This closed-loop tuning of model and system parameters further improves computational efficiency and robustness.

In yet another embodiment, the server controls physical devices in the workspace based on the approved spatial arrangement plan data. For example, the server can transmit updated location coordinates to automated guided vehicles or mobile robots that move furniture or equipment into new positions. The server can send configuration commands to lighting and HVAC controllers to adjust lighting patterns and temperature in regions designated as rest or concentration areas. In this way, the spatial arrangement plan computed by the generative AI model and optimization modules is directly used to configure and control physical equipment, providing a concrete link between the computer-executed processing and real-world device control.

Through these embodiments, the server, the terminal, and the sensors cooperate to realize a system in which generative AI models and prompt sentences are used in a specific, technically constrained manner. The system does not merely automate human planning; instead, it uses non-conventional internal representations, specialized optimization routines, and model training methods that are tailored to spatial layout generation and emotion-aware refinement. The described data structures, processing flows, and model architectures improve processing speed, accuracy, and resource utilization of the underlying computer system, and thereby enable reliable and efficient deployment of optimized spatial arrangements in real environments.

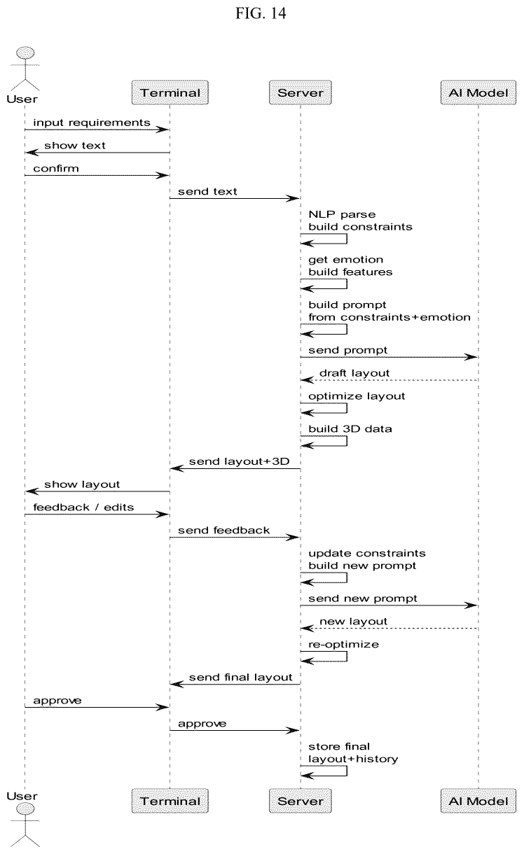

The following describes the processing flow using FIG. 14

### Step 1:

The user operates the terminal and inputs requirements for a spatial arrangement.

The user launches an application on the terminal, such as a web browser or a native app, and enters requirements in natural language, including floor area, number of workers, required regions, environmental preferences, and priorities (for example, “I need a 300 square meter office for 25 workers with two meeting rooms and one quiet area, and I want to reduce stress and noise”).

The user may provide the requirements via keyboard or voice. When the user speaks, the terminal captures an audio signal from a microphone and sends the audio to a speech-to-text service.

Input: raw user input (keystrokes or audio signal).

Output: text data representing the natural language requirements displayed on the terminal screen for confirmation.

The terminal performs a speech recognition process on the audio, converts the audio into text, and then displays the resulting text to the user for correction. After the user confirms, the terminal packages the text, user identifier, and project identifier into a structured message.

### Step 2:

The terminal transmits the confirmed requirements and optional sensor streams to the server. The terminal sends the confirmed text data, together with context information such as user ID and project ID, to the server via a secure communication protocol.

If the user has permitted video or physiological data collection, the terminal also starts streaming camera frames and biological sensor readings to the server at configured intervals.

Input: confirmed text data and optional video frames and sensor measurements from the user environment.

Output: network messages containing text requirements and multimodal raw data transmitted to the server.

The terminal encapsulates the data into message objects or JSON payloads and uses an HTTP or streaming interface to deliver the messages to the server's communication module.

### Step 3:

The server performs natural language preprocessing and structured constraint extraction. The server receives the text data and executes a natural language processing module that tokenizes the sentences, normalizes case, and removes extraneous punctuation.

The server applies a syntactic parser and a named entity recognizer to identify quantities (for example, “300 square meters,” “25 workers”), region types (for example, “meeting room,” “quiet area”), and modifiers (for example, “reduce stress,” “reduce noise,” “eco-friendly”).

Input: text data containing user requirements.

Output: structured data representing layout constraints and user priorities (for example, floor area, worker count, region types, environmental constraints, priority weights).

The server converts the parsed information into a structured record or object, assigning each extracted element to a specific field. The server may compute default values when a field is not explicitly specified, and records these defaults in the structured data.

### Step 4:

The server computes emotion feature values from multimodal emotion-related data.

The server receives biological signals (such as heart rate streams) and image information (face images or frames) from the terminal or from separate sensors.

The server processes the images using a convolutional neural network that outputs probabilities for emotion categories like stressed, relaxed, fatigued, and active.

The server processes heart rate sequences using a temporal model, such as a recurrent or temporal convolutional network, to detect elevated stress or fatigue patterns.

The server also runs a sentiment classifier on the user's text comments to infer environmental orientation or preference for calm versus active spaces.

Input: raw biological signals, image frames, and user text comments.

Output: emotion feature values, such as stress score, fatigue score, activity score, and eco orientation score, stored in association with the structured layout constraints.

The server normalizes the raw model outputs into fixed ranges (for example, 0 to 1), aggregates multiple measurements over a short time window, and stores the resulting feature vector in a data structure that will be used to condition subsequent layout generation.

### Step 5:

The server aggregates emotion data into region-based emotion distribution data.

The server associates each emotion measurement with a spatial region identifier or coordinate based on the location of workers or sensors.

The server maintains a grid or graph in memory where each node corresponds to a region of the workspace. For each node, the server accumulates emotion feature values over time and computes statistics such as mean and variance of stress score and fatigue score.

Input: timestamped emotion feature values and corresponding region identifiers.

Output: emotion distribution data, representing aggregated emotion statistics per region (for example, a stress heat map across the workspace).

The server updates the grid or graph structure incrementally whenever new emotion measurements arrive, recomputing summary statistics and storing the updated emotion distribution data in memory or persistent storage.

### Step 6:

The server generates a primary prompt sentence for the generative AI model.

The server takes the structured layout constraints and user priorities, and constructs a natural language instruction describing the layout problem.

The server inserts explicit values for floor area, worker count, required regions, and priority weights into a prompt template, and includes evaluation indices such as minimizing walking distance or reducing stress.

Input: structured data representing layout constraints and user priorities.

Output: a primary prompt sentence in natural language describing the layout task and requested output format.

The server formats the prompt sentence, for example: “Based on the following conditions, generate an optimal office layout: floor size 300 square meters, 25 workers, two meeting rooms, one quiet concentration area, and one collaboration zone. Prioritize stress reduction and quiet work, minimize walking distance, and keep corridors at least 1.5 meters wide. Output structured positions, dimensions, and functions for all regions, and explain your design choices.”

### Step 7:

The server generates an additional prompt sentence based on emotion distribution data.

The server converts the region-based emotion statistics into descriptive language indicating high-stress or low-comfort areas.

The server appends or prepends this description to the primary prompt sentence, instructing the generative AI model to adjust or refine the layout based on the detected emotion patterns.

Input: emotion distribution data and the primary prompt sentence.

Output: a combined or additional prompt sentence describing both layout constraints and current emotion patterns (for example, high-stress zones that require mitigation).

The server may produce text such as: “Currently, stress levels are high in the assembly area in the northeast and moderate in the packaging area in the south. Adjust the layout to reduce stress in those regions by repositioning noisy equipment and adding rest areas within 10 meters of affected workstations, while preserving production capacity and safety clearances.”

### Step 8:

The server encodes the prompt sentences and structured constraints for the generative AI model.

The server concatenates the primary prompt sentence, the additional emotion-based prompt sentence, and optionally a serialized representation of the current or previous layout into a single sequence.

The server tokenizes the sequence into tokens recognized by the generative AI model, converts tokens into numerical IDs, and creates corresponding embeddings.

Input: text prompt sentences, structured constraints, and optional serialized layout data.

Output: a sequence of embedded vectors and model-ready inputs for the generative AI model.

The server organizes the embeddings into a tensor of shape suitable for the transformer-based generative AI model, and stores attention masks or segment identifiers as additional tensors.

### Step 9:

The server invokes the generative AI model to generate a draft spatial arrangement plan.

The server forwards the prepared tensors to the generative AI model running on an accelerator, such as a GPU.

The generative AI model performs forward inference through its layers, computing self-attention, feed-forward transformations, and output logits over tokens.

The server decodes the generated output tokens into a serialized spatial arrangement plan and a textual explanation.

Input: embedded prompt vectors, model parameters, and attention masks.

Output: draft spatial arrangement plan data in serialized form and an optional explanation string.

The server parses the serialized plan into a structured data object containing region types, positions, sizes, and attributes, and stores this plan data as a draft layout in memory.

### Step 10:

The server refines the draft plan using geometric, safety, and route-based optimization.

The server converts the draft plan into a set of decision variables, such as coordinates and dimensions for each region.

The server formulates an objective function that combines walking distance, congestion, adjacency preferences, and penalties derived from emotion feature values and emotion distribution data.

The server defines constraints representing non-overlap, minimum corridor width, minimum distance to hazardous areas, and required adjacency relationships between certain region types.

Input: draft spatial arrangement plan data, emotion feature values, emotion distribution data, and system constraints.

Output: final spatial arrangement plan data with adjusted positions and dimensions that satisfy constraints and improve objective values.

The server runs an optimization solver to iteratively adjust the decision variables, computing gradients or search directions, and updating variables until convergence criteria are met. The server writes the optimized positions and dimensions back into the plan data and computes final evaluation metrics for logging.

### Step 11:

The server generates three-dimensional scene data and visualization assets from the final plan.

The server maps each region type in the final plan to a corresponding three-dimensional asset, such as a desk model, wall element, machine, or seating area.

The server uses a three-dimensional engine's scripting interface to instantiate these assets at coordinates specified in the final plan, setting orientation, scale, materials, and lighting based on environmental attributes.

Input: final spatial arrangement plan data and asset mappings.

Output: three-dimensional scene data and derived visualization assets (for example, scene files or renderable models) suitable for display on the terminal.

The server exports the scene or renders images from multiple viewpoints, and packages these assets together with the final plan data and textual explanation in a response for the terminal.

### Step 12:

The terminal receives and displays the visualization and plan information.

The terminal downloads or receives the visualization assets and final plan data from the server over a network connection.

The terminal loads the three-dimensional scene into a viewer module and renders the scene on a display.

Input: visualization assets and final spatial arrangement plan data.

Output: an interactive display showing the spatial arrangement, along with metadata such as room sizes, functions, and evaluation metrics, visible to the user.

The terminal allows the user to rotate and zoom the camera, switch between a two-dimensional floor plan and a three-dimensional view, and select regions or objects to reveal detailed attributes.

### Step 13:

The user evaluates the displayed layout and inputs feedback or manual modifications.

The user observes the rendered layout and the accompanying explanation and determines whether the plan meets their requirements.

The user interacts with the user interface by rating the layout, entering comments (for example, “Move the meeting rooms farther from the open space” or “Add more plants near the windows”), or directly dragging elements to new positions.

Input: visualized layout and metadata presented on the terminal.

Output: feedback data including ratings, text comments, and delta changes to object positions and attributes.

The terminal encodes the user's feedback and modifications into a structured format and sends them back to the server.

### Step 14:

The server processes user feedback and updates spatial arrangement conditions.

The server receives the ratings, comments, and delta layout changes from the terminal.

The server applies natural language processing to the comments to detect new or revised constraints (for example, increased distance between noisy and quiet regions, or additional green areas near windows).

Input: structured feedback data and modified layout elements.

Output: updated spatial arrangement conditions and modified structured constraints reflecting the user's latest preferences.

The server merges the new constraints and modifications into the existing structured data object, adjusts priority weights if the comments indicate changed emphasis (for example, more importance on collaboration or relaxation), and stores an updated version of the spatial arrangement conditions in memory.

### Step 15:

The server constructs a new prompt sentence for iterative refinement.

The server creates a new prompt sentence that references the current layout state and explicitly incorporates the user's feedback and modified constraints.

The server may include information such as “keep the desk count constant,” “relocate meeting rooms farther from open space,” and “introduce additional plants near windows.” Input: updated spatial arrangement conditions, delta layout changes, and history of previous prompt sentences and outputs.

Output: a refined prompt sentence instructing the generative AI model to generate an improved layout starting from the current configuration.

The server optionally includes details about shortcomings of the previous layout and the desired changes, thereby instructing the model to produce a variation that addresses specific issues without redesigning the entire space.

### Step 16:

The server iteratively repeats generative and optimization steps until convergence or approval.

The server passes the refined prompt sentence and updated constraints to the generative AI model as in earlier steps, obtains an updated layout, and performs optimization and validation again.

The server compares new evaluation metrics with previous ones and checks whether improvement thresholds or convergence criteria have been satisfied.

Input: refined prompt sentence, updated constraints, and current layout data.

Output: a sequence of progressively improved spatial arrangement plan versions, one of which is eventually selected as final based on user approval or objective thresholds.

The server logs each iteration, including prompts, layouts, metrics, and user responses, for later analysis and potential model retraining.

### Step 17:

The server finalizes the plan, records history, and prepares implementation data.

Once the user approves a layout, the server marks the corresponding plan data as final and stores the layout, prompts, emotion distribution data, and feedback in persistent storage.

The server converts the final layout data into export formats consumable by other systems, such as building information modeling tools or factory control systems.

Input: approved final spatial arrangement plan data and associated history information.

Output: stored records for learning data and implementation-ready files or messages for external systems.

The server may also compute summary statistics (for example, average improvement in walking distance or stress score compared to initial conditions) and attach these metrics to the record, supporting future evaluation and retraining of the generative AI model and emotion recognition components.

The data generation model 58 is a so-called generative artificial intelligence (AI). Examples of the data generation model 58 include generative AIs such as ChatGPT (registered trademark) (Internet search <URL: https://openai.com/blog/chatgpt>) and the like. The data generation model 58 is obtained by performing deep learning with a neural network. The data generation model 58 is input with a prompt including an instruction, and is input with inference data such as audio data representing speech, text data representing text, image data representing images (for example, still image data or video data), and the like. The data generation model 58 takes the input inference data, performs inference according to the instruction indicated in the prompt, and outputs an inference result in one or more data format from out of audio data, text data, image data, or the like. The data generation model 58 includes, for example, a text generative AI, an image generative AI, a multimodal generative AI, or the like. Reference here to inference indicates, for example, analysis, classification, prediction, and/or abstraction etc. The specific processing unit 290 performs the specific processing referred to above while using the data generation model 58. The data generation model 58 may be a model fine-tuned so as to output an inference result from a prompt not including an instruction, and in such cases the data generation model 58 is able to output an inference result from the prompt not including an instruction. There are plural types of the data generation model 58 included in the data processing device 12 or the like, and the data generation models 58 include an AI other than a generative AI. An AI other than a generative AI is, for example, a linear regression, a logistic regression, a decision tree, a random forest, a support vector machine (SVM), a k-means clustering, a convolutional neural network (CNN), a recurrent neural network (RNN), a generative adversarial network (GAN), a naïve Bayes, or the like and is capable of performing various processing, however there is no limitation to such examples. The AI may be an AI agent. Moreover, when the processing of each of the units mentioned above is performed by an AI, this processing is partly or entirely performed by the AI, however there is no limitation to such examples. Moreover, processing executed by an AI including a generative AI may be switched to rule-based processing, and rule-based processing may be switched to processing executed by an AI including a generative AI.

Moreover, although the processing by the data processing system 10 described above was executed by the specific processing unit 290 of the data processing device 12 or by the control unit 46A of the smart device 14, the processing may be executed by a specific processing unit 290 of the data processing device 12 and a control unit 46A of the smart device 14. Moreover, the specific processing unit 290 of the data processing device 12 acquires and collects information needed for processing from the smart device 14 or from an external device or the like, and the smart device 14 acquires and collects information needed for processing from the data processing device 12 or from an external device or the like.

For example, a collection unit is implemented by the control unit 46A of the smart device 14 and/or by the specific processing unit 290 of the data processing device 12. For example, an acquisition unit acquires number-of-steps data using the camera 42 and/or the communication I/F 44 of the smart device 14, and the number-of-steps data is processed by the specific processing unit 290 of the data processing device 12. For example, an analysis unit implemented by the specific processing unit 290 of the data processing device 12 analyzes data from the collection unit and the acquisition unit. For example, a generation unit implemented by the specific processing unit 290 of the data processing device 12 generates a cooking menu using a generative AI. For example, a supply unit implemented by the output device 40 of the smart device 14 and/or the specific processing unit 290 of the data processing device 12 supplies the generated cooking menu to the user. Correspondence relationships of each unit to devices and control units are not limited to the examples described above, and various modifications thereof are possible.

The above exemplary embodiment gives an implementation example in which the specific processing is performed by the data processing device 12, however technology disclosed herein is not limited thereto, and the specific processing may be performed by the smart device 14.

### Second Exemplary Embodiment

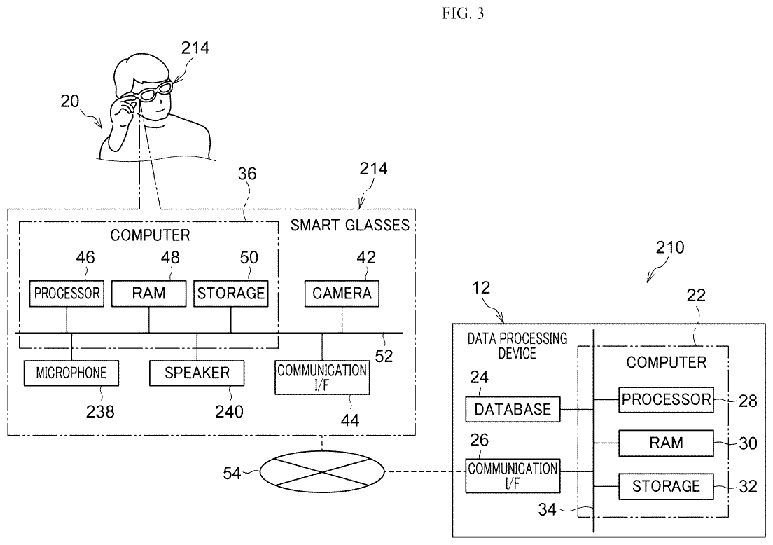

FIG. 3 illustrates an example of a configuration of a data processing system 210 according to a second exemplary embodiment.

As illustrated in FIG. 3, the data processing system 210 includes a data processing device 12 and smart glasses 214. A server is an example of the data processing device 12.

The data processing device 12 includes a computer 22, a database 24, and a communication I/F 26. The computer 22 is an example of a “computer” according to technology disclosed herein. The computer 22 includes a processor 28, RAM 30, and storage 32. The processor 28, the RAM 30, and the storage 32 are connected to a bus 34. The database 24 and the communication I/F 26 are also connected to the bus 34. The communication I/F 26 is connected to a network 54. Examples of the network 54 include a Wide Area Network (WAN) and/or a local area network (LAN).

The smart glasses 214 include a computer 36, a microphone 238, a speaker 240, a camera 42, and a communication I/F 44. The computer 36 includes a processor 46, RAM 48, and storage 50. The processor 46, the RAM 48, and the storage 50 are connected to a bus 52. The microphone 238, the speaker 240, the camera 42, and the communication I/F 44 are also connected to the bus 52.

The microphone 238 receives an instruction or the like from a user 20 by receiving speech uttered by the user 20. The microphone 238 captures the speech uttered by the user 20, converts the captured speech into audio data, and outputs the audio data to the processor 46. The speaker 240 outputs audio under instruction from the processor 46.

The camera 42 is a compact digital camera installed with an optical system such as a lens, an aperture, a shutter, and the like, and with an imaging device such as a complementary metal-oxide semiconductor (CMOS) image sensor or a charge coupled device (CCD) image sensor or the like. The camera 42 images the surroundings of the user 20 (for example, an imaging range defined by an angle of view equivalent to the width of visual field of an ordinary healthy subject).

The communication I/F 44 is connected to the network 54. The communication I/F 44 and the communication I/F 26 perform the role of exchanging various information between the processor 46 and the processor 28 over the network 54. The exchange of various information between the processor 46 and the processor 28 is performed in a secure state using the communication I/F 44 and the communication I/F 26.

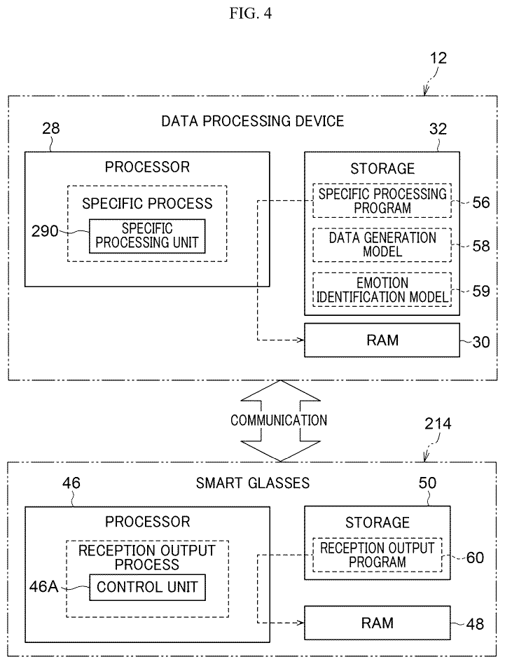

FIG. 4 illustrates an example of relevant functions of the data processing device 12 and the smart glasses 214. As illustrated in FIG. 4, specific processing is performed by the processor 28 in the data processing device 12. A specific processing program 56 is stored in the storage 32.

The specific processing program 56 is an example of a “program” according to technology disclosed herein. The processor 28 reads the specific processing program 56 from the storage 32, and in the RAM 30 executes the read specific processing program 56. The specific processing is implemented by the processor 28 operating as the specific processing unit 290 according to the specific processing program 56 executed in the RAM 30.

The data generation model 58 and the emotion identification model 59 are stored in the storage 32. The data generation model 58 and the emotion identification model 59 are employed by the specific processing unit 290. The specific processing unit 290 uses the emotion identification model 59 to estimate an emotion of a user, and is able to perform the specific processing using the user emotion. In an emotion estimation function (emotion identification function) that uses the emotion identification model 59, various estimations, predictions, and the like are performed related to emotions of the user, include estimating and predicting the emotion of the user, however, there is no limitation to such examples. Moreover, estimation and prediction of emotion also includes, for example, analyzing (parsing) emotions and the like.

Reception and output processing is performed by the processor 46 in the smart glasses 214. A reception and output program 60 is stored in the storage 50. The processor 46 reads the reception and output program 60 from the storage 50 and in the RAM 48 executes the read reception and output program 60. The reception and output processing is implemented by the processor 46 operating as the control unit 46A according to the reception and output program 60 executed in the RAM 48. Note that a configuration may be adopted in which the smart glasses 214 include a data generation model and an emotion identification model similar to the data generation model 58 and the emotion identification model 59, and processing similar to the specific processing unit 290 is performed using these models.

Next, description follows regarding the specific processing by the specific processing unit 290 of the data processing device 12. The units of the system described below are implemented by the data processing device 12 and the smart glasses 214. In the following description the data processing device 12 is called a “server”, and the smart glasses 214 is called a “terminal”.

### Example 1

Explanation of flow will be omitted due to being similar to a flow of the specific processing in Example 1 as described in the first exemplary embodiment above.

### Application Example 1

Explanation of flow will be omitted due to being similar to a flow of the specific processing in Application Example 1 as described in the first exemplary embodiment above.

### Example 2

Explanation of flow will be omitted due to being similar to a flow of the specific processing in Example 2 as described in the first exemplary embodiment above.

### Application Example 2

Explanation of flow will be omitted due to being similar to a flow of the specific processing in Application Example 2 as described in the first exemplary embodiment above.

The specific processing unit 290 transmits a result of the specific processing to the smart glasses 214. The control unit 46A in the smart glasses 214 outputs the specific processing result to the speaker 240. The microphone 238 acquires audio representing user input in response to the specific processing result. The control unit 46A transmits audio data representing the user input as acquired by the microphone 238 to the data processing device 12. The specific processing unit 290 in the data processing device 12 acquires the audio data.

The data generation model 58 is a so-called generative artificial intelligence (AI). Examples of the data generation model 58 include generative AIs such as ChatGPT (registered trademark) (Internet search <URL: https://openai.com/blog/chatgpt>) and the like. The data generation model 58 is obtained by performing deep learning with a neural network. The data generation model 58 is input with a prompt including an instruction, and is input with inference data such as audio data representing speech, text data representing text, image data representing images (for example, still image data or video data), and the like. The data generation model 58 takes the input inference data, performs inference according to the instruction indicated in the prompt, and outputs an inference result in one or more data format from out of audio data, text data, image data, or the like. The data generation model 58 includes, for example, a text generative AI, an image generative AI, a multimodal generative AI, or the like. Reference here to inference indicates, for example, analysis, classification, prediction, and/or abstraction etc. The specific processing unit 290 performs the specific processing referred to above while using the data generation model 58. The data generation model 58 may be a model fine-tuned so as to output an inference result from a prompt not including an instruction, and in such cases the data generation model 58 is able to output an inference result from the prompt not including an instruction. There are plural types of the data generation model 58 included in the data processing device 12 or the like, and the data generation models 58 include an AI other than a generative AI. An AI other than a generative AI is, for example, a linear regression, a logistic regression, a decision tree, a random forest, a support vector machine (SVM), a k-means clustering, a convolutional neural network (CNN), a recurrent neural network (RNN), a generative adversarial network (GAN), a naïve Bayes, or the like and is capable of performing various processing, however there is no limitation to such examples. The AI may be an AI agent. Moreover, when the processing of each of the units mentioned above is performed by an AI, this processing is partly or entirely performed by the AI, however there is no limitation to such examples. Moreover, processing executed by an AI including a generative AI may be switched to rule-based processing, and rule-based processing may be switched to processing executed by an AI including a generative AI.

Although the processing by the data processing system 10 described above is executed by the specific processing unit 290 of the data processing device 12 or by the control unit 46A of the smart glasses 214, the processing may be executed by a specific processing unit 290 of the data processing device 12 and a control unit 46A of the smart glasses 214. Moreover, the specific processing unit 290 of the data processing device 12 acquires and collects information needed for processing from the smart glasses 214 or from an external device or the like, and the smart glasses 214 acquires and collects information needed for processing from the data processing device 12 or from an external device or the like.

For example, the collection unit is implemented by the control unit 46A of the smart glasses 214 and/or by the specific processing unit 290 of the data processing device 12. For example, an acquisition unit acquires number-of-steps data using the camera 42 and/or the communication I/F 44 of the smart glasses 214, and the number-of-steps data is processed by the specific processing unit 290 of the data processing device 12. For example, an analysis unit implemented by the specific processing unit 290 of the data processing device 12 analyzes data from the collection unit and the acquisition unit. For example, a generation unit implemented by the specific processing unit 290 of the data processing device 12 generates a cooking menu using a generative AI. For example, a supply unit implemented by the speaker 240 of the smart glasses 214 and/or the specific processing unit 290 of the data processing device 12 supplies the generated cooking menu to the user. Correspondence relationships of each unit to devices and control units are not limited to the examples described above, and various modifications thereof are possible.

The above exemplary embodiment gives an implementation example in which the specific processing is performed by the data processing device 12, however technology disclosed herein is not limited thereto, and the specific processing may be performed by the smart glasses 214.

### Third Exemplary Embodiment

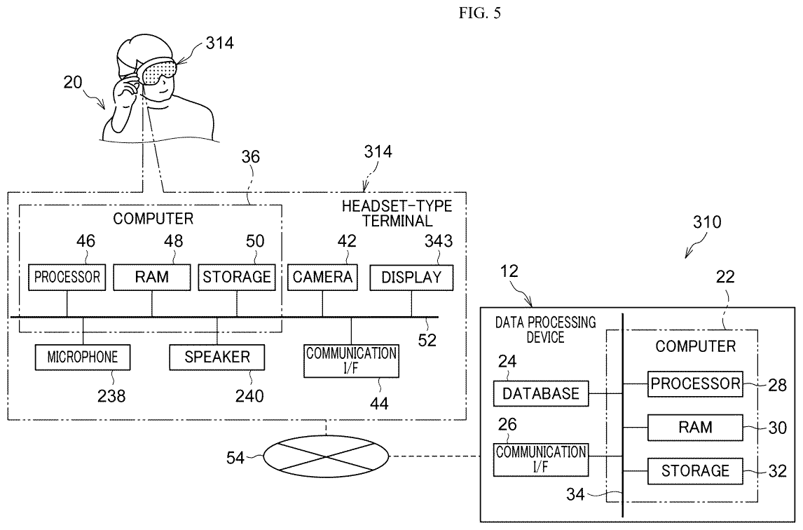

FIG. 5 illustrates an example of a configuration of a data processing system 310 according to a third exemplary embodiment.

As illustrated in FIG. 5, the data processing system 310 includes a data processing device 12 and a headset-type terminal 314. A server is an example of the data processing device 12.

The data processing device 12 includes a computer 22, a database 24, and a communication I/F 26. The computer 22 is an example of a “computer” according to technology disclosed herein. The computer 22 includes a processor 28, RAM 30, and storage 32. The processor 28, the RAM 30, and the storage 32 are connected to a bus 34. The database 24 and the communication I/F 26 are also connected to the bus 34. The communication I/F 26 is connected to a network 54. Examples of the network 54 include a Wide Area Network (WAN) and/or a local area network (LAN).

The headset-type terminal 314 includes a computer 36, a microphone 238, a speaker 240, a camera 42, a communication I/F 44, and a display 343. The computer 36 includes a processor 46, RAM 48, and storage 50. The processor 46, the RAM 48, and the storage 50 are connected to a bus 52. The microphone 238, the speaker 240, the camera 42, the display 343, and the communication I/F 44 are also connected to the bus 52.

The microphone 238 receives an instruction or the like from a user 20 by receiving speech uttered by the user 20. The microphone 238 captures the speech uttered by the user 20, converts the captured speech into audio data, and outputs the audio data to the processor 46. The speaker 240 outputs audio under instruction from the processor 46.

The camera 42 is a compact digital camera installed with an optical system such as a lens, an aperture, a shutter, and the like, and with an imaging device such as a complementary metal-oxide semiconductor (CMOS) image sensor or a charge coupled device (CCD) image sensor or the like. The camera 42 images the surroundings of the user 20 (for example, an imaging range defined by an angle of view equivalent to the width of visual field of an ordinary healthy subject).

The communication I/F 44 is connected to the network 54. The communication I/F 44 and the communication I/F 26 perform the role of exchanging various information between the processor 46 and the processor 28 over the network 54. The exchange of various information between the processor 46 and the processor 28 is performed in a secure state using the communication I/F 44 and the communication I/F 26.

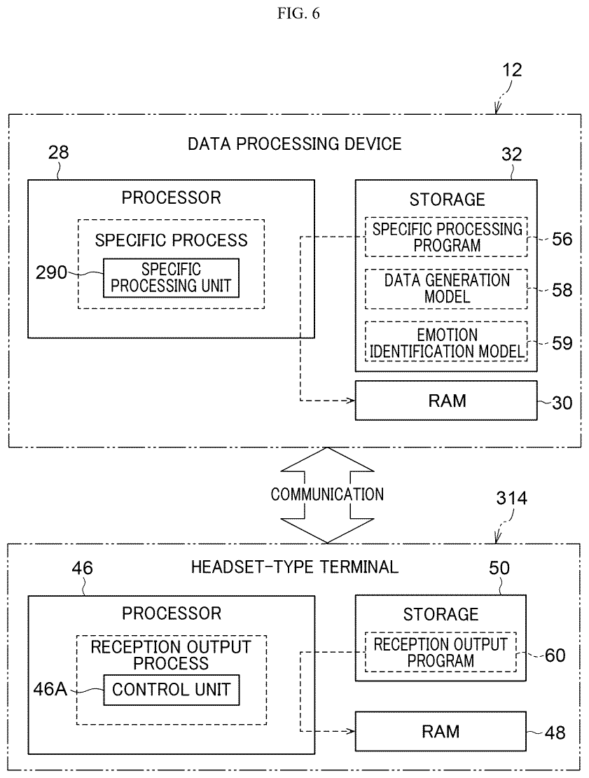

FIG. 6 illustrates an example of relevant functions of the data processing device 12 and the headset-type terminal 314. As illustrated in FIG. 6, specific processing is performed by the processor 28 in the data processing device 12. A specific processing program 56 is stored in the storage 32.

The specific processing program 56 is an example of a “program” according to technology disclosed herein. The processor 28 reads the specific processing program 56 from the storage 32, and in the RAM 30 executes the read specific processing program 56. The specific processing is implemented by the processor 28 operating as the specific processing unit 290 according to the specific processing program 56 executed in the RAM 30.

The data generation model 58 and the emotion identification model 59 are stored in the storage 32. The data generation model 58 and the emotion identification model 59 are employed by the specific processing unit 290.

Reception and output processing is performed by the processor 46 in the headset-type terminal 314. A reception and output program 60 is stored in the storage 50. The processor 46 reads the reception and output program 60 from the storage 50, and in the RAM 48 executes the read reception and output program 60. The reception and output processing is implemented by the processor 46 operating as the control unit 46A according to the reception and output program 60 executed in the RAM 48.

Next, description follows regarding the specific processing by the specific processing unit 290 of the data processing device 12. The units of the system described below are implemented by the data processing device 12 and the headset-type terminal 314. In the following description the data processing device 12 is called a “server”, and the headset-type terminal 314 is called a “terminal”.

### Example 1

Explanation of flow will be omitted due to being similar to a flow of the specific processing in Example 1 as described in the first exemplary embodiment above.

### Application Example 1

Explanation of flow will be omitted due to being similar to a flow of the specific processing in Application Example 1 as described in the first exemplary embodiment above.

### Example 2

Explanation of flow will be omitted due to being similar to a flow of the specific processing in Example 2 as described in the first exemplary embodiment above.

### Application Example 2

Explanation of flow will be omitted due to being similar to a flow of the specific processing in Application Example 2 as described in the first exemplary embodiment above.

The specific processing unit 290 transmits a result of the specific processing to the headset-type terminal 314. In the headset-type terminal 314, the control unit 46A outputs the result of the specific processing to the speaker 240 and the display 343. The microphone 238 acquires audio representing user input in response to the specific processing result. The control unit 46A transmits audio data representing the user input as acquired by the microphone 238 to the data processing device 12. The specific processing unit 290 in the data processing device 12 acquires the audio data.

The data generation model 58 is a so-called generative artificial intelligence (AI). Examples of the data generation model 58 include generative Als such as ChatGPT (registered trademark) (Internet search <URL: https://openai.com/blog/chatgpt>) and the like. The data generation model 58 is obtained by performing deep learning with a neural network. The data generation model 58 is input with a prompt including an instruction, and is input with inference data such as audio data representing speech, text data representing text, image data representing images (for example, still image data or video data), and the like. The data generation model 58 takes the input inference data, performs inference according to the instruction indicated in the prompt, and outputs an inference result in one or more data format from out of audio data, text data, image data, or the like. The data generation model 58 includes, for example, a text generative AI, an image generative AI, a multimodal generative AI, or the like. Reference here to inference indicates, for example, analysis, classification, prediction, and/or abstraction etc. The specific processing unit 290 performs the specific processing referred to above while using the data generation model 58. The data generation model 58 may be a model fine-tuned so as to output an inference result from a prompt not including an instruction, and in such cases the data generation model 58 is able to output an inference result from the prompt not including an instruction. There are plural types of the data generation model 58 included in the data processing device 12 or the like, and the data generation models 58 include an AI other than a generative AI. An AI other than a generative AI is, for example, a linear regression, a logistic regression, a decision tree, a random forest, a support vector machine (SVM), a k-means clustering, a convolutional neural network (CNN), a recurrent neural network (RNN), a generative adversarial network (GAN), a naïve Bayes, or the like and is capable of performing various processing, however there is no limitation to such examples. The AI may be an AI agent. Moreover, when the processing of each of the units mentioned above is performed by an AI, this processing is partly or entirely performed by the AI, however there is no limitation to such examples. Moreover, processing executed by an AI including a generative AI may be switched to rule-based processing, and rule-based processing may be switched to processing executed by an AI including a generative AI.

Although the processing by the data processing system 10 described above is executed by the specific processing unit 290 of the data processing device 12 or by the control unit 46A of the headset-type terminal 314, the processing may be executed by a specific processing unit 290 of the data processing device 12 and a control unit 46A of the headset-type terminal 314. Moreover, the specific processing unit 290 of the data processing device 12 acquires and collects information needed for processing from the headset-type terminal 314 or from an external device or the like, and the headset-type terminal 314 acquires and collects information needed for processing from the data processing device 12 or from an external device or the like.

For example, the collection unit is implemented by the control unit 46A of the headset-type terminal 314 and/or by the specific processing unit 290 of the data processing device 12. For example, an acquisition unit acquires number-of-steps data using the camera 42 and/or the communication I/F 44 of the headset-type terminal 314, and the number-of-steps data is processed by the specific processing unit 290 of the data processing device 12. For example, an analysis unit implemented by the specific processing unit 290 of the data processing device 12 analyzes data from the collection unit and the acquisition unit. For example, a generation unit implemented by the specific processing unit 290 of the data processing device 12 generates a cooking menu using a generative AI. For example, a supply unit implemented by the speaker 240 and the display 343 of the headset-type terminal 314 and/or the specific processing unit 290 of the data processing device 12 supplies the generated cooking menu to the user. Correspondence relationships of each unit to devices and control units are not limited to the examples described above, and various modifications thereof are possible.

The above exemplary embodiment gives an implementation example in which the specific processing is performed by the data processing device 12, however technology disclosed herein is not limited thereto, and the specific processing may be performed by the headset-type terminal 314.

### Fourth Exemplary Embodiment

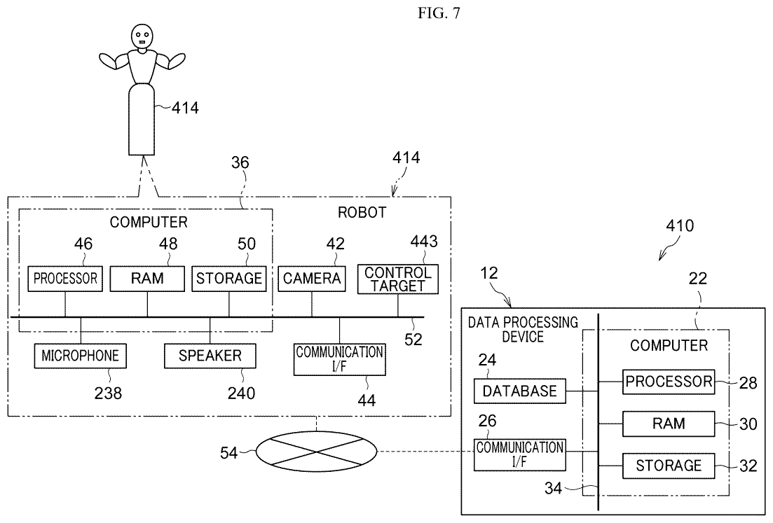

FIG. 7 illustrates an example of a configuration of a data processing system 410 according to a fourth exemplary embodiment

As illustrated in FIG. 7, the data processing system 410 includes a data processing device 12 and a robot 414. A server is an example of the data processing device 12.

The data processing device 12 includes a computer 22, a database 24, and a communication I/F 26. The computer 22 is an example of a “computer” according to technology disclosed herein. The computer 22 includes a processor 28, RAM 30, and storage 32. The processor 28, the RAM 30, and the storage 32 are connected to a bus 34. The database 24 and the communication I/F 26 are also connected to the bus 34. The communication I/F 26 is connected to a network 54. Examples of the network 54 include a Wide Area Network (WAN) and/or a local area network (LAN).

The robot 414 includes a computer 36, a microphone 238, a speaker 240, a camera 42, a communication I/F 44, and a control target 443. The computer 36 includes a processor 46, RAM 48, and storage 50. The processor 46, the RAM 48, and the storage 50 are connected to a bus 52. The microphone 238, the speaker 240, the camera 42, the control target 443, and the communication I/F 44 are also connected to the bus 52.

The microphone 238 receives an instruction or the like from a user 20 by receiving speech uttered by the user 20. The microphone 238 captures the speech uttered by the user 20, converts the captured speech into audio data, and outputs the audio data to the processor 46. The speaker 240 outputs audio under instruction from the processor 46.

The camera 42 is a compact digital camera installed with an optical system such as a lens, an aperture, a shutter, and the like, and with an imaging device such as a complementary metal-oxide semiconductor (CMOS) image sensor or a charge coupled device (CCD) image sensor or the like. The camera 42 images the surroundings of the robot 414 (for example, with an imaging range defined by an angle of view equivalent to the width of visual field of an ordinary healthy subject).

The communication I/F 44 is connected to the network 54. The communication I/F 44 and the communication I/F 26 perform the role of exchanging various information between the processor 46 and the processor 28 over the network 54. The exchange of various information between the processor 46 and the processor 28 is performed in a secure state using the communication I/F 44 and the communication I/F 26.

The control target 443 includes a display device, eye LEDs, and motors to drive arms, hands, feet, and the like. The posture and gesture of the robot 414 are controlled by controlling the motors of the arms, hands, feet, and the like. Part of an emotion of the robot 414 can be expressed by controlling these motors. Moreover, a facial expression of the robot 414 can be represented by controlling an illumination state of the eye LEDs of the robot 414.

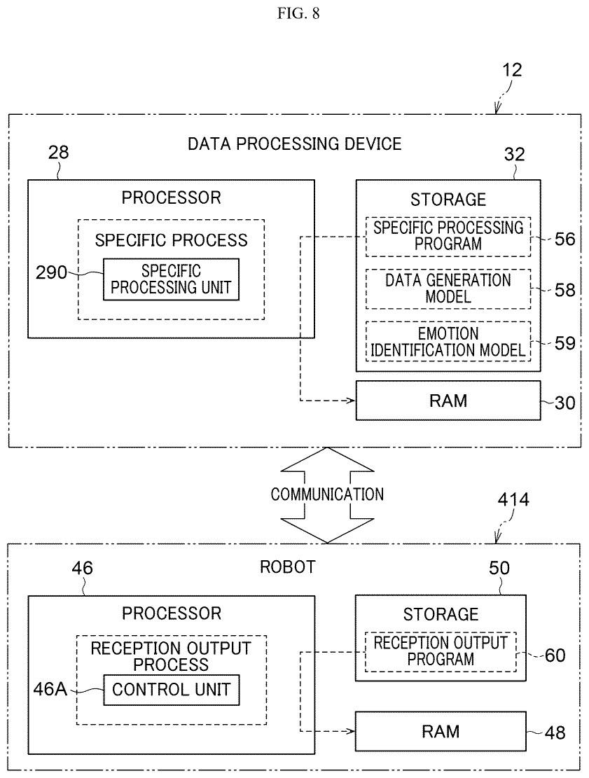

FIG. 8 illustrates an example of relevant functions of the data processing device 12 and the robot 414. As illustrated in FIG. 8, specific processing is performed by the processor 28 in the data processing device 12. A specific processing program 56 is stored in the storage 32.

The specific processing program 56 is an example of a “program” according to technology disclosed herein. The processor 28 reads the specific processing program 56 from the storage 32, and in the RAM 30 executes the read specific processing program 56. The specific processing is implemented by the processor 28 operating as the specific processing unit 290 according to the specific processing program 56 executed in the RAM 30.

The data generation model 58 and the emotion identification model 59 are stored in the storage 32. The data generation model 58 and the emotion identification model 59 are employed by the specific processing unit 290.

Reception and output processing is performed by the processor 46 in the robot 414. A reception and output program 60 is stored in the storage 50. The processor 46 reads the reception and output program 60 from the storage 50, and in the RAM 48 executes the read reception and output program 60. The reception and output processing is implemented by the processor 46 operating as the control unit 46A according to the reception and output program 60 executed in the RAM 48.

Next, description follows regarding the specific processing by the specific processing unit 290 of the data processing device 12. The units of the system described below are implemented by the data processing device 12 and the robot 414. In the following description the data processing device 12 is called a “server”, and the robot 414 is called a “terminal”.

### Example 1

Explanation of flow will be omitted due to being similar to a flow of the specific processing in Example 1 as described in the first exemplary embodiment above.

### Application Example 1

Explanation of flow will be omitted due to being similar to a flow of the specific processing in Application Example 1 as described in the first exemplary embodiment above.

### Example 2

Explanation of flow will be omitted due to being similar to a flow of the specific processing in Example 2 as described in the first exemplary embodiment above.

### Application Example 2

Explanation of flow will be omitted due to being similar to a flow of the specific processing in Application Example 2 as described in the first exemplary embodiment above.

The specific processing unit 290 transmits a result of the specific processing to the robot 414. In the robot 414, the control unit 46A outputs the result of the specific processing to the speaker 240 and the control target 443. The microphone 238 acquires audio representing user input in response to the specific processing result. The control unit 46A transmits audio data representing the user input as acquired by the microphone 238 to the data processing device 12. The specific processing unit 290 in the data processing device 12 acquires the audio data.

The data generation model 58 is a so-called generative artificial intelligence (AI). Examples of the data generation model 58 include generative Als such as ChatGPT (registered trademark) (Internet search <URL: https://openai.com/blog/chatgpt>) and the like. The data generation model 58 is obtained by performing deep learning with a neural network. The data generation model 58 is input with a prompt including an instruction, and is input with inference data such as audio data representing speech, text data representing text, image data representing images (for example, still image data or video data), and the like. The data generation model 58 takes the input inference data, performs inference according to the instruction indicated in the prompt, and outputs an inference result in one or more data format from out of audio data, text data, image data, or the like. The data generation model 58 includes, for example, a text generative AI, an image generative AI, a multimodal generative AI, or the like. Reference here to inference indicates, for example, analysis, classification, prediction, and/or abstraction etc. The specific processing unit 290 performs the specific processing referred to above while using the data generation model 58. The data generation model 58 may be a model fine-tuned so as to output an inference result from a prompt not including an instruction, and in such cases the data generation model 58 is able to output an inference result from the prompt not including an instruction. There are plural types of the data generation model 58 included in the data processing device 12 or the like, and the data generation models 58 include an AI other than a generative AI. An AI other than a generative AI is, for example, a linear regression, a logistic regression, a decision tree, a random forest, a support vector machine (SVM), a k-means clustering, a convolutional neural network (CNN), a recurrent neural network (RNN), a generative adversarial network (GAN), a naïve Bayes, or the like and is capable of performing various processing, however there is no limitation to such examples. The AI may be an AI agent. Moreover, when the processing of each of the units mentioned above is performed by an AI, this processing is partly or entirely performed by the AI, however there is no limitation to such examples. Moreover, processing executed by an AI including a generative AI may be switched to rule-based processing, and rule-based processing may be switched to processing executed by an AI including a generative AI.

Although the processing by the data processing system 10 described above is executed by the specific processing unit 290 of the data processing device 12 or by the control unit 46A of the robot 414, the processing may be executed by a specific processing unit 290 of the data processing device 12 and a control unit 46A of the robot 414. Moreover, the specific processing unit 290 of the data processing device 12 acquires and collects information needed for processing from the robot 414 or from an external device or the like, and the robot 414 acquires and collects information needed for processing from the data processing device 12 or from an external device or the like.

For example, the collection unit is implemented by the control unit 46A of the robot 414 and/or by the specific processing unit 290 of the data processing device 12. For example, an acquisition unit acquires number-of-steps data using the camera 42 and/or the communication I/F 44 of the robot 414, and the number-of-steps data is processed by the specific processing unit 290 of the data processing device 12. For example, an analysis unit implemented by the specific processing unit 290 of the data processing device 12 analyzes data from the collection unit and the acquisition unit. For example, a generation unit implemented by the specific processing unit 290 of the data processing device 12 generates a cooking menu using a generative AI. For example, a supply unit implemented by the speaker 240 and the control target 443 of the robot 414 and/or the specific processing unit 290 of the data processing device 12 supplies the generated cooking menu to the user. Correspondence relationships of each unit to devices and control units are not limited to the examples described above, and various modifications thereof are possible.

The above exemplary embodiment gives an implementation example in which the specific processing is performed by the data processing device 12, however technology disclosed herein is not limited thereto, and the specific processing may be performed by the robot 414.

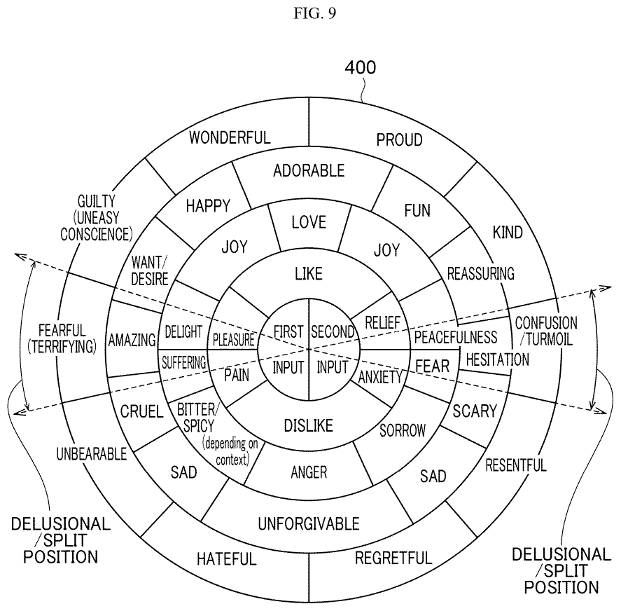

Note that the emotion identification model 59 serves as an emotion engine, and may decide the emotion of a user according to a specific mapping. Specifically, the emotion identification model 59 may decide the emotion of a user according to an emotion map (see FIG. 9) that is a specific mapping. Moreover, the emotion identification model 59 may also decide the emotion of the robot similarly, and the specific processing unit 290 may be configured so as to perform the specific processing using the emotion of the robot.

FIG. 9 is a diagram illustrating an emotion map 400 mapping plural emotions. In the emotion map 400, emotions are arranged in concentric circles that radiate out from the center. Primitive states of emotion are arranged nearer to the center of the concentric circles. Emotions expressing states and actions generated from states of mind are arranged further toward the outside of the concentric circles. Emotions are defined as including both affect and mental states. Emotions generated from reactions occurring in the brain are generally arranged at the left side of the concentric circles. Emotions induced by situational assessment are generally arranged at the right side of the concentric circles. Emotions generated from reactions occurring in the brain that are also emotions induced by situational assessment are generally arranged toward the top and toward the bottom of the concentric circles. Moreover, emotions of “euphoria” are arranged at the upper side of the concentric circles, and emotions of “dysphoria” are arranged at the lower side of the concentric circles. Plural emotions are accordingly mapped in this manner in the emotion map 400 based on a structure giving rise to emotions, and emotions that readily occur at the same time are mapped close to each other.

An example of such emotions is a distribution of emotions in the direction of 3 o'clock on the emotion map 400, generally around a boundary between relief and anxiety. Situational awareness dominates over internal sensations in the right half of the emotion map 400, with an impression of calm.

The inside of the emotion map 400 represents feelings, and the outside of the emotion map 400 represents actions, and so emotions further toward the outside of the emotion map 400 are more visible (are expressed by actions).

Human emotions are based on various balances, such as posture and blood sugar value balances, with a state of dysphoria being exhibited when these balances are far from ideal and a state of euphoria being exhibited when these balances are near to ideal. Even in a robot, a car, a motorbike, or the like, emotions can be thought of as being based on various balances such as orientation and remaining battery balances, with a state called dysphoria being exhibited when these balances are far from ideal and a state called euphoria being exhibited when these balances are near to ideal. An emotion map may, for example, be generated based on the emotion map of Dr. Mitsuyoshi (PhD Dissertation https://ci.nii.ac.jp/naid/500000375379: “Research on the phonetic recognition of feelings and a system for emotional physiological brain signal analysis”, Tokushima University).

Emotions belonging to an area called “reaction” where feeling dominates are arranged in the left half of the emotion map. Moreover, emotions belonging to an area called “situation” where situational awareness dominates are arranged in the right half of the emotion map.

There are two types of emotion that facilitate leaning in an emotion map. One is an emotion in the vicinity of the center of negative “penitence” and “reflection” on the situational side. In other words, sometimes a negative “emotion” such as “I don't want to feel this way ever again” and “I don't want to be chided again” is experienced in a robot. Another is a positive emotion in the area of “desire” on the reaction side. In other words, there are times when a positive feeling such as “desire more” and “want to know more” is experienced.

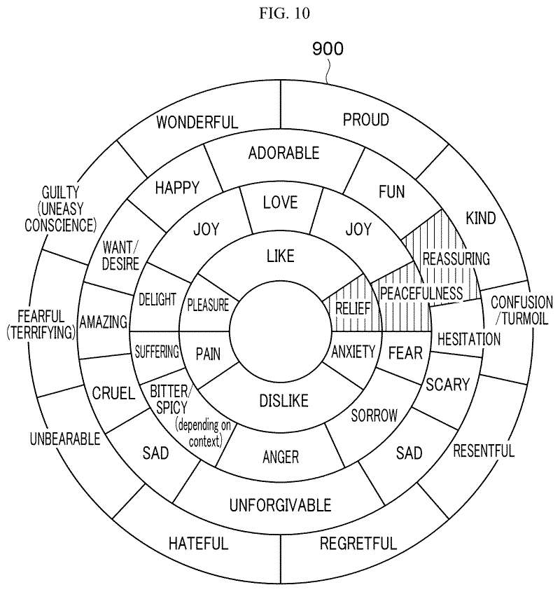

In the emotion identification model 59, user input is input to a pre-trained neural network, and emotion values indicating emotions shown on the emotion map 400 are acquired and the emotions of the user are decided. This neural network is pre-trained based on plural training data sets that each combine a user input with an emotion value indicating an emotion shown on the emotion map 400. The neural network is also trained such that emotions arranged close to each other have values that are close to each other, as in an emotion map 900 illustrated in FIG. 10. In FIG. 10 the plural emotions of “relief”, “peaceful”, and “reassured” are indicated as an example of close emotion values.

Although the system according to the present disclosure has been described mainly as functions of the data processing device 12, the system according to the present disclosure is not limited to being implemented in a server. The system according to the present disclosure may be implemented as a general information processing system. The present disclosure may, for example, be implemented by a software program operating on a personal computer, and may be implemented by an application operating on a smartphone or the like. The method according to the present disclosure may also be supplied to a user in the form of Software as a Service (Saas).

Although in the exemplary embodiments described above examples are given of embodiments in which the specific processing is performed by a single computer 22, technology disclosed herein is not limited thereto, and distributed processing may be performed for the specific processing, with the specific processing distributed across plural computers including the computer 22. For example, the data generation model 58 may be provided in a device external to the data processing device 12, such that data generation in response to input data is performed in the external device.

Although in the exemplary embodiments described above examples are described of embodiments in which the specific processing program 56 is stored in the storage 32, the technology disclosed herein is not limited thereto. For example, the specific processing program 56 may be stored on a portable, non-transitory, computer readable, storage medium, such as universal serial bus (USB) memory or the like. The specific processing program 56 stored on the non-transitory storage medium is then installed on the computer 22 of the data processing device 12. The processor 28 then executes the specific processing according to the specific processing program 56.

Moreover, the specific processing program 56 may be stored on a storage device, such as a server connected to the data processing device 12 over the network 54, with the specific processing program 56 then being downloaded in response to a request from the data processing device 12 and installed on the computer 22.

Note that there is no need to store the entire specific processing program 56 on the storage device, such as a server connected to the data processing device 12 over the network 54, or to store the entire specific processing program 56 on the storage 32, and part of the specific processing program 56 may be stored thereon.

Hardware resources for executing the specific processing may use various processors as listed below. Examples of processors include, for example, a CPU that is a general-purpose processor that functions as a hardware resource to execute the specific processing by executing software, namely a program. Moreover, the processor may, for example, be a dedicated electronic circuit that is a processor having a circuit configuration custom designed for executing the specific processing, such as a field-programmable gate array (FPGA), a programmable logic device (PLD), or an application specific integrated circuit (ASIC). Memory is inbuilt or connected to each of these processors, and the specific processing is executed by each of these processors using the memory.

The hardware resource that executes the specific processing may be configured from one of these various processors, or may be configured from a combination of two or more processors of the same or different type (for example, a combination of plural FPGAs, or a combination of a CPU and a FPGA). The hardware resource executing the specific processing may be a single processor.

Examples of configurations of a single processor include, firstly, a configuration of a single processor resulting from combining one or more CPU and software, in an embodiment in which this processor functions as the hardware resource for executing the specific processing. Secondly, as typified by a System-on-chip (SOC) or the like, there is also an embodiment that uses a processor realized by a single IC chip to function as an overall system including plural hardware resources for executing the specific processing. Adopting such an approach means that the specific processing is realized using one or more of the various processors described above as hardware resource.

Furthermore, more specifically, an electrical circuit that combines circuit elements such as semiconductor elements or the like may be employed as a hardware structure of these various processors. The specific processing is merely an example thereof. This means that obviously redundant steps may be omitted, new steps may be added, and the processing sequence may be swapped around within a range not departing from the spirit of the present disclosure.

The described content and drawing content illustrated above are a detailed description of parts according to the present disclosure, and are merely examples of the present disclosure. For example, description related to the above configuration, function, operation, and advantageous effects is a description related to examples of the configuration, function, operation, and advantageous effects of parts according to the present disclosure. This means that obviously redundant parts may be eliminated, new elements may be added, and switching around may be performed on the described content and drawing content illustrated above within a range not departing from the spirit of the present disclosure. Moreover, to avoid misunderstanding and to facilitate understanding of parts according to the present disclosure, description related to common knowledge in the art and the like not particularly needing description to enable implementation of the present disclosure is omitted in the described content and drawing content illustrated as described above.

All publications, patent applications and technical standards mentioned in the present specification are incorporated by reference in the present specification to the same extent as if each individual publication, patent application, or technical standard was specifically and individually indicated to be incorporated by reference.

Note that, regarding the above description, the following supplementary notes are further disclosed.

### Example 1

### (Supplementary 1)

A system comprising a processor,
wherein the processor is configured to
receive, in an interactive manner, requirement information regarding spatial layout from a user via an interactive interface, and
analyze the requirement information by using natural language processing to extract structured constraint information including at least a space type, area conditions, functional conditions, circulation conditions, and comfort conditions, and generate, based on the structured constraint information, a prompt sentence as a generation instruction text that is inputtable to a generative AI model, and
input the prompt sentence to the generative AI model and, based on inference processing performed by the generative AI model, generate, as data, a spatial layout plan that takes into account at least space utilization efficiency, work efficiency, communication, environmental load, and user emotion, and
perform consistency verification and correction processing on position information, dimension information, and function information for each region included in the spatial layout plan, and convert the spatial layout plan into layout display data including geometric information for display and explanatory information, and
visually present the spatial layout plan by using three-dimensional display technology or two-dimensional display technology based on the layout display data, obtain feedback information from the user in an interactive manner in response to the presentation, and regenerate the prompt sentence by combining the feedback information with the requirement information so as to iteratively update the spatial layout plan, and
recognize emotion information of the user obtained during or after the presentation of the spatial layout plan, and adjust at least a region configuration, dimension allocation, and arrangement relationship of the spatial layout plan based on the emotion information.

### (Supplementary 2)

The system according to Supplementary 1,
wherein the processor is configured to
calculate an evaluation value using the emotion information of the user and the structured constraint information, the evaluation value using, as indices, at least work efficiency and burden reduction, and automatically change content of the prompt sentence to be input to the generative AI model such that the evaluation value satisfies a predetermined condition, thereby generating the spatial layout plan.

### (Supplementary 3)

The system according to Supplementary 1,
wherein the processor is configured to
analyze an emotional state of the user to calculate emotion indices indicating at least comfort/uncomfortableness, tension, and concentration, and change the spatial layout plan by adjusting spatial configuration parameters including at least an area ratio of open regions, a number of individual work regions, and a width of circulation paths according to the emotion indices.

### Application Example 1

### (Supplementary 1)

A system comprising a processor, a storage device, a communication device, and a terminal including a display device and an input device,
wherein the processor is configured to
acquire, via the terminal, a user request related to spatial arrangement expressed in natural language in an interactive manner, and record the user request as character information, obtain, via the communication device, the character information transmitted from the terminal, and convert the character information into structured data representing spatial arrangement conditions by executing a language analysis program that divides the character information into units of morphemes or words and analyzes grammatical information and semantic information, and generate, on the basis of the structured data, a prompt sentence suitable for input to a generative AI model and numerical feature values associated with the prompt sentence,
input the prompt sentence and the numerical feature values to the generative AI model executed on a numerical computation device, and generate layout data representing a plurality of candidate spatial arrangement plans by performing neural network computation using parameters representing evaluation indices including space utilization efficiency, work efficiency, communication smoothness, environmental impact, and user preference, execute a movement path analysis algorithm and a visibility evaluation algorithm for the plurality of spatial arrangement plans to calculate index values indicating movement distance, congestion degree, visibility, and environmental influence, and select an optimal spatial arrangement plan on the basis of the index values and the spatial arrangement conditions, and adjust the layout data by local search or rule-based correction when necessary,
convert the selected or adjusted spatial arrangement plan into a display data structure to generate two-dimensional or three-dimensional image information, transmit the image information to the display device of the terminal via the communication device so as to visually present the spatial arrangement plan, acquire, via the terminal, an additional user request expressed in natural language or a layout manipulation input, update the spatial arrangement conditions in accordance with the additional user request or the layout manipulation input, and repeatedly execute processing of generation by the generative AI model and evaluation based on the updated spatial arrangement conditions, and
store, in the storage device, the prompt sentence, the spatial arrangement conditions, the spatial arrangement plans, and an update history thereof in association with one another, and manage the stored information as history information that is available for subsequent generation processing or analysis processing.

### (Supplementary 2)

The system according to supplementary 1,
wherein the processor is configured to
acquire, via the terminal, evaluation information indicating a user reaction or data indicating a user emotional state, and, on the basis of the evaluation information or the emotional state, change weighting of the numerical feature values input to the generative AI model or weighting of the evaluation indices, thereby generating a spatial arrangement plan that takes into account work efficiency and reduction of psychological load.

### (Supplementary 3)

The system according to supplementary 1,
wherein the processor is configured to
accumulate, in the storage device, a plurality of prompt sentences received from the user and respective spatial arrangement plans finally adopted in association with the plurality of prompt sentences as a history, and, on the basis of the history, update parameters of at least one of the generative AI model and the evaluation indices so as to preferentially generate a spatial arrangement plan adapted to a user preference for a prompt sentence of a similar type.

### Example 2

### (Supplementary 1)

A system comprising a processor,
wherein the processor is configured to
acquire, in an interactive manner, requirement information relating to a spatial arrangement from a user via a terminal device, and convert the requirement information into formatted information,
analyze the formatted information by using natural language processing to obtain an analysis result, and construct, based on the analysis result, a prompt sentence suitable for input to a generative information processing model,
transmit the prompt sentence to the generative information processing model operating on an external information processing apparatus, and acquire response information including a proposal relating to the spatial arrangement from the generative information processing model,
analyze the response information to convert the proposal relating to the spatial arrangement into structured arrangement information, and generate evaluation information relating to space utilization efficiency, work efficiency, smoothness of information exchange, and environmental load based on the structured arrangement information,
generate two-dimensional or three-dimensional visual representation data based on the structured arrangement information and the evaluation information, and output the visual representation data to a display device, and
acquire feedback information from the user relating to the proposal for the spatial arrangement presented on the display device, integrate the feedback information into the requirement information to update the prompt sentence, and repeatedly execute regeneration processing of the proposal for the spatial arrangement by the generative information processing model using the updated prompt sentence.

### (Supplementary 2)

The system according to supplementary 1,
wherein the processor is configured to
divide the proposal relating to the spatial arrangement into area units based on the analysis result and the structured arrangement information, generate area information indicating a function, a positional relationship, and a passage arrangement for each area unit, and associate the area information with the visual representation data and output the area information.

### (Supplementary 3)

The system according to supplementary 1,
wherein the processor is configured to
determine whether the response information acquired from the generative information processing model includes a missing element or an inconsistency, and, when the missing element or the inconsistency is determined to be included, supplement the proposal relating to the spatial arrangement by adding a constraint condition indicating the missing element or the inconsistency to the prompt sentence and re-inputting the prompt sentence to the generative information processing model.

### Application Example 2

### (Supplementary 1)

A system comprising a processor,
wherein the processor is configured to
receive, in an interactive manner, a requirement for a spatial arrangement from a user, acquire an input in a natural language including a voice input, perform a speech recognition process and a display process for text editing on the input, and thereby obtain text data,
analyze the text data by using a natural language processing technique, perform syntactic analysis and keyword extraction, generate structured data including information regarding a floor area, a number of workers, required functional regions, environmental conditions, and user priorities, and dynamically generate a prompt sentence for input to a generative AI model based on the structured data and past spatial arrangement information,
acquire emotion-related data including text input, voice input, and image input from the user, calculate emotion feature values indicating stress, fatigue, activity, and environmental orientation from the emotion-related data by using an emotion recognition model, and integrate the emotion feature values into the structured data as spatial arrangement conditions,
execute the generative AI model using the prompt sentence and the spatial arrangement conditions as inputs, and generate spatial arrangement plan data including types, positions, dimensions, and attributes of regions while simultaneously considering space utilization efficiency, work efficiency, facilitation of information exchange, environmental load, and the emotion feature values,
perform a verification process and a numerical optimization process on the spatial arrangement plan data with respect to geometric consistency, safety criteria, and route constraints, and adjust the positions and dimensions of the regions to improve evaluation indices relating to path length, congestion, and safety, thereby generating final spatial arrangement plan data,
generate three-dimensional scene data by using a three-dimensional modeling technique based on the final spatial arrangement plan data, generate visualization data for performing two-dimensional display and three-dimensional display based on the three-dimensional scene data, and transmit the visualization data to a terminal device to visually present a spatial arrangement plan,
acquire operation input and evaluation input from the user with respect to the visually presented spatial arrangement plan, update the spatial arrangement conditions based on the evaluation input and the emotion feature values, and iteratively adjust the spatial arrangement plan by re-executing the generative AI model based on the updated spatial arrangement conditions,
generate emotion distribution data for each region by temporally aggregating emotion data based on biological information and image information acquired from workers in a work environment, generate an additional prompt sentence for partially modifying an existing spatial arrangement plan by using the emotion distribution data, and generate an updated spatial arrangement plan by causing the generative AI model to operate using the additional prompt sentence, and
store the final spatial arrangement plan data, the prompt sentence, and the emotion distribution data, and execute a learning data generation process for training the generative AI model and the emotion recognition model by using storage results.

### (Supplementary 2)

The system according to supplementary 1,
wherein the processor is configured to
determine an emotion state by using the emotion recognition model based on biological information and image information acquired from the user or a worker, generate constraint conditions for changing a placement density or placement position of a rest region, a concentration work region, or a collaboration work region in accordance with the emotion state, and incorporate the constraint conditions into the spatial arrangement conditions so as to generate a spatial arrangement plan that takes into account work efficiency and stress reduction.

### (Supplementary 3)

The system according to supplementary 1,
wherein the processor is configured to
automatically generate a multi-stage prompt sentence including a descriptive statement that explicitly indicates evaluation indices relating to space utilization efficiency, work efficiency, facilitation of information exchange, and environmental load, and a conditional statement for updating the spatial arrangement plan, by using, as inputs, the requirement in the natural language from the user, the structured data, the emotion feature values, and history information including the emotion distribution data, and by referring to a previous output result of the generative AI model and feedback information from the user.

What is claimed is:

1. A system comprising:
circuitry configured to:
receive, via a communication interface coupled to a packet-switched network, natural-language requirement information regarding a spatial layout from a terminal device, and analyze the requirement information using natural language processing to extract structured constraint information comprising at least a space type, area conditions, functional conditions, circulation conditions, and comfort conditions;
generate, based on the structured constraint information, a prompt sentence as a generation instruction text for input to a generative AI model, and input the prompt sentence to the generative AI model to obtain layout plan data representing a spatial layout that takes into account at least space utilization efficiency, work efficiency, communication flow, and environmental load;
perform consistency verification and correction processing on position information, dimension information, and function information for each region included in the layout plan data, and convert the layout plan data into layout display data for three-dimensional rendering;
transmit the layout display data to the terminal device via the communication interface for three-dimensional visual presentation, receive emotion feature data from the terminal device, and apply an emotion recognition model to the emotion feature data to generate an emotional state representation; and
generate an updated prompt sentence based on the emotional state representation, history information comprising prior layout plan data and feedback information, and the structured constraint information, and input the updated prompt sentence to the generative AI model to generate a refined layout plan.

2. The system according to claim 1, wherein the circuitry is configured to
apply a named entity recognition model to the natural-language requirement information to identify spatial entity types, functional requirement entities, and constraint entities, and use the identified entities to populate structured constraint information fields.

3. The system according to claim 2, wherein the circuitry is configured to
apply a semantic parsing model to extract hierarchical relationships between identified spatial entities and functional requirement entities, and incorporate the hierarchical relationships as conditional parameters in the prompt sentence.

4. The system according to claim 3, wherein the circuitry is configured to
apply a consistency analysis model to the hierarchical relationships to verify that functional requirement entities assigned to each spatial region do not violate area condition constraints, and generate correction instructions for the generative AI model when violations are detected.

5. The system according to claim 4, wherein the circuitry is configured to
incorporate the correction instructions as penalty parameters in the updated prompt sentence to prevent the generative AI model from generating layouts that violate area condition constraints.

6. The system according to claim 1, wherein the circuitry is configured to
receive audio data from the terminal device, apply a voice tone analysis model to extract prosodic features, receive image data from the terminal device, apply a facial expression recognition model to generate an expression classification, and combine the prosodic features and the expression classification to generate the emotional state representation.

7. The system according to claim 6, wherein the circuitry is configured to
generate an emotion distribution data set by accumulating emotional state representations over a session, and incorporate the emotion distribution data into the updated prompt sentence to enable the generative AI model to account for temporal patterns in the user's emotional responses.

8. The system according to claim 1, wherein the circuitry is configured to
apply a three-dimensional modeling pipeline to the corrected layout plan data to generate a rendering mesh, apply texture mapping and lighting parameters to the rendering mesh, and transmit the rendered three-dimensional display data to the terminal device.

9. The system according to claim 8, wherein the circuitry is configured to
generate interactive navigation parameters for the three-dimensional rendering that allow the user to adjust the viewing angle and zoom level via the terminal device, and receive updated viewing parameters from the terminal device via the communication interface.

10. The system according to claim 1, wherein the circuitry is configured to
receive feedback information from the terminal device indicating user satisfaction with specific regions of the layout plan, and incorporate the feedback information as weighted constraint adjustments in the updated prompt sentence for layout refinement.

11. The system according to claim 10, wherein the circuitry is configured to
apply a preference learning model to accumulated feedback information stored in a storage device to identify regions of the layout that consistently receive low satisfaction scores, and generate targeted refinement parameters for those regions.

12. The system according to claim 1, wherein the circuitry is configured to
apply an environmental load calculation model to the layout plan data to calculate energy efficiency metrics and carbon footprint estimates for each spatial region, and incorporate the calculated metrics as constraint parameters in the prompt sentence.

13. The system according to claim 12, wherein the circuitry is configured to
generate alternative layout variants that trade off space utilization efficiency against environmental load metrics, and present the variants to the terminal device for user comparison.

14. The system according to claim 1, wherein the circuitry is configured to
apply a simulation model to the layout plan data to estimate communication flow patterns between spatial regions, and incorporate estimated communication flow metrics as optimization parameters in the updated prompt sentence.

15. The system according to claim 14, wherein the circuitry is configured to
apply a graph-based analysis model to the communication flow patterns to identify bottleneck regions, and generate layout adjustment recommendations targeting bottleneck regions.

16. The system according to claim 1, wherein the circuitry is configured to
maintain a session history comprising prior layout plan data versions, feedback information, and emotional state representations in a storage device, and enable retrieval of any prior version via the terminal device.

17. The system according to claim 16, wherein the circuitry is configured to
apply a comparison model to consecutive layout plan data versions to identify specific changes introduced at each iteration, and transmit a change summary to the terminal device.

18. A system comprising:
circuitry configured to:
receive, via a communication interface coupled to a packet-switched network, natural-language requirement information from a terminal device, apply a natural language processing model to extract structured constraint information comprising a space type, area conditions, functional conditions, and comfort conditions, and generate a prompt sentence for a generative AI model incorporating the structured constraint information;
obtain layout plan data from the generative AI model, apply consistency verification and correction processing to position, dimension, and function information, and convert the layout plan data into three-dimensional display data;
receive audio data and image data from the terminal device, apply a voice tone analysis model and a facial expression recognition model to generate an emotional state representation, and accumulate emotional state representations to generate emotion distribution data;
generate an updated prompt sentence based on the emotional state representation, emotion distribution data, prior layout plan data, and feedback information received from the terminal device, and input the updated prompt sentence to the generative AI model to generate a refined layout plan; and
transmit refined layout display data to the terminal device via the communication interface.

19. The system according to claim 18, wherein the circuitry is configured to
apply a preference learning model to accumulated feedback information to identify low-satisfaction spatial regions, apply a simulation model to estimate communication flow metrics, and incorporate both low-satisfaction regions and communication flow bottleneck parameters into the updated prompt sentence for targeted layout refinement.

20. A method comprising:
receiving, via a communication interface coupled to a packet-switched network, natural-language requirement information regarding a spatial layout from a terminal device, and analyzing the requirement information using natural language processing to extract structured constraint information comprising at least a space type, area conditions, functional conditions, circulation conditions, and comfort conditions;
generating, based on the structured constraint information, a prompt sentence as a generation instruction text for input to a generative AI model, and inputting the prompt sentence to the generative AI model to obtain layout plan data;
performing consistency verification and correction processing on position information, dimension information, and function information for each region included in the layout plan data, and converting the layout plan data into layout display data for three-dimensional rendering;
transmitting the layout display data to the terminal device via the communication interface for three-dimensional visual presentation, receiving emotion feature data from the terminal device, and applying an emotion recognition model to the emotion feature data to generate an emotional state representation; and
generating an updated prompt sentence based on the emotional state representation, history information, and the structured constraint information, and inputting the updated prompt sentence to the generative AI model to generate a refined layout plan.
